(19) United States
(12) Patent Application Publication
(10) Pub. No.: US 2021/0235190 A1
(43) Pub. Date: Jul. 29, 2021

(54) SOUND QUALITY MODIFICATION ELEMENT, AUDIO SYSTEM, AUDIO AMPLIFIER APPARATUS EQUIPPED WITH SOUND QUALITY MODIFICATION ELEMENT, AND SPEAKER SYSTEM EQUIPPED WITH SOUND QUALITY MODIFICATION ELEMENT

(71) Applicant: KaMS Co., Ltd., Nagoya-shi, Aichi (JP)

(72) Inventor: Naoto KAINUMA, Nagoya-shi (JP)

(73) Assignee: KaMS Co., Ltd., Nagoya-shi, Aichi (JP)

(21) Appl. No.: 15/734,914

(22) PCT Filed: Jul. 18, 2019
(86) PCT No.: PCT/JP2019/028277

§ 371 Date: Dec. 3, 2020

(30) Foreign Application Priority Data
Jul. 20, 2018 (JP) 2018-136415

(51) Int. Cl. H04R 3/04; H04R 1/22; H03F 3/181

(52) U.S. Cl. CPC H04R 3/04; H03F 2200/03; H03F 3/181; H04R 1/22

(57) ABSTRACT

These sound quality modification elements are connected to connection paths extending from audio amplifier circuits for outputting audio signals, to one or more speakers, and modify the sound qualities of sounds emitted from the speakers. The sound quality modification elements are each provided with an element body including: an element block made of a single metal block having a dimension of at least 5 mm in the radial direction and a dimension of at least 5 mm in the longitudinal direction; and at least a first element terminal disposed at one end of the element block, and, as an option, a second element terminal disposed at the other end.

### TECHNICAL FIELD

The present invention relates to a sound quality modification element for modifying the sound quality of sound to be reproduced, an audio amplifier apparatus equipped with the sound quality modification element, or a speaker system equipped with the sound quality modification element, for use in an audio system for emitting the sound reproduced by a speaker through connection paths such as a speaker cable from a sound signal (an electric signal) output from an audio amplifier circuit.

### BACKGROUND ART

In general, there have been known a stereo audio system, 5.1 ch surround system, and others, in which an audio amplifier circuit and a speaker system (a speaker system including one or a plurality of speakers) are connected via a speaker cable(s), the audio amplifier circuit amplifies an input analog or digital electric signal, such as music, and the speaker system reproduces sounds from the sound signal (the electric signal) output from the audio amplifier circuit.

Regarding such stereo audio systems, mainly music lovers demand to listen to the music (music pieces) played with better sound. For the purpose of modification (improvement) of the quality of the sound to be reproduced, e.g., for extended high tones, echo of low tones, expensive audio amplifier apparatus, speaker systems, speaker cables, and others may be used. Further, various devices and methods have been proposed for the purpose of modifying (improving) the sound to be reproduced.

### RELATED ART DOCUMENTS

### Patent Documents

Patent Document 1: JP-A-2007-81831

Patent Document 2: JP-A-2005-143093

Patent Document 3: JP-A-2001-34273

### SUMMARY OF INVENTION

### Problems to be Solved by the Invention

The present invention has been made in view of the above demands and provides a sound quality modification element for modifying the quality of sound, such as music (music pieces), emitted from a speaker(s) in an audio system including one or a plurality of speakers to reproduce a sound signal output from an audio amplifier circuit through a connection path(s), an audio amplifier apparatus equipped with the sound quality modification element, and a speaker system equipped with the sound quality modification element.

### Means of Solving the Problems

(First Item)

A first aspect provides a sound quality modification element to be connected to a connection path extending from an audio amplifier circuit that outputs a sound signal to one or a plurality of speakers, the sound quality modification element being configured to modify sound quality of sound to be emitted from the one or the plurality of speakers, the sound quality modification element comprising an element body including: an element block part formed of a single metal block having a dimension of 5 mm or more in a diametrical direction and a dimension of 5 mm in a length direction perpendicular to the diameter direction; and at least a first element terminal part provided at one end of the element block part in the length direction, from among the first element terminal part and a second element terminal part provided at an other end of the element block part in the length direction.

Concretely, for example, the sound quality modification element is configured to modify the sound quality of sound to be emitted from the speaker system by connection to (i) an amplifier output terminal of the audio amplifier circuit that outputs a sound signal, (ii) a speaker input terminal of the speaker system including one or a plurality of speakers, (iii) a speaker cable connecting the amplifier output terminal and the speaker input terminal, (iv) the amplifier output terminal and the speaker cable, or (v) the speaker cable and the speaker input terminal. Preferably, the sound quality modification element is provided with the element body including: the element block part formed of a single metal block having a dimension of 5 mm or more in the diametrical direction and a dimension of 5 mm or more in the length direction; and a first element terminal part provided at one end of the element block part in the length direction and optionally a second element terminal part provided at the other end of the element block part in the length direction.

The sound quality modification element of the present invention is configured to modify the sound quality of sound to be emitted from the speaker connected to the audio amplifier circuit (an amplifier) that outputs a sound signal through the connection path such as a speaker cable as compared with the sound quality of sound to be emitted from the configuration not using the sound quality modification element. The sound quality modification element of the present invention is provided with the element body including the element block part formed of a single metal block and a first element terminal part. Alternatively, the sound quality modification element of the present invention is provided with the element body including the element block part formed of a single metal block, a first element terminal part, and a second element terminal part.

When used for the audio system, concretely, the above sound quality modification element is connected to for example (i) the amplifier output terminal of the audio amplifier circuit, (ii) the speaker input terminal of the speaker system including the one or more speakers, (iii) the speaker cable connecting the amplifier output terminal and the speaker input terminal, (iv) the amplifier output terminal and the speaker cable, or (v) the speaker cable and the speaker input terminal, to modify the sound quality of sound to be emitted from the speaker system. Specifically, the audio system incorporating the sound quality modification element, as compared with an audio system not using the sound quality modification element, can modify the sound quality of sound (music pieces, etc.) to be reproduced from the speaker system, for example, by emphasizing sounds, or tones, in a mid-high range and a low range according to the dimension of the element block part, so that each instrument or voice sound is reproduced with each clear tone, from among the sounds to be emitted from the speaker system (sounds such as music pieces and singing voice sounds to be reproduced through the speaker system).

Specifically, the inventor prepares the sound quality modification element having a very simple structure provided with the element body including the element block part formed of a single metal block and the first element terminal part provided at one end of the element block part (only the first element terminal part without including the second element terminal part). Further, for example, in an audio system in which an amplifier output terminal of the audio amplifier circuit and a speaker input terminal of the speaker system are connected through a speaker cable, when the first element terminal part of the sound quality modification element is conductively connected to (i) the amplifier output terminal, (ii) the speaker input terminal, or (iii) the speaker cable (its midpoint), the inventor found that the sound quality of the sound to be emitted from the speaker of the speaker system can be modified. The detailed mechanism that the sound quality can be modified by the sound quality modification element connected in the above pattern is yet-to-be defined. However, when the sound quality modification element is conductively connected to a connection site (e.g., the amplifier output terminal, the speaker input terminal, or the midpoint of the speaker cable), a part of the sound signal output from the audio amplifier circuit travels by diverging into the sound quality modification element via the connection site. Therefore, it is conceived that, the above configuration can change the sound signal (electric signal) input to the speaker system through the speaker input terminal, thereby modifying the sound quality of the sound to be reproduced from the speaker system as compared with the configuration not incorporating the sound quality modification element.

Incidentally, as the connection method to connect the first element terminal part of the sound quality modification element to the amplifier output terminal and others, there are a method wherein the first element terminal part extending from the element block part is designed to have an open-tip (U-shaped) or round (O-shaped) terminal shape and this first element terminal part is directly connected to the the amplifier output terminal and others, a method wherein one end of the first connection cable is conductively connected to the first element terminal part and the other end of the first connection cable is connected to the amplifier output terminal and others.

Furthermore, the inventor prepares the sound quality modification element having a very simple structure provided with the element body including the element block part formed of a single metal block, the first element terminal part provided at one end of this element block part, and the second element terminal part provided at the other end of the element block part. For example, in an audio system in which an amplifier output terminal of the audio amplifier circuit and a speaker input terminal of the speaker system are connected to each other through a speaker cable, when both the first element terminal part and the second element terminal part of the sound quality modification element are conductively connected to (i) the same amplifier output terminal, (ii) the same speaker input terminal, or (iii) the same speaker cable (its midpoint), the inventor found that the sound quality of the sound (music pieces, etc.) to be emitted from the speaker system can be modified. The detailed mechanism that the sound quality can be modified by the sound quality modification element connected in the above pattern is also unclear. However, this sound quality modification element is connected to the connection site (the amplifier output terminal, the speaker input terminal, or the midpoint of the speaker cable, and others). This configuration allows a part of the sound signal output from the amplifier output terminal of the audio amplifier circuit to travel by diverging into the sound quality modification element via the connection site and further travel in a loop flow through a path from the first element terminal part, the element block part, and the second element terminal part in this order (or a reversed path) and return again to the connection site. Accordingly, it is conceived that the above-configured sound quality modification element can change the sound signal to be input to the speaker system through the speaker input terminal and modify the sound quality of sound reproduced from the speaker system, as compared with the configuration not using the sound quality modification element.

As the connection method to connect the first element terminal part and the second element terminal part to the amplifier output terminal and others, there is a method wherein one of the first element terminal part and the second element terminal part extending from the element block part is designed to have an open-tip (U-shaped) or round (O-shaped) terminal shape, and the one of the element terminal parts is directly connected to the connection site of the amplifier output terminal and others, while the other element terminal part of the element block part is connected to one end of the connection cable and the other end of the connection cable is connected to the same connection site. As another example, there is a method wherein the other end of the first connection cable whose one end is conductively connected to the first element terminal part and the other end of the second connection cable whose one end is conductively connected to the second element terminal part are connected to the same connection site, such as the same amplifier output terminal. In this case, when the first connection cable connected to the first element terminal part and the second connection cable connected to the second element terminal part are designed with the same length, the effect of sound modification by the sound quality modification element can be enhanced.

Furthermore, the inventor prepares the sound quality modification element having a very simple structure provided with the element body including the element block part formed of a single metal block, the first element terminal part provided at one end of this element block part, and the second element terminal part provided at the other end of the element block part. In an audio system in which an amplifier output terminal of the audio amplifier circuit and a speaker input terminal of the speaker system are connected to each other through a speaker cable, when the sound quality modification element is inserted in series in a transmission path of a sound signal (an electric signal) extending from the amplifier output terminal to the speaker input terminal through the speaker cable, the inventor found that the sound quality of the sound to be emitted from the speaker system can be modified. The connection pattern of this sound quality modification element may include for example a pattern that the first element terminal part of the sound quality modification element is connected to the amplifier output terminal of the audio amplifier circuit, while the second element terminal part of the sound quality modification element to an amp-side end of the speaker cable (which is usually connected to the amplifier output terminal of the audio amplifier circuit). Another example is a pattern that the first element terminal part of the sound quality modification element is connected to a speaker-side end of the speaker cable (which is usually connected to the speaker input terminal of the speaker system), while the second element terminal part of the sound quality modification element is connected to the speaker input terminal of the speaker system. Still another example is a pattern that the speaker cable is divided into a first speaker cable arranged on a side close to the amplifier and a second speaker cable arranged on a side close to the speaker, and the first element terminal part of the sound quality modification element is connected to a speaker-side end of the first speaker cable, while the second element terminal part of the sound quality modification element is connected to an amp-side end of the second speaker cable. The detailed mechanism that the sound quality can be modified by the sound quality modification element connected in the above pattern is also unclear. However, the sound quality modification element is connected in series to midpoints of a transmission path of a sound signal (an electric signal) extending from the amplifier output terminal of the audio amplifier circuit to the speaker input terminal of the speaker system via the speaker cable. Accordingly, it is conceived that the sound quality modification element configured as above can change the sound signal to be input to the speaker, thereby modifying the sound quality of sound to be reproduced by the speaker, as compared with the configuration not using the sound quality modification element.

The connection method to connect the first element terminal part and the second element terminal part to the amplifier output terminal and others may include a method wherein the first element terminal part and the second element terminal part extending from the element block part are each designed to have an open-tip (U-shaped) or round (O-shaped) terminal shape, and those element terminal parts are directly connected to the amplifier output terminal, the end of the speaker cable, and others. Another example is a method wherein that the other end of the first connection cable whose one end is conductively connected to the first element terminal part and the other end of the second connection cable whose one end is conductively connected to the second element terminal part are connected one to each of the amplifier output terminal, the end of the speaker cable, and others. The connection path extending from the audio amplifier circuit to the one or more speakers is a path in which a sound signal output from the audio amplifier circuit travels to the speaker(s). This connection path is conceived as being constituted of e.g. an output path from the audio amplifier circuit to the amplifier output terminal, a transmission path from the amplifier output terminal to the speaker input terminal of the speaker system, and an input path from the speaker input terminal to the single speaker or the speakers.

In this description, the sound range is referred to as a deep low range (16 to 40 Hz), a low range (40 to 160 Hz), a mid-low range (160 to 320 Hz), a mid-range (320 to 2600 Hz), a mid-high range (2600 to 5000 Hz), a high range (5000 to 10 kHz), and an ultra-high range (10 kHz or more) (see http://peanuts2.sakura.ne.jp/omotya/oto01.html).

In this sound quality modification element, the dimension of the element block part in the diametrical direction generally influences the range of a tone pitch (sound range) in which the sound quality modification effect that clearly emphasizes each tone is obtained, and the degree of this effect. Specifically, in the sound quality modification element in which the element block part has a relatively small diameter of the order of 5 to 15 mmφ, among music (music pieces or compositions) and the like to be reproduced by the speaker system, each tone in the mid-range (320 to 2600 Hz) to the mid-high range (2600 to 5000 Hz), such as voice sound and piano sound, is clearly emphasized; however, each tone in the deep low range (16 to 40 Hz) or the low range (40 to 160 Hz) is relatively lower in the degree of the sound quality modification effect than in the mid-range and the mid-high range.

However, for example, in the sound quality modification element in which the element block part has a relatively large diameter of 15 to 80 mmφ, the sound range in which the sound quality modification effect is produced extends over low tones, so that each tone is clearly emphasized not only in the mid-range and the mid-high range but also in the mid-low range (160 to 320 Hz) and further in the low range and the deep low range, and the degree of the sound quality modification effect increases. Furthermore, for example, in the sound quality modification element including the element block part having a larger diameter of 80 mmφ or more, the sound range in which the sound quality modification effect is obtained extends over low tones, so that each tone is clearly emphasized not only in the mid-range and the mid-high range but also in the low range and the deep low range, and the degree of the sound quality modification effect further increases. However, even when the element block part is designed with a diameter of greater than 200 mmφ, the sound quality modification element becomes large in body size and weight, but the sound quality modification effect is saturated (reaches the limit). Thus, the element block part is preferably designed with a diameter of 300 mmφ or less, preferably, about 200 mmφ or less.

In contrast, the dimension of the element block part in the length direction influences the degree of the sound quality modification. Specifically, as the length of the element block part is longer within a range of 5 mm or more, the degree of the sound quality modification that clearly emphasizes (more emphasizes) each tone (the sound quality modification effect) becomes larger in the sound range limited by the diameter. For example, in the case where the diameter of the element block part is set to 5 to 15 mmφ, as the length is longer beyond 5 mm, the sound quality modification effect that clearly emphasizes each tone is greater in the mid-range or the mid-high range (more emphasizes). In other words, the length is preferably set to 5 mm or more and, further, to 30 mm or more. However, in consideration of the body size and weight of the sound quality modification element, the length is preferably set to 200 mm or less. In the case where the diameter of the element block part is set to 15 to 80 mmφ, as the length is longer beyond 5 mm, the sound quality modification effect that clearly emphasizes each tone is greater not only in the mid-range and the mid-high range but also in the mid-low range, the low range, and the deep low range. In other words, the length is preferably set to 5 mm or more and, further, to 10 mm or more. However, in consideration of the body size and weight of the sound quality modification element, the length is preferably set to 50 mm or less. In the case where the diameter of the element block part is set to 80 to 400 mmφ, furthermore, as the length is longer beyond 5 mm, the the sound quality modification effect that clearly emphasizes each tone is greater not only in the mid-range and the mid-high range but also in the mid-low range, the low range, and the deep low range. In other words, the length is preferably set to 5 mm or more and, further, to 10 mm or more. However, in consideration of the body size and weight of the sound quality modification element, the length is preferably set to 30 mm or less.

The element block part of the sound quality modification element is formed of a single metal block. The materials of the element block part may include oxygen-free copper (JIS: C1020 (Cu 99.96% or more), C1011 (Cu 99.99% or more) etc.), pure aluminum (JIS: A1070 (Al 99.70% or more), A1080 (Al 99.80% or more), A1085 (Al 99.85% or more), A1100 (Al 99.00% or more), IN99 (Al 99.99% or more) etc.), aluminum alloy (JIS: A3003, A5052, etc.), stainless steel (JIS: SUS304, SUS310S, SUS430, etc.), and brass (JIS: C2600, C3560, etc.). For preventing corrosion and suppressing oxidation film formation or for improving the property, the element block part may also be applied with metal plating. For preventing corrosion and suppressing oxidation film formation, the element block part or the metal plating layer of the element block part may be coated with an insulating protective layer made of resin, such as enamel, or glass. Furthermore, in order to suppress the influence of external vibration on the sound quality modification element, the element block part or the metal plating layer of the element block part may be provided thereon with a vibration-proof layer for suppressing vibration transmission. Depending on the materials of the vibration-proof layer, this vibration-proof layer can also be used as the insulating protective layer. Further, the shape of the element block part may include a columnar shape, e.g., cylindrical, square prismatic, triangular prismatic, hexagonal prismatic, elliptical cylindrical, etc., shapes extending in the length direction. These shapes include a disc shape larger in diameter than in axial direction, e.g., a circular disc shape, a rectangular plate shape, and a hexagonal plate shape. In particular, the element block part is preferably designed in a cylindrical (circular-disc) shape that is isotropic in the diametrical direction. If the element block part is not isotropic in the diametrical direction, the diameter of the element block part is set twice the average radius obtained by measuring lengths from the axis to each point on the entire circumference.

The first element terminal part provided in the element block part is joined to or the first element terminal part and the second element terminal part are joined to the amplifier output terminal, the speaker input terminal, the speaker cable, or the ends (a bundle of strands) of the first connection cable and the second connection cable or the terminal member(s), such as crimping terminals formed at the ends, to electrically connect the element block part thereto. The first element terminal part and the second element terminal part each may include e.g. a male screw part protruding from the element block part in the length direction. Another example is a female screw part formed as a recess in the element block part. They may be designed to have an open-tip (U-shaped) terminal or a round (O-shaped) terminal protruding from the element block part in order to directly connect to the amplifier output terminal and speaker input terminal. As another example, they may be an annular protrusion cylindrically protruding from one end or the other end of the element block part. This annular protrusion is squashed after the end of a connection cable (a bundle of strands) is inserted in an inner recess of the protrusion, so that the bundle of strands is conductively crimped to the squashed annular protrusion. A portion of the element block part protruding from one end or the other end may be designed as a banana plug, a Y-plug, or a bullet terminal.

The first connection cable extending from the first element terminal part and the second connection cable extending from the second element terminal part only have to be long enough for conductive connection of each of the first element terminal part and the second element terminal part to the amplifier output terminal and others and thus is preferably set to 50 cm or less, more preferably, 30 cm or less.

The audio system incorporating the foregoing sound quality modification element may include an audio system in which an audio amplifier apparatus containing an audio amplifier circuit that outputs a sound signal in a frequency band of about 20 kHz or less is connected to one or a plurality of speaker systems through a speaker cable(s). Further, the sound quality modification element may be applied to a high-resolution audio system, suitable for a sound signal in a frequency band exceeding 40 kHz, in which an audio amplifier circuit is connected to one or more speaker systems through a speaker cable(s). The high-resolution audio system indicates an audio system having the property that can reproduce a sound signal of a digital sound source (e.g., PCM format: quantization 24 bits/sampling frequency of 96 kHz) higher in quality than conventional DC standards (PCM format: quantization 16 bits/sampling frequency of 44.1 kHz). In those audio systems, a pair of amplifier output terminals (a plus terminal (red) and a minus terminal (black)) of the audio amplifier circuit is connected to a pair of speaker input terminals (a plus terminal (red) and a minus terminal (black)) of the speaker system through a pair of speaker cables. Therefore, it is preferable to use one pair or plural pairs of sound quality modification elements so that the sound quality modification elements of the same number as the paired amplifier output terminals, the paired speaker input terminals, or the paired speaker cables, etc. are connected to those terminals or cables. While the sound quality modification effect decreases, one or a plurality of sound quality modification elements may be connected to one side, for example, connected to only one of the paired amplifier output terminals (e.g., connected to only the plus terminal), connected to only one of the paired speaker input terminals (e.g., connected to only the minus terminal), and so on. In a stereo audio system mentioned below, the sound quality modification elements are preferably arranged evenly for an L channel and an R channel. However, the number of sound quality modification elements and the type of sound quality modification elements may be consciously set different between the L channel and the R channel. This configuration can influence the localization of sounds perceivable by listeners, for example, displace the position of sound images to be localized, as compared with the configuration using the sound quality modification elements evenly arranged. The same applies to a multi-channel audio system mentioned below.

The audio amplifier apparatus of the audio system includes an audio amplifier apparatus for monaural, stereo, or multi-channel such as 5.1 ch surround. For example, in the stereo audio amplifier apparatus, generally, a pair of audio amplifier circuits corresponding to the R channel and the L channel are housed in a casing, and the wall of the casing is provided with a pair of amplifier output terminals, i.e., a plus terminal (red) and a minus terminal (black), per each channel. The audio amplifier circuit and the paired amplifier output terminals are connected through a pair of output paths.

The speaker system to be used in the audio system may include a speaker system constituted of a single speaker (a full-range speaker, etc.) and further a multi-way speaker system constituted of a plurality of speakers (speaker units) such as a woofer, a squawker, a tweeter, or the like and a network circuit board (a circuit board on which a network circuit, such as a low-pass filter and a high-pass filter, is mounted) provided in front of the speakers to connect to each speaker. The speaker system may include a speaker system configured such that a single speaker is housed, or alternatively, a plurality of speakers and a network circuit board are housed in a single speaker box (an enclosure), a speaker system configured such that a plurality of speakers connected to the network circuit board is housed in individual speaker boxes, and a speaker system, as with a car audio system, configured such that a plurality of speakers connected to a network circuit board is attached to several locations in a vehicle without using speaker boxes. The speaker system has generally two (a pair of) speaker input terminals. For example, the speaker system for an R channel and the speaker system for an L channel are each provided with a pair of speaker input terminals including a plus terminal (red) and a minus terminal (black) and a pair of input paths extending from the corresponding terminals to one or more speakers.

The sound quality modification element may be applied to a passive speaker system not including an audio amplifier circuit that drives the speaker(s) and also an active speaker system including an audio amplifier circuit, one or more speakers, and a speaker cable(s) connecting them in a single casing to reproduce voice sound input from a microphone or a separate analog/digital sound signal source, connected with or without wire. Furthermore, the sound quality modification element may be applied to a speaker-integrated player including: a sound signal acquisition part for obtaining a sound signal, such as a microphone part, a radio tuner part, a television tuner part, and a sound signal reproducing part for reproducing a sound signal recorded in a sound signal record medium (a record, a cassette tape, a CD, an MD, a DVD, a blue-ray disc (BD), a USB memory, an SD card, a hard disc, etc.); an audio amplifier part for amplifying the obtained sound signal; and a speaker part for reproducing voice sound from the amplified sound signal, these parts being contained in a single casing. One example of such a player may include an electronic megaphone, a portable radio cassette CD player, a portable CD radio player, and others.

(Second Item)

In the foregoing sound quality modification element, the element block part may be made of pure aluminum.

(Third Item)

Alternatively, in the sound quality modification element described in the first item, the element block part may be made of oxygen-free copper.

It has been found that even if the same music (music pieces, etc.) is reproduced, the sound quality modification effect varies depending on metal materials constituting the element block part and accordingly the sound quality of sound to be reproduced and emitted from the speaker system varies. For instance, when a sound quality modification element including an element block part having a diameter of 10 mmφ and a length of 42 mm is made of aluminum alloy (e.g., A5052), this sound quality modification element can achieve the same sound quality modification effect (the effect that each tone in the mid-range or the mid-high range is clearly emphasized) as compared with a sound quality modification element made of pure aluminum (e.g., A1070) or oxygen-free copper (e.g., C1020), but is somewhat inferior thereto in extension of each tone in the mid-high range. It also has been found that if a sound quality modification element is made of stainless steel (e.g., SUS304), this sound quality modification element is somewhat inferior in the sound quality modification effect (the effect that each tone in the mid-range or the mid-high range is clearly emphasized) to a sound quality modification element made of pure aluminum (e.g., A1070) or oxygen-free copper (e.g., C1020), and is apt to reproduce tight sound in the mid-high range. In contrast, in the foregoing sound quality modification element, the element block part is made of pure aluminum or oxygen-free copper. Accordingly, this sound quality modification element reproduces the sound with well-extended tones in the mid-high range and a soft sound quality, as compared with the element block part made of aluminum alloy, stainless steel, or others. The element block part made of pure aluminum is somewhat superior in property to the element block part made of oxygen-free copper.

Since the surface of the element block part made of pure aluminum is naturally formed with a thin layer made of aluminum oxide, the element block part can be used as it is. In addition, the element block part may be formed with an oxide film by anodization (so-called alumite treatment). Furthermore, the element block part may be protected with an insulating resin layer, such as an enamel layer, a glass layer, etc., and also provided with an insulating protective layer for preventing electrical conduction to other components. The surface of an element block part made of oxygen-free copper may be protected with an insulating resin layer, such as an enamel layer, a glass layer, etc. to suppress oxidation of the element block part (oxygen-free copper) to protect the element block part or alternatively may be provided with an insulating protective layer for preventing electrical conduction to other components. The resin layer, such as an enamel layer, may include layers made of polyvinyl formal, polyurethane, polyamide-imide, polyester, nylon, acryl, and others.

(Fourth Item)

Alternatively, in the sound quality modification element described in the first item, the element block part may be made of pure aluminum or oxygen-free copper, and the element block part may include a metal plating layer that covers over an entire surface of the element block part.

Since the element block part is formed with the metal plating layer, this element block part can further modify the sound quality as compared with an element block part not formed with any metal plating layer.

The metal plating layer provided to the element block part may include a silver plating layer, a tin plating layer, a nickel plating layer, a nickel-gold plating layer, a nickel-chrome plating layer, a zinc plating chromate conversion coating (unichrome plating) layer, and others. Optionally, the sound quality modification element may additionally be provided, on the metal plating layer, with an insulating resin layer such as an enamel layer, a glass layer, and others, to suppress oxidation of the metal plating layer and the element block part.

(Fifth Item)

Alternatively, in the sound quality modification element described in the fourth item, the metal plating layer may be an oxidation-resistant metal plating layer.

The above sound quality modification element with the metal plating layer made of oxidation-resistant metal can suppress oxidation of the element block part and the metal plating layer itself as compared with a sound quality modification element not provided with an oxidation-resistant metal plating layer, and thus can maintain the sound quality modification effect over a long period.

(Sixth Item)

Alternatively, in the sound quality modification element described in the fourth or fifth item, the metal plating layer may be a nickel plating layer.

The above sound quality modification element provided with the nickel plating layer as the metal plating layer can improve the oxidation resistance property of not only the element block part but also the metal plating layer, and further can reproduce clear tones in the deep low range, low range, mid-range, mid-high range and the sound balanced between the deep low range to low range and the mid-range to mid-high range, as compared with a sound quality modification element not provided with the metal plating layer.

(Seventh Item)

Alternatively, in the sound quality modification element described in the fourth or fifth item, the metal plating layer may be a nickel plating layer and a gold plating layer covering the nickel plating layer.

The above sound quality modification element provided with the nickel plating layer and the gold plating layer covering this nickel plating layer as the metal plating layer can improve the oxidation resistance of not only the element block part but also the metal plating layer. In addition, this sound quality modification element can reproduce each tone clearly in the deep low range, low range, mid-range, and mid-high range and also the sound balanced between the deep low range to low range and the mid-range to mid-high range, as compared with a sound quality modification element not provided with the metal plating layer. The above sound quality modification element is similar in sound quality to a sound quality modification element formed with only an electrolytic nickel plating layer, but can further emphasize each tone in the deep low range, low range, mid-range, and mid-high range.

(Eighth Item)

Alternatively, in the sound quality modification element described in the fourth or fifth item, preferably, the metal plating layer may be a nickel plating layer and a chrome plating layer covering the nickel plating layer.

This sound quality modification element provided with the nickel plating layer and the chrome plating layer covering the nickel plating layer as the metal plating layer can improve the oxidation resistance of not only the element block part but also the metal plating layer and further reproduce each tone clearly in the deep low range, low range, mid-range, and mid-high range and the sound balanced between the deep low range to low range and the mid-range to mid-high range, as compared with a sound quality modification element not provided with any metal plating layer. The above sound quality modification element is similar in sound quality to the sound quality modification element formed with the electrolytic nickel plating layer, but can further emphasize each tone in the deep low range and the low range, whereas it is inferior in tones in the mid-range and the mid-high range.

(Ninth Item)

Alternatively, in the sound quality modification element described in the fourth or fifth item, preferably, the metal plating layer is a tin plating layer.

The above sound quality modification element provided with a tin-nickel plating layer as the metal plating layer can improve the oxidation resistance of not only the element block part but also the metal plating layer, and further can reproduce each tone clearly in the deep low range, low range, mid-range, and mid-high range and the sound balanced between the deep low range to low range and the mid-range to mid-high range, as compared with a sound quality modification element not provided with any metal plating layer. Regarding the sound quality, each tone sounds softer in the deep low range, low range, mid-range, and mid-high range, as compared with the sound quality modification element formed with the electrolytic nickel plating layer alone.

(Tenth Item)

Alternatively, in the sound quality modification element described in the fourth item, preferably, the metal plating layer is a silver plating layer.

The above sound quality modification element in which the metal plating layer is the silver plating layer can reproduce each tone clearly in the deep low range, low range, mid-range, and mid-high range and the sound balanced between the deep low range to low range and the mid-range to mid-high range, as compared with the sound quality modification element not formed with any metal plating layer. The above sound quality modification element is inferior in the degree of emphasis of each tone in the mid-range and mid-high range, but can reproduce more emphasized tones in the deep low range and the low range, as compared with the sound quality modification element formed with the electrolytic nickel plating layer. Regarding the sound quality, each tone sounds softer in the deep low range and the low range, as compared with the sound quality modification element formed with the electrolytic nickel plating layer. Preferably, the sound quality modification element is provided with a resin layer such as an enamel layer, or a glass layer, to prevent oxidation of the silver plating layer.

(Eleventh Item)

The sound quality modification element described in one of the first to seventh and eighth to tenth items may further include a vibration-proof layer on a surface of the element block part or on the metal plating layer.

The above sound quality modification element is provided with the vibration-proof layer on the surface of the element block part or on the metal plating layer and thus can make clearer the sound to be reproduced by the speaker system. This seems because the vibration-proof layer can prevent the influence of vibration externally transmitted to the element block part.

The vibration-proof layer is a layer for suppressing transmission of vibration and may include a vibration-proof coating layer made of e.g. vibration-proof coating material applied on the surface of the element block part or the metal plating layer and a vibration-proof sheet made of vibration-proof material adhered on the metal plating layer or the like. The vibration-proof layer may be formed of a combination of the vibration-proof coating layer and the vibration-proof sheet. The vibration-proof layer may be formed on the surface of the element block part or on the metal plating layer and preferably formed on an element-side end of the connection cable connected to the element block part, a retaining nut, and the connection cable. Herein, the vibration-proof coating material may include materials that contain a large amount of fillers, such as silica sand, gypsum, fibers, and calcium carbonate in vehicles, such as asphalt-based, epoxy-based, phthalic acid-based, and emulsion-based vehicles. For example, the emulsion-based vibration-proof coating material may include NOXUDOL 3100 (made by AUSON). The vibration-proof sheet may include a foamed rubber sheet containing closed pores or semi-closed semi-continuous pores. Examples thereof are EPTSEALLER (made by Nitto Denko Corporation) and LEGETOLEX (made by Nitto Denko Corporation).

(Twelfth Item)

In the sound quality modification element described in one of the first to seventh, eighth to tenth, and eleventh items, the element body may be configured such that the element block part includes the first element terminal part without including the second element terminal part.

The sound quality modification element in this aspect is configured such that the element block part includes only the first element terminal part, from among the first element terminal part and the second element terminal part. This sound quality modification element can modify the sound quality of sound (music pieces, etc.) to be emitted from the speaker system for example by directly conductively connecting the first element terminal part or alternatively the other end of the first connection cable whose one end is connected to the first element terminal part to (i) the amplifier output terminal of the audio amplifier circuit, (ii) the speaker input terminal of the speaker system, or (iii) a midpoint of the speaker cable connecting between the amplifier output terminal and the speaker input terminal. Thus, the sound quality modification element is easier to connect as compared with the sound quality modification element including both the first element terminal part and the second element terminal part.

(Thirteenth Item)

In the sound quality modification element described in one of the first to seventh, eighth to tenth, and eleventh items, the element body may be configured such that the element block part includes the first element terminal part and the second element terminal part.

The above sound quality modification element is connected in series to the connection path within the connection path. For example, the sound quality modification element is connected in series to the speaker cable connecting the amplifier output terminal and the speaker input terminal. Specifically, the first element terminal part of this sound quality modification element is connected to the amplifier output terminal and the second element terminal part is connected to the speaker cable; the first element terminal part is connected to the amp-side first speaker cable and the second element terminal part is connected to the speaker-side second speaker cable; or alternatively, the first element terminal part is connected to the speaker cable and the second element terminal part is connected to the speaker input terminal. These configurations can modify the sound quality of sound (music pieces, etc.) to be emitted from the speaker system. Alternatively, the sound quality modification element in this aspect is configured such that both the first element terminal part and the second element terminal part are connected to the same connection site in the connection path. For example, those element terminal parts are conductively connected to (i) the same amplifier output terminal of the audio amplifier circuit, (ii) the same speaker input terminal, or (iii) the same midpoint of the speaker cable. These configurations can also modify the sound quality of sound (music pieces, etc.) to be emitted from the speaker system.

In this sound quality modification element, the first element terminal part is directly connected to or alternatively connected through the first connection cable whose one end is connected to the first element terminal part to for example the amplifier output terminal, the speaker cable, and others. Further, the second element terminal part is directly connected to or alternatively connected through the second connection cable whose one end is connected to the second element terminal part to the speaker cable, the speaker input terminal, and others. Alternatively, both the first connection cable whose one end is connected to the first element terminal part and the second connection cable whose one end is connected to the second element terminal part are connected to for example the same amplifier output terminal, the same midpoint of the same speaker cable, or the same speaker input terminal in use. In this case, when the first connection cable and the second connection cable are designed with the same length, the sound quality modification element can more easily provide the sound quality modification effect.

(Fourteenth Item)

The sound quality modification element described in the thirteenth item preferably includes a first connection cable whose one end is conductively connected to the first element terminal part, a second connection cable whose one end is conductively connected to the second element terminal part, and a terminal member constituted of the other end of the first connection cable and the other end of the second connection cable conductively connected to each other and tied in a bundle.

This sound quality modification element includes the terminal member formed of the other end of the first connection cable and the other end of the second connection cable that are conductively tied in a bundle. Thus, this terminal member has only to be connected to the amplifier output terminal, the same portion of the speaker cable, or the speaker input terminal to complete connection of the sound quality modification element to any of those components, and therefore the sound quality modification element can be easily connected thereto.

The terminal member may be selected in consideration of the configurations of the amplifier output terminal and others to which the terminal member is connected and for example may include a terminal member using a tip-open (U-shaped) or round (O-shaped) crimping terminal whereby the other end of the first connection cable and the other end of the second connection cable are tied in a bundle so as to conductively connect to each other by crimping.

(Fifteenth Item)

An audio system may include: the one or the plurality of sound quality modification elements described in the twelfth item; the audio amplifier circuit; and a speaker system including the one or the plurality of speakers, wherein the first element terminal part of the one or the plurality of sound quality modification elements is connected to a connection site in a transmission path extending from an amplifier output terminal of the audio amplifier circuit to a speaker input terminal of the speaker system. Concretely, the audio system is preferably provided with: the one or more sound quality modification elements described in the eleventh item; the audio amplifier circuit; the speaker system including the one or more speakers; and a speaker cable connecting the amplifier output terminal of the audio amplifier circuit and the speaker input terminal of the speaker system, wherein the first element terminal part(s) of the one or more sound quality modification elements is connected to the amplifier output terminal(s), the speaker input terminal(s), or a midpoint(s) of the speaker cable(s).

This audio system includes the sound quality modification element(s) including the first element terminal part(s) connected to a connection site(s) within the transmission path(s), concretely, to the amplifier output terminal(s), the speaker input terminal(s), or the midpoint(s) of the speaker cable(s). Accordingly, the audio system incorporating the sound quality modification element(s) can modify the sound quality of the sound (music pieces, etc.) to be reproduced by the speaker system so that each tone of each instrument is clearly emphasized in the high range, low range, and others, from among the sounds to be emitted from the speaker system, according to the dimension of the element block part(s), as compared with an audio system not provided with the sound quality modification element(s). When the first element terminal parts of the sound quality modification elements are connected one to each of the connection sites in the transmission paths, the sound quality modification effect by each sound quality modification element is superimposed, so that the sound quality of the sound (music pieces, etc.) to be reproduced by the speaker system can be greatly modified. The sound quality modification elements to be connected may be designed such that the element block parts are either the same or different in dimension.

The audio system may be configured such that the first element terminal part(s) of the sound quality modification element(s) is connected to the amplifier output terminal(s), to the speaker input terminal(s), or to the midpoint(s) of the speaker cable(s).

(Sixteenth Item)

An audio system may include: the one or the plurality of sound quality modification elements described in the thirteenth item; the audio amplifier circuit; and a speaker system including the one or the plurality of speakers, wherein the first element terminal part and the second element terminal part of the one or the plurality of sound quality modification elements are connected to a same connection site in a transmission path extending from an amplifier output terminal of the audio amplifier circuit to a speaker input terminal of the speaker system. Concretely, the audio system is preferably provided with: the one or more of sound quality modification elements described in the thirteenth item; the audio amplifier circuit; the speaker system including the one or more speakers; and a speaker cable connecting the amplifier output terminal of the audio amplifier circuit and the speaker input terminal of the speaker system, wherein the first element terminal part(s) and the second element terminal part(s) of the one or more sound quality modification elements are preferably connected to the same amplifier output terminal(s), the same speaker input terminal(s), or the same midpoint(s) of the speaker cable(s).

This audio system includes the sound quality modification element configured such that the first element terminal part(s) and the second element terminal part(s) are connected to the same connection site(s) within the transmission path(s), concretely, to the same amplifier output terminal(s), the same speaker input terminal(s), or the same midpoint(s) of the speaker cable(s). Accordingly, the audio system incorporating the sound quality modification element(s) can modify the sound quality of the sound (music pieces, etc.) to be reproduced by the speaker system so that each tone of each instrument is clearly emphasized in the high range, low range, and others, from among the sounds to be emitted from the speaker system, according to the dimension of the element block part(s), as compared with an audio system not provided with the sound quality modification element(s). When the first element terminal parts and the second element terminal parts of the sound quality modification elements are connected one to each of the same connection sites in the transmission paths, the sound quality modification effect by each sound quality modification element is superimposed, so that the sound quality of sound (music pieces, etc.) to be reproduced by the speaker system can be greatly modified. The sound quality modification elements to be connected may be designed such that the element block parts are either the same or different in dimension.

(Seventeenth Item)

Alternatively, an audio system may include: the plurality of sound quality modification elements described in the thirteenth item, the plurality of sound quality modification elements being connected in series to each other; the audio amplifier circuit; and a speaker system including the one or the plurality of speakers, wherein unconnected one of the first element terminal parts and unconnected one of the second element terminal parts of the plurality of sound quality modification elements connected in series to each other are connected to a same connection site in a transmission path extending from an amplifier output terminal of the audio amplifier circuit to a speaker input terminal of the speaker system. Concretely, the audio system is preferably provided with: the plurality of sound quality modification elements described in the thirteenth item, connected in series to each other; the audio amplifier circuit; the speaker system containing the one or more speakers; and a speaker cable connecting the amplifier output terminal of the audio amplifier circuit and the speaker input terminal of the speaker system, wherein unconnected one of the first element terminal part and unconnected one of the second element terminal part of the sound quality modification elements connected in series to each other are preferably connected to the same amplifier output terminal(s), the same speaker input terminal(s), or the same midpoint(s) of the speaker cable(s).

In this audio system, a plurality of sound quality modification elements each including an element block part having a first element terminal part at one end and a second element terminal part at the other end is used in a way that the sound quality modification elements are connected in series to each other, that is, the second element terminal parts of the sound quality modification elements are connected to the first element terminal parts of other sound quality modification elements. Further, the unconnected one of the first element terminal parts and the unconnected one of the second element terminal parts, the unconnected ones being located at both ends in a string of the sound quality modification elements connected in series to each other, are connected to the same connection site(s) in the transmission path(s), e.g., to the same midpoint(s) of the speaker cable(s). This audio system can superimpose the sound quality modification effect by each sound quality modification element and greatly modify the sound quality of sound (music pieces, etc.) to be reproduced by the speaker system. The sound quality modification elements connected in series may be designed such that the element block parts are either the same or different in dimension.

(Eighteenth Item)

Alternatively, preferably, an audio system includes: the one or the plurality of sound quality modification elements described in the fourteenth item; the audio amplifier circuit; and a speaker system including the one or more speakers, wherein the terminal member(s) of the one or more sound quality modification elements is connected to a connection site(s) in the transmission path(s) extending from the amplifier output terminal of the audio amplifier circuit to the speaker input terminal of the speaker system. Concretely, the audio system is preferably provided with: the one or more sound quality modification elements described in the fourteenth item; the audio amplifier circuit; and the speaker system including the one or more speakers; and the speaker cable connecting the amplifier output terminal of the audio amplifier circuit and the speaker input terminal of the speaker system, wherein the terminal member(s) of the one or more sound quality modification elements is connected to the amplifier output terminal(s), the speaker input terminal(s), or the midpoint(s) of the speaker cable.

This audio system incorporating the sound quality modification element(s) can also modify the sound quality of sound (music pieces, etc.) to be reproduced by the speaker system so that each tone of each instrument is clearly emphasized in the high range, low range, and others, from among the sounds to be emitted from the speaker system, according to the dimension of the element block part(s), as compared with an audio system not provided with the sound quality modification element(s). When the terminal members of the sound quality modification elements are connected one to each of the connection sites such as the midpoints of the speaker cable, the sound quality modification effect by each sound quality modification element is superimposed, so that the sound quality of sound (music pieces, etc.) to be reproduced by the speaker system can be greatly modified. The sound quality modification elements to be connected may be designed such the element block parts are either the same or different in dimension.

(Nineteenth Item)

Alternatively, an audio system may include: the one or the plurality of sound quality modification elements described in the thirteenth item, the plurality of sound quality modification elements being connected in series to each other; the audio amplifier circuit; and a speaker system including the one or the plurality of speakers, wherein the one or the plurality of sound quality modification elements connected in series to each other are connected in series in a transmission path extending from an amplifier output terminal of the audio amplifier circuit to a speaker input terminal of the speaker system by use of unconnected one of the first element terminal parts and unconnected one of the second element terminal parts. Concretely, the audio system may include: the one or the plurality of sound quality modification elements described in the thirteenth item, the plurality of sound quality modification elements being connected in series to each other; the audio amplifier circuit; the speaker system including the one or more speakers; and the speaker cable connecting the amplifier output terminal of the audio amplifier circuit and the speaker input terminal of the speaker system, wherein (i) unconnected one of the first element terminal part(s) of the one or more sound quality modification elements connected in series to each other is connected to the amplifier output terminal and unconnected one of the second element terminal part(s) is connected to an end of the speaker cable(s) on a side close to the audio amplifier circuit, (ii) unconnected one of the first element terminal part(s) of the one or more sound quality modification elements connected in series to each other is connected to an end of the speaker cable on a side close to the speaker system and unconnected one of the second element terminal part(s) is connected to the speaker input terminal of the speaker system, or (iii) the speaker cable includes a first speaker cable on the side close to the audio amplifier circuit and a second speaker cable on the side close to the speaker system, and unconnected one of the first element terminal part(s) of the one or more sound quality modification elements connected in series to each other is connected to a speaker-side end of the first speaker cable and unconnected one of the second element terminal part(s) is connected to an amp-side end of the speaker cable.

This audio system incorporating the one or more sound quality modification elements connected in series to each other can also modify the sound quality of sound (music pieces, etc.) to be reproduced by the speaker system so that each tone of each instrument is clearly emphasized in the high range, low range, and others, from among the sounds to be emitted from the speaker system, according to the dimension of the element block part(s), as compared with an audio system not provided with the sound quality modification element(s). When the sound quality modification elements connected in series to each other are used, the sound quality modification effect by each sound quality modification element is superimposed, so that the sound quality of sound (music pieces, etc.) to be reproduced by the speaker system can be greatly modified. The sound quality modification elements to be used may be designed such that the element block parts are either the same or different in dimension.

(Twentieth Item)

An audio amplifier apparatus may include the one or the plurality of sound quality modification elements described in the twelfth, thirteenth, or fourteenth item; the audio amplifier circuit including an amplifier output terminal, wherein (i) the first element terminal part of the one or the plurality of sound quality modification elements is connected to a connection site in an output path extending from the audio amplifier circuit to the amplifier output terminal, (ii) the first element terminal part and the second element terminal part of the one or the plurality of sound quality modification elements are connected to a same connection site in an output path extending from the audio amplifier circuit to the amplifier output terminal, or (iii) the audio amplifier apparatus further includes an output path extending from the audio amplifier circuit to the amplifier output terminal, and the one or the plurality of sound quality modification elements connected in series to each other are connected in series within the output path by use of unconnected one of the first element terminal parts and unconnected one of the second element terminal parts. Concretely, the audio amplifier apparatus equipped with a sound quality modification element preferably includes the one or more sound quality modification elements described in the twelfth item and the audio amplifier circuit including the amplifier output terminal, wherein the first element terminal part(s) of the one or more sound quality modification elements is connected to the connection site(s) in the output path(s) extending from the audio amplifier circuit to the amplifier output terminal. Alternatively, the audio amplifier apparatus equipped with a sound quality modification element preferably includes the one or more sound quality modification elements described in the thirteenth item and the audio amplifier circuit including the amplifier output terminal, wherein the first element terminal part(s) and the second element terminal part(s) of the one or more sound quality modification elements are connected to the same connection site(s) in the output path(s) extending from the audio amplifier circuit to the amplifier output terminal. Alternatively, the audio amplifier apparatus equipped with a sound quality modification element preferably includes the one or more sound quality modification elements described in the fourteenth item and the audio amplifier circuit including the amplifier output terminal, wherein the terminal member(s) of the one or more sound quality modification elements is connected to the connection site(s) in the output path(s) extending from the audio amplifier circuit to the amplifier output terminal. Alternatively, the audio amplifier apparatus equipped with a sound quality modification element preferably includes the one or more sound quality modification elements described in the thirteenth item and the audio amplifier circuit including the amplifier output terminal, and further includes an output path(s) extending from the audio amplifier circuit to the amplifier output terminal, wherein the one or more sound quality modification elements connected in series to each other are connected in series within the output path(s) by use of unconnected one of the first element terminal parts and unconnected one of the second element terminal parts.

When those audio amplifier apparatus equipped with a sound quality modification element are used by connecting the amplifier output terminal of the audio amplifier circuit to the speaker input terminal of the speaker system through the speaker cable(s) as usual, they can emit the quality-modified sound from the speaker system as compared with an apparatus not using the sound quality modification element(s). When the sound quality modification elements are connected to the output path(s), the sound quality modification effect by each sound quality modification element is superimposed, so that the sound quality of sound (music pieces, etc.) to be reproduced by the speaker system can be greatly modified. The sound quality modification elements to be connected may be designed so that the element block parts are either the same or different in dimension.

In the above audio amplifier apparatus equipped with a sound quality modification element, the sound quality modification elements may be connected one to each of the paired output paths extending from the audio amplifier circuit to the paired amplifier output terminals (a plus terminal and a minus terminal). For example, in a stereo (2ch) audio amplifier apparatus provided with a pair of audio amplifier circuits (for an R channel and an L channel), two pairs of output paths extending from the paired audio amplifier circuits to the paired amplifier output terminals (a plus terminal (a red terminal) and a minus terminal (a black terminal)). Thus, the sound quality modification elements may be connected to the two pairs of output paths (i.e., four output paths); for example, each sound quality modification element for each output path (i.e., total four sound quality modification elements) or each group of sound quality modification elements for each output path (i.e., total four groups of sound quality modification elements). However, the sound quality modification element(s) may be connected to only an output path extending to the plus terminal of the paired amplifier output terminals (e.g., one sound quality modification element for one output path, i.e., total two sound quality modification elements), even though this configuration decreases the sound quality modification effect. Alternatively, the sound quality modification element(s) may be connected to only an output path extending to the minus terminal. Alternatively, in order to influence the localization of sounds perceivable by listeners, for example, to displace the position of sound images to be localized, the number of sound quality modification elements and the type of sound quality modification elements may be consciously set different between the L channel and the R channel. The amplifier apparatus with a sound quality modification element may be configured such that the sound quality modification element(s) is placed in an amplifier casing enclosing the audio amplifier circuit.

(Twenty-First Item)

A speaker system equipped with a sound quality modification element may include: the one or the plurality of sound quality modification elements described in the twelfth, thirteenth, or fourteenth item; the speaker system including a speaker input terminal, wherein (i) the first element terminal part of the one or the plurality of sound quality modification elements is connected to a connection site in an input path extending from the speaker input terminal of the speaker system to the one or the plurality of speakers, (ii) the first element terminal part and the second element terminal part of the one or the plurality of sound quality modification elements are connected to a same connection site in an input path extending from the speaker input terminal of the speaker system to the one or the plurality of speakers, or (iii) the speaker system further includes an input path extending from the speaker input terminal to the one or the plurality of speakers, and the one or the plurality of sound quality modification elements connected in series to each other are connected in series in the input path by use of unconnected one of the first element terminal parts and unconnected one of the second element terminal parts. Concretely, the speaker system equipped with a sound quality modification element may include the one or more sound quality modification elements described in the twelfth item and the speaker system including the speaker input terminal, wherein the first element terminal part(s) of the one or more or sound quality modification elements is connected to the connection site(s) in the input path(s) extending from the speaker input terminal of the speaker system to one or more speakers. Alternatively, the speaker system equipped with a sound quality modification element may include the one or more sound quality modification elements described in the thirteenth item and the speaker system including the speaker input terminal, wherein the first element terminal part(s) and the second element terminal part(s) of the one or more sound quality modification elements are connected to the same connection site(s) in the input path(s) extending from the speaker input terminal of the speaker system to the one or more speakers. Alternatively, the speaker system equipped with a sound quality modification element may include the one or more sound quality modification elements described in the fourteenth item and the speaker system including the speaker input terminal, wherein the terminal member(s) of the sound quality modification element(s) is connected to the connection site(s) in the input path extending from the speaker input terminal of the speaker system to the one or more speakers. Alternatively, the speaker system equipped with a sound quality modification element may include the one or more sound quality modification elements connected in series to each other described in the thirteenth item and the speaker system including the speaker input terminal, and further include an input path extending from the speaker input terminal to the one or more speakers, wherein the the one or more sound quality modification elements connected in series to each other are connected in series within the input path(s) by use of unconnected one of the first element terminal parts and unconnected one of the second element terminal parts.

When those speaker systems equipped with a sound quality modification element are used by connecting the amplifier output terminal of the audio amplifier circuit to the speaker input terminal of the speaker system through the speaker cable(s) as usual, they can emit the quality-modified sound from the speaker system as compared with an apparatus not using the sound quality modification element(s). When the sound quality modification elements are connected to the input path(s), the sound quality modification effect by each sound quality modification element is superimposed, so that the sound quality of sound (music pieces, etc.) to be reproduced by the speaker system can be greatly modified. The sound quality modification elements to be connected may be designed so that the element block parts are either the same or different in dimension.

In the above speaker system for one channel including one or more speakers, there is generally provided a pair of speaker input terminals (each pair including two terminals, that is, a plus terminal (a red terminal) and a minus terminal (a black terminal)). In the foregoing speaker system equipped with a sound quality modification element, the sound quality modification elements may be connected one to each of the paired input paths extending from the paired speaker input terminals of the speaker system to one speaker or to plural speakers via a network circuit; for example, one sound quality modification element for one input path, i.e., total two sound quality modification elements, or one group of sound quality modification elements for one input path, i.e., total two groups of sound quality modification elements. However, the sound quality modification element may be connected to only an input path extending from the plus terminal of the paired (two) speaker input terminals (e.g., one sound quality modification element or one group of sound quality modification elements for one input path). Alternatively, the sound quality modification element may be connected to only an input path extending from only the minus terminal. The speaker system equipped with a sound quality modification element may be configured such that the sound quality modification element(s) is placed in a speaker box provided to the speaker system.

### BRIEF DESCRIPTION OF THE DRAWINGS

FIG. 1 is an explanatory view showing a configuration of an audio system using a series connection type sound quality modification element in a first embodiment;

FIG. 2A is an explanatory view showing a shape of an element body of a sound quality modification element used in an audio system in first to third embodiments and a seventh modified embodiment and a sound quality modification element used in a second embodiment;

FIG. 2B is an explanatory view showing a shape of a sound quality modification element used in the audio system in the first embodiment and the seventh and thirteenth modified embodiments;

FIG. 2C is an explanatory view showing a shape of a sound quality modification element used in the audio system in the third embodiment;

FIG. 3A is an explanatory view showing a configuration of the audio system using a series connection type sound quality modification element in the second embodiment;

FIG. 3B is an explanatory view showing a configuration of the audio system using a plurality of series connection type sound quality modification elements in the seventh modified embodiment;

FIG. 4 is an explanatory view showing showing a configuration of the audio system using a series connection type sound quality modification element in the third embodiment;

FIG. 5 is an explanatory view showing a configuration of an audio system using a one-end connection type sound quality modification element in a fourth embodiment;

FIG. 6A is an explanatory view showing a shape of an element body of the one-end connection type sound quality modification element used in the audio systems in the fourth to sixth embodiments;

FIG. 6B is an explanatory view showing a shape of the one-end connection type sound quality modification element used in the audio systems in the fourth to sixth embodiments and eighth, ninth, and twelfth modified embodiments;

FIG. 7A is an explanatory view showing a configuration of an audio system using the one-end connection type sound quality modification element in a fifth embodiment;

FIG. 7B is an explanatory view showing a configuration of the audio system using a plurality of the one-end connection type sound quality modification elements in the eighth modified embodiment;

FIG. 7C is an explanatory view showing a configuration of the audio system using the one-end connection type sound quality modification elements arranged unevenly for right and left channels in the ninth modified embodiment;

FIG. 8 is an explanatory view showing a configuration of the audio system using the one-end connection type sound quality modification element in the sixth embodiment;

FIG. 9 is an explanatory view showing a configuration of an audio system using a loop connection type sound quality modification element in a seventh embodiment;

FIG. 10A is an explanatory view showing a shape of the loop connection type sound quality modification element used in the seventh to eleventh embodiments and first, fourth, tenth, eleventh, thirteenth, and fourteenth modified embodiments;

FIG. 10B is an explanatory view showing a shape of a sound quality modification element usable in the audio systems in the seventh to eleventh embodiments and first, fourth, tenth, eleventh, thirteenth, and fourteenth modified embodiments;

FIG. 10C is an explanatory view showing a shape of a sound quality modification element usable in the audio systems in the seventh to eleventh embodiments and first, fourth, tenth, eleventh, thirteenth, and fourteenth modified embodiments;

FIG. 11A is an explanatory view showing a configuration of an audio system using the loop connection type sound quality modification element in an eighth embodiment;

FIG. 11B is an explanatory view showing a configuration of the audio system using a plurality of the loop connection type sound quality modification elements in the tenth modified embodiment;

FIG. 11C is an explanatory view showing a configuration of the audio system using the loop connection type sound quality modification elements arranged unevenly for right and left channels in the eleventh modified embodiment;

FIG. 11D is an enlarged explanatory view showing a configuration of the audio system in which a plurality of sound quality modification elements connected in series is connected in a loop form to a speaker cable in the twelfth modified embodiment;

FIG. 12 is an explanatory view showing a configuration of an audio system using the loop connection type sound quality modification element in a ninth embodiment;

FIG. 13A is an explanatory view showing a configuration of an audio amplifier apparatus equipped with a sound quality modification element and the audio system using the loop connection type sound quality modification element in the first modified embodiment;

FIG. 13B is an explanatory view showing a configuration of an audio amplifier apparatus equipped with a sound quality modification element, using the loop connection type sound quality modification element in the thirteenth modified embodiment;

FIG. 14 is an explanatory view showing a configuration of an audio amplifier apparatus equipped with a sound quality modification element, using the one-end connection type sound quality modification element in a second modified embodiment;

FIG. 15 is an explanatory view showing a configuration of an audio amplifier apparatus equipped with a sound quality modification element and an audio system, using the series connection type sound quality modification element in a third modified embodiment;

FIG. 16A is an explanatory view showing a configuration of an audio amplifier apparatus equipped with a sound quality modification element and the audio system, using the loop connection type sound quality modification element in the fourth modified embodiment;

FIG. 16B is an explanatory view showing a configuration of an audio amplifier apparatus equipped with a sound quality modification element and the audio system, using the loop connection type sound quality modification element in the fourteenth modified embodiment;

FIG. 17 is an explanatory view showing a configuration of a speaker system equipped with a sound quality modification element and an audio system, using the one-end connection type sound quality modification element in a fifth modified embodiment;

FIG. 18 is an explanatory view showing a configuration of a speaker system equipped with a sound quality modification element and an audio system, using the series connection type sound quality modification element in a sixth modified embodiment;

FIG. 19 is an explanatory view showing a configuration of an audio system using a sound quality modification element on only a plus terminal side in a tenth embodiment;

FIG. 20 is an explanatory view showing a configuration of the audio system using a sound quality modification element on only a minus terminal side in the eleventh embodiment; and

FIG. 21 is an explanatory view showing a configuration of an audio system of a basic configuration.

### MODE FOR CARRYING OUT THE INVENTION

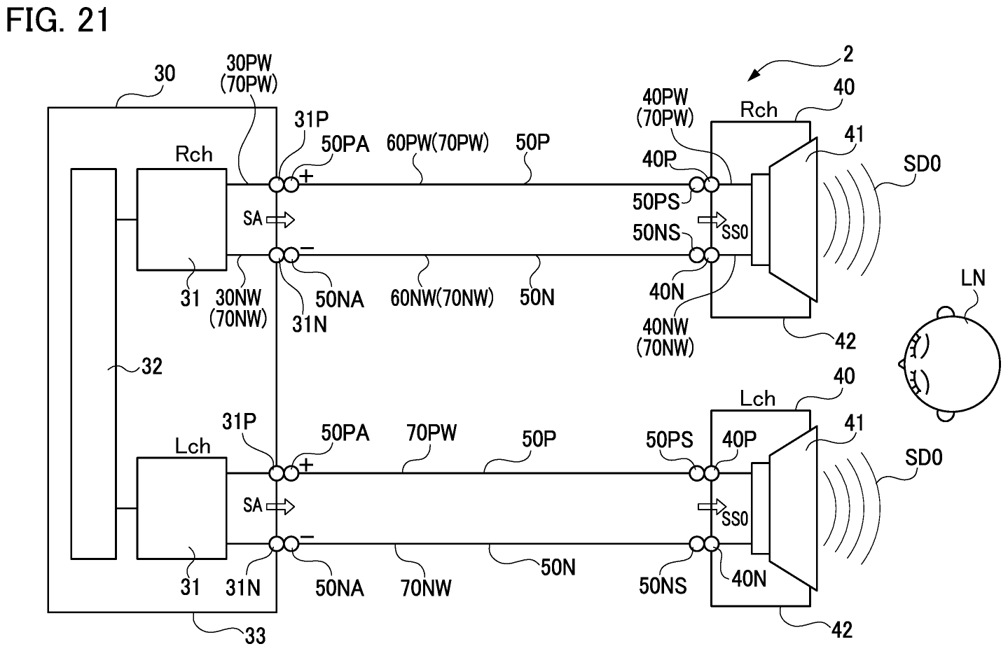

A basic configuration of a stereo audio system 2 (hereinafter, simply referred to as a system) in which a sound quality modification element 10A and others mentioned below are not yet incorporated will be described first (see FIG. 21). The system 2 of this basic configuration and a system 20 and others incorporating the sound quality modification element 10A and others in first to eleventh embodiments and first to fourteenth modified embodiments each include a stereo audio amplifier (hereinafter, also simply referred to as an amplifier or amp) 30 and others, a pair of (two) speaker systems 40 and others, and two pairs of (four) speaker cables (hereinafter, also simply referred to as a cable) 50P, 50N (150P, 150N) connecting the amplifier and the speaker systems.

The amplifier 30 is provided with a CD drive part 32 configured to drive a music CD (a compact disc) put in an amplifier casing 33 by a listener LN to obtain a pair of sound signals for a right channel and a left channel, and two (a pair of) audio amplifier circuits 31 (hereinafter, also simply referred to as an amplifier circuit or amplifier circuits) configured to amplify each obtained sound signal for each channel and output a sound signal SA from a pair of amplifier output terminals 31P and 31N. This pair of amplifier output terminals 31P and 31N of each amplifier circuit 31 is fixed to the amplifier casing 33 to enable external connection.

In contrast, the pair of speaker systems 40 each contain a single speaker (a full-range speaker) 41 in a speaker box (enclosure) 42. The terminals of this speaker 41, that is, speaker input terminals 40P, 40N of the speaker system 40 are fixed to the speaker box 42 to enable external connection. Further, the two pairs of amplifier output terminals 31P, 31N of the amplifier 30 are connected to the two pairs of speaker input terminals 40P, 40N of the paired speaker systems 40 through the two pairs of cables 50P, 50N (150P, 150N). The sound signals SA output from the amplifier 30 are thus input as sound signals SS0 into the speakers 41 and reproduced as sound (voice sound) SD0.

In the system 2, 20, and others in the basic configuration, each embodiment, and each modified embodiment, the amplifier circuits 31 and the speakers 41 may be connected through connection paths 70PW, 70NW extending from the amplifier circuits 31 to the speakers 41. The sound signals SA output from the amplifier circuits 31 travel through those connection paths 70PW, 70NW to the speakers 41. In the system 2, 20, and others in the basic configuration, each embodiment, and each modified embodiment, each connection path 70PW, 70NW includes separate paths, i.e., an output path 31PW, 31NW extending from the amplifier circuit 31 to the amplifier output terminal 31P, 31N, a transmission path 60PW, 60NW extending from the amplifier output terminal 31P, 31N to the speaker input terminal 40P, 40N of the speaker system 40, and an input path 40PW, 40NW extending from the speaker input terminal 40P, 40N to the speaker 41. The system 20 and others in the first to eleventh embodiments and seventh to twelfth modified embodiments from among the following embodiments and modified embodiments are each configured such that the sound quality modification element 10A and others are connected within the transmission paths 60PW, 60NW. In contrast, a system 320 and others in the first to third and thirteenth modified embodiments are each configured such that the sound quality modification element 10A and others are connected in the output paths 31PW, 31NW. Further, a system 323 and others in the fourth to sixth and fourteenth modified embodiments are each configured such that the sound quality modification element 10A and others are connected in the input paths 40PW, 40NW.

(Series Connection Type Sound Quality Modification Element)

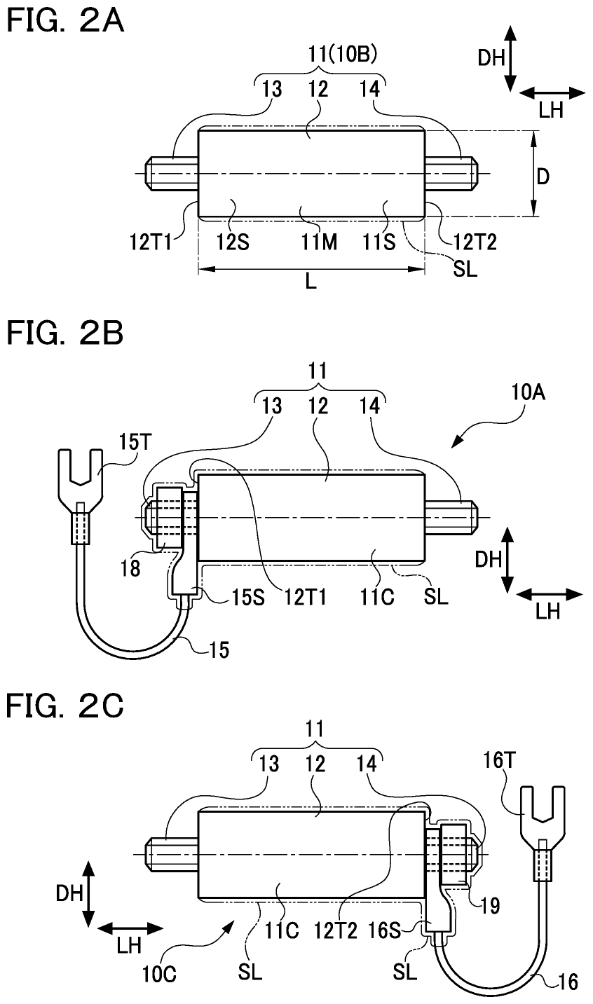

Series connection type sound quality modification elements 10A, 10B, and 10C used in the first to third embodiments and the seventh modified embodiment will be described first with reference to FIGS. 2A, 2B, and 2C. The sound quality modification element 10A (see FIG. 2B) includes an element body 11 and a first connection cable 15. The sound quality modification element 10B (see FIG. 2A) includes only the element body 11. The sound quality modification element 10C (see FIG. 2C) includes the element body 11 and a second connection cable 16. The sound quality modification element 10B is also used in the third and sixth modified embodiments which will be mentioned later.

The element body 11 (see FIG. 2A) is formed of a single metal block (e.g., an oxygen-free copper block) and includes an element block part 12 having a round-columnar shape, a first element terminal part 13 having a male screw shape protruding from a first end face 12T1 that is one end face (a left end in the figure) of the element block part 12, and a second element terminal part 14 having a male screw shape protruding from a second end face 12T2 that is the other end face (a right end in the figure) of the element block part 12.

The element block part 12 has a round-columnar or circular-disk shape with a diameter D of 5 mm or more in a diametrical direction DH (a vertical direction in the figure) and a length L of 5 mm or more in a length direction LH (a lateral direction in the figure) perpendicular to the diametrical direction DH. For example, the element block part 12 has a round-columnar shape with a diameter D of 10 mm and a length L of 42 mm.

Depending on the diameter D and the length L of the element block part 12, as mentioned later, the sound range to be modified and the degree of modification obtained by connection of the sound quality modification element 10A and others are changed.

In the system incorporating such a sound quality modification element 10A and others including the element block part 12 having for example a round columnar shape with a diameter D of 10 mm and a length L of 42 mm, the sound SD to be emitted from the speaker system 40 (the sound such as music pieces and singing voice sound reproduced from a CD put in a CD drive) can be modified to the sound that each tone of each instrument and voice sound in a relatively high range is clearly emphasized, as compared with the sound SD0 obtainable by the system 2 in the basic configuration not using the sound quality modification element 10A and others. More concretely, regarding the music (music pieces) and others to be reproduced from the speaker system, such as voice sound and piano sound, tones in the mid-range (320 to 2600 Hz) to the mid-high range (2600 to 5000 Hz) are each distinctly emphasized. As the diameter D of the element block part 12 of each sound quality modification element 10A and others is set larger, the sound quality modification effect is obtained such that each tone not only in the mid-range and mid-high range but also in the mid-low range (160 to 320 Hz) and further in the low range (40 to 160 Hz) and deep low range (16 to 40 Hz) is more clearly emphasized. Furthermore, the longer the length L of the element block part 12 of each sound quality modification element 10A and others, the greater the degree of the sound quality modification that clearly emphasizes each tone in sound ranges limited by the diameter D.

The first connection cable 15 includes end parts 15S and 15T formed of U-shaped crimping terminals joined to both ends of a cable (a bundle of strands). The end part 15S on a side close to an element (“element-side end part”) is pressed against and conductively connected to the first end face 12T1 of the element block part 12 with a retaining nut 18 screwed onto the first element terminal part 13. The length of the first connection cable 15 only has to be long enough to conductively connect the first element terminal part 13 of the sound quality modification element 10A to the amplifier output terminal 31P, 31N through the first connection cable 15 as described later. Concretely, the length of the first connection cable 15 is preferably 50 cm or less, more preferably, 30 cm or less. In the first embodiment, for example, it is 30 cm. The second connection cable 16 includes end parts 16S and 16T formed of U-shaped crimping terminals joined to both ends of a cable (a bundle of strands). The end part 16S on a side close to an element (“element-side end part”) is pressed against and conductively connected to the first end face 12T1 of the element block part 12 with a retaining nut 19 screwed onto the second element terminal part 14. The length of the second connection cable 16 only has to be long enough to conductively connect the second element terminal part 14 of the sound quality modification element 10C to the speaker input terminal 40P, 40N through the second connection cable 16 as described later. Concretely, the length of the second connection cable 16 is preferably 50 cm or less, more preferably, 30 cm or less. In the third embodiment, for example, it is 30 cm.

In the element body 11, the male screw-shaped, first element terminal part 13 and second element terminal part 14 are provided at both ends of the element block part 12 in the length direction to respectively protrude from the first and second end faces 12T1 and 12T2. However, the first and second element terminal parts may be formed as female screw-shaped holes perforated in the first and second end faces 12T1 and 12T2. In this case, bolts may be threadedly inserted in those female screw-shaped holes to connect the element-side end parts 15S and 16S of the first and second connection cables 15 and 16 to the element block part 12. Alternatively, the element block part 12 may also be provided with cylindrical annular protrusions having a smaller diameter than the element block part 12 and protruding from the first end face 12T1 and the second end face 12T2. The element-side end parts (a bundle of strands) 15S and 16S of the first and second connection cables 15 and 16 are each inserted in an inner recess of the annular protrusion and then this annular protrusion is squashed so that the bundle of strands is crimped in conduction to the squashed annular protrusion.

In the element body 11 (see FIG. 2A), the entire surface 11S of the element body 11 including the entire surface 12S of the element block part 12 may be coated with a metal plating layer (e.g., a nickel plating layer) 11M. Depending on the materials of the metal plating layer 11M, as mentioned later, the sound quality of sound SD is variously modified by the sound quality modification element 10A and others. To protect the element block part 12 and others or prevent unnecessary conductive connection, an insulating protective layer 11C made of an insulating coating, such as an enamel coating made of e.g. polyvinyl formal resin, polyurethane resin, and the like, may be provided on the element block part 12, on all of the element block part 12, the element-side end part 15S of the first connection cable 15, and the retaining nut 18, or on all of the element block part 12, the element-side end part 16S of the second connection cable 16, and the retaining nut 19, with or without the foregoing metal plating layer 11M. Each of the sound quality modification elements 10A and others may be housed in a casing or a protective cover for protection. FIGS. 2B and 2C show the sound quality modification elements 10A and 10C in which one end of each element body 11 is connected to either the first connection cable 15 or the second connection cable 16. Alternatively, a sound quality modification element may be provided with both the first connection cable 15 and the second connection cable 16 at both ends of an element body 11.

Furthermore, as indicated by a chain line in FIGS. 2A to 2C, a vibration-proof layer SL may be provided on the surface 12S of the element block part 12 or on the metal plating layer 11M applied on the surface 12S of the element block part 12 to suppress the influence of external vibration on each sound quality modification element 10A to 10C. This configuration enables the sound SD to be more clearly reproduced by the speaker system 40. This seems because the vibration-proof layer can prevent the sound from including noise due to the influence of external vibration transmitted to the element block part 12. In each of the sound quality modification elements 10A to 10C, a film-shaped vibration-proof layer SL is provided in such a manner that NOXUDOL 3100 (made by AUSON) that is an emulsion-based vibration-proof coating material is applied and dried. The vibration-proof layer SL may be further provided on not only the surface 12S of the element block part 12 or the metal plating layer 11M but also on the elemental-side end parts 15S, 16S of the connection cables 15, 16 and the retaining nuts 18, 19.

### First Embodiment

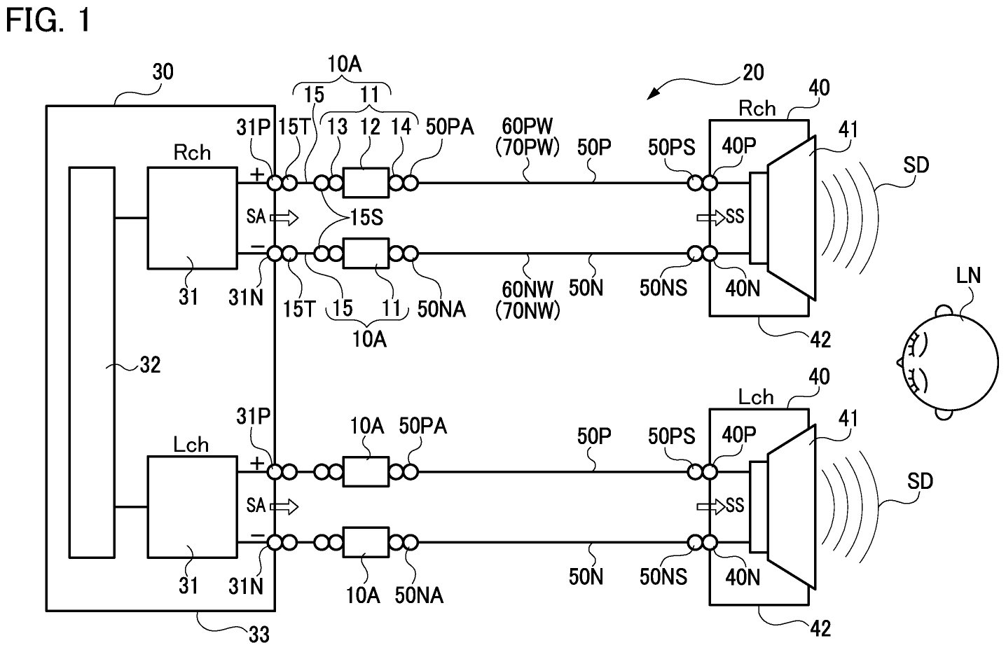

The first embodiment will be described referring to FIGS. 1A and 2B. In the system 20 in the first embodiment incorporating the sound quality modification elements 10A shown in FIG. 2B, each sound quality modification element 10A is inserted in series in each of the transmission paths 60PW, 60NW of the connection paths 70PQ, 70NW in the audio system 2 (see FIG. 21) in the foregoing basic configuration, concretely, between the amplifier 30 and each of the speaker cables 50P, 50N. More concretely, the other ends 15T of the first connection cables 15 of the sound quality modification elements 10A are connected one to each of the amplifier output terminals 31P, 31N of the amplifier 30 (the amplifier circuits 31), while the second element terminal parts 14 of the sound quality modification elements 10A are connected to the amp-side end parts SOPA, 50NA of the speaker cables 50P, 50N with unillustrated retaining nuts. Thus, the first element terminal parts 13 of the sound quality modification elements 10A (the element bodies 11) are connected to the amplifier output terminals 31P, 31N, while the second element terminal parts 14 are connected to the end parts 50PA, 50NA of the speaker cables 50P, 50N, located on a side close to the audio amplifier circuit.

The system 20 in the first embodiment using the sound quality modification elements 10A as above can modify the sound quality of the sound SD to be emitted from the speaker systems 40 (the speakers 41), as compared with the sound SD0 obtained by the system 2 (see FIG. 21) not using the sound quality modification element (that is, in the basic configuration). The detailed mechanism that the sound quality can be modified by the sound quality modification elements 10A connected in the above pattern is yet-to-be defined. However, each of the sound quality modification elements 10A is connected in series to a midpoint of each of the transmission paths 60PW, 60NW of the sound signals (electrical signals) SA, from the amplifier output terminals 31P, 31N of the audio amplifier circuits 31 to the speaker input terminals 40P, 40N of the speaker systems 40 through the speaker cables 50P, 50N. Accordingly, it is conceived that the sound signals SS input to the speakers 41 in the system 20 incorporating the sound quality modification elements 10A become different from the sound signal SSO in the system 2 not using the sound quality modification elements 10A and thus the sound quality of the sound SD reproduced by the speaker systems 40 (the speakers 41) are modified from the sound SD0 obtainable by the system 2.

### Second Embodiment

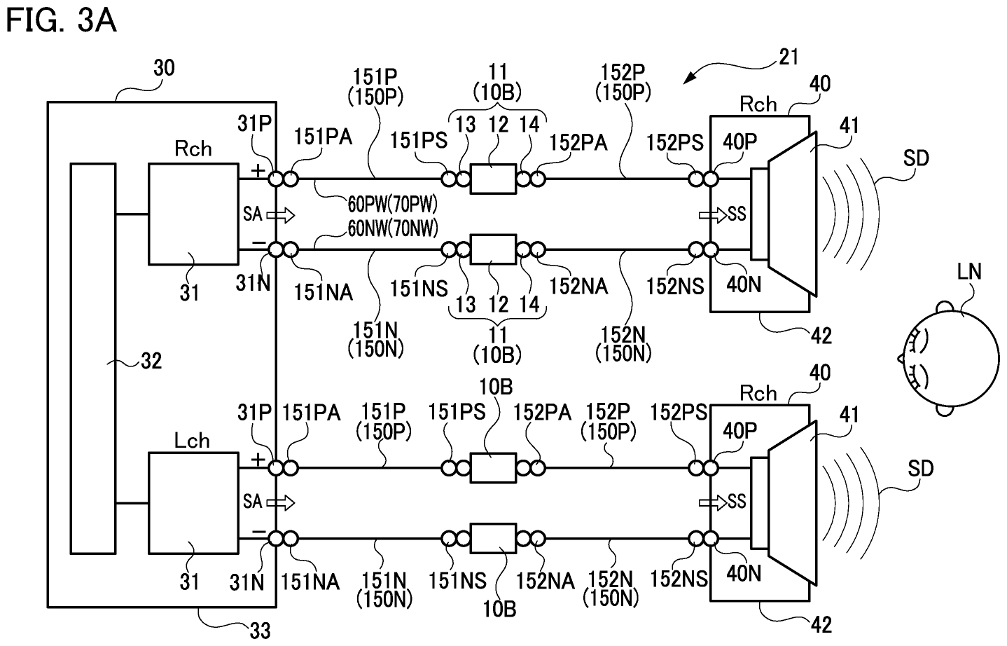

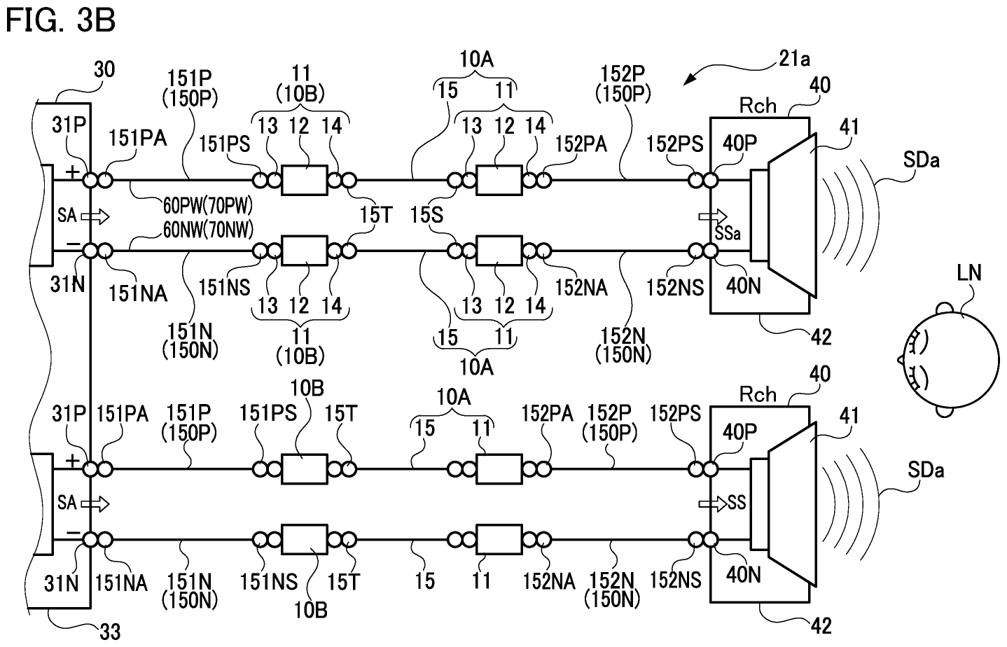

Next, a second embodiment will be described referring to FIGS. 3A and 2A. In a system 21 in the second embodiment incorporating the sound quality modification elements 10B not including the second connection cable, each sound quality modification element 10B is inserted in series in each of the transmission paths 60PW, 60NW in the system 2 (see FIG. 21) in the foregoing basic configuration, concretely, at a midpoint of each speaker cable 150P, 150N. More concretely, instead of the speaker cables 50P, 50N, speaker cables 150P, 150N each including a first speaker cable 151P, 151N and a second speaker cable 152P, 152N are arranged. The first element terminal parts 13 of the sound quality modification elements 10B are connected to speaker-side end parts 151PS, 151NS of the first speaker cables 151P, 151N by use of retaining nuts not shown. In contrast, the second element terminal parts 14 of the sound quality modification elements 10B are connected to amp-side end parts 152PA, 152NA of the second speaker cables 152P, 152N by use of retaining nuts not shown. Further, the amp-side end parts 151PA, 151NA of the first speaker cables 151P, 151N are correspondingly connected to the amplifier output terminals 31P, 31N of the amplifier 30 (the amplifier circuits 31). Similarly, the speaker-side end parts 152PS, 152NS of the second speaker cables 152P, 152N are correspondingly connected to the speaker input terminals 40P, 40N of the speaker systems 40. Thus, the first element terminal parts 13 of the sound quality modification elements 10B (the element bodies 11) are connected one to each of the speaker-side end parts 151PS, 151NS of the first speaker cables 151P, 151N, while the second element terminal parts 14 are connected one to each of the amp-side end parts 152PA, 152NA of the second speaker cables 152P, 152N.

As with the system 20 in the first embodiment, the system 21 in the second embodiment using the sound quality modification elements 10B can also change the sound signals SS to modify the sound quality of the sound SD to be emitted from the speaker systems 40, as compared with the system 2 not using the sound quality modification elements (that is, in the basic configuration).

### Seventh Modified Embodiment

A system 21a in the seventh modified embodiment which is a variation of the second embodiment will be described referring to FIGS. 3B, 2A, and 2B. In the system 21 in the foregoing second embodiment, each of the sound quality modification elements 10B is connected in series to a midpoint of each speaker cable 150P, 150N. In contrast, the system 21a in the seventh modified embodiment is different in that a plurality of (two in this seventh modified embodiment) sound quality modification elements 10A, 10B connected in series to each other are connected in series to a midpoint of each of the speaker cables 150P, 150N. Specifically, the second element terminal part 14 of the sound quality modification element 10B shown in FIG. 2A is connected to the other end part 15T of the first connection cable 15 of the sound quality modification element 10A shown in FIG. 2B with a retaining nut not shown so that the sound quality modification elements 10B and 10A are connected in series to each other. Further, as in the second embodiment, the unconnected first element terminal pars 13 of the sound quality modification elements 10B, which are unconnected to the sound quality modification elements 10A, are connected one to each of the speaker-side end parts 151PS, 151NS of the first speaker cables 151P, 151N with retaining nuts not shown. On the other hand, the unconnected second element terminal parts 14 of the sound quality modification elements 10A, which are unconnected to the sound quality modification elements 10B, are connected one to each of the amp-side end parts 152PA, 152NA of the second speaker cables 152P, 152N with retaining nuts not shown.

The sound SDa reproduced by the system 21a in the seventh modified embodiment using the plurality of sound quality modification elements 10B, 10A (two sound quality modification elements for each speaker in the present modified embodiment) is different from the sound SD reproduced by the system 21 in the second embodiment using one sound quality modification element 10B for each speaker. In the system 21a in the seventh modified embodiment, the plurality of sound quality modification elements 10B, 10A are connected in series, so that the sound quality modification effect obtained by each sound quality modification element is superimposed on the sound signal SSa to be input to the speaker systems 40. Thus, the sound quality of the sound SDa reproduced by the speaker systems 40 is greatly modified as compared with the sound SD in the second embodiment. The plurality of sound quality modification elements 10B, 10A connected to each other may be designed such that the element block parts 12 have either the same or different dimension. When a plurality of sound quality modification elements including the element block parts 12 equal in dimension to each other is used, the sound quality modification effect is deeply generated. Further, when a plurality of sound quality modification elements including element block parts 12 different in dimension is used, for example, when the sound quality modification elements 10B and others in which e.g. the diameters of the element block parts 12 are set to three different dimensions, large/middle/small, are used, the sound quality modification effect by each sound quality modification element is superimposed, resulting in the sound quality modification effect exerted over a wide range. Further, even when the sound quality modification elements 10B and others are used in the foregoing first embodiment and a third embodiment mentioned later and others, the same effect as above can also be obtained.

### Third Embodiment

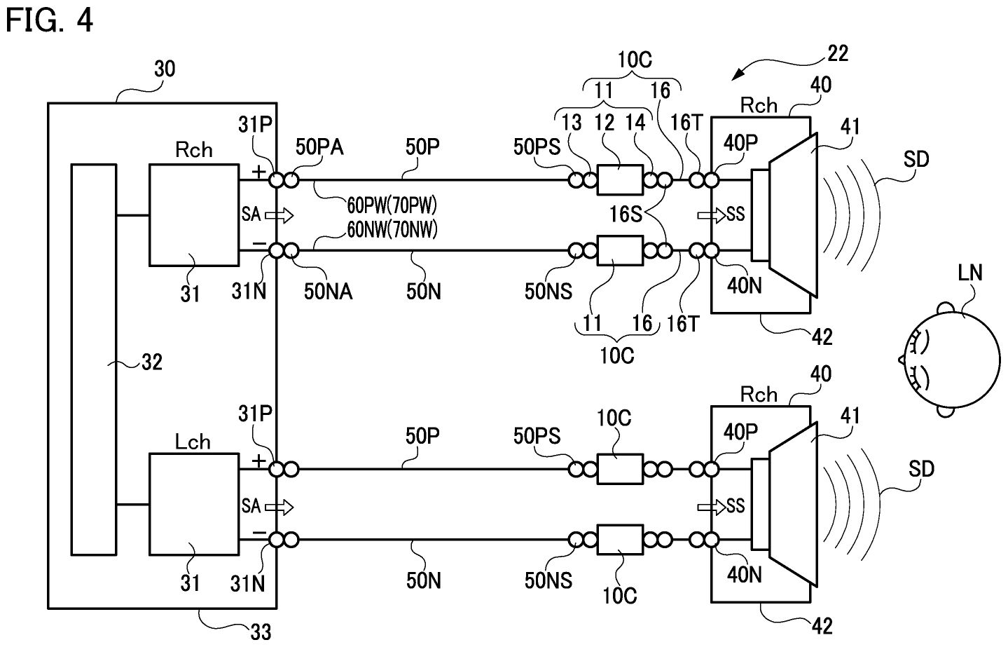

Next, a third embodiment will be described referring to FIGS. 4 and 2C. In a system 22 in the third embodiment incorporating the sound quality modification elements 10C each including the second connection cable 16 shown in FIG. 2C, each sound quality modification element 10C is inserted in series in each of the transmission path 60PW, 60NW in the system 2 (see FIG. 21) in the foregoing basic configuration, concretely, between each of the speaker cables 50P, 50N and the corresponding speaker input terminals 40P, 40N of each speaker system 40. More concretely, the first element terminal parts 13 of the sound quality modification elements 10C are connected one to each of the speaker-side end parts 50PS, 50NS of the speaker cables 50P, 50N with retaining nuts not shown. On the other hand, the other end parts 16T of the second connection cables 16 of the sound quality modification elements 10C are connected one to each of the speaker input terminals 40P, 40N of the speaker systems 40. Thus, the first element terminal parts 13 of the sound quality modification elements 10C (the element bodies 11) are connected to the speaker-side end parts 51PS, 51NS of the speaker cables 51P, 51N, while the second element terminal parts 14 are connected to the speaker input terminals 40P, 40N of the speaker systems 40.

As with the systems 20 and 21 in the first and second embodiments, the system 22 in the third embodiment using the sound quality modification elements 10C can also modify the sound quality of the sound SD to be emitted from the speaker systems 40, as compared with the system 2 (see FIG. 21) not using the sound quality modification elements (that is, in the basic configuration).

(One-End Connection Type Sound Quality Modification Element)

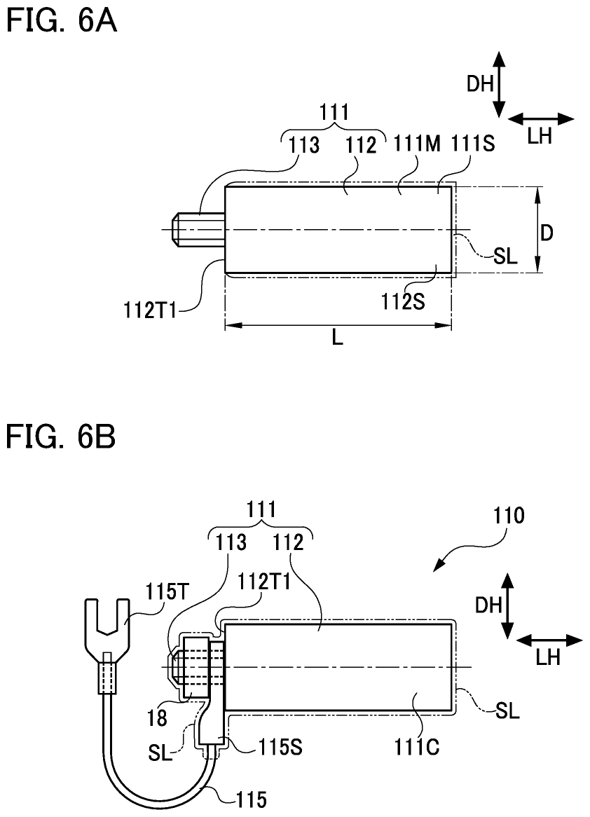

Next, a one-end connection type sound quality modification element 110 used in the fourth to sixth embodiments and eighth and ninth modified embodiments will be described referring to FIGS. 6A and 6B. The sound quality modification element 110 (see FIG. 6B) includes an element body 111 and a connection cable 115. This element body 111 (see FIG. 6A) is formed of a single metal block (e.g., an oxygen-free copper block) and includes an element block part 112 having a round-columnar shape and a first element terminal part 113 having a male screw shape protruding from a first end face 112T1 that is one end face (a left end in the figure) of the element block part 112. Specifically, this sound quality modification element 110 is configured such that the element body 11 used for the sound quality modification element 10A and others is not provided with the second element terminal part 14. The sound quality modification element 110 is also used in the second and fifth modified embodiments described later.

The element block part 112 has a round-columnar or circular-disk shape with a diameter D of 5 mm or more in a diametrical direction DH (a vertical direction in the figure) and a length L of 5 mm or more in a length direction LH (a lateral direction in the figure) perpendicular to the diametrical direction DH. For example, the element block part 112 has a round-columnar shape with a diameter D of 10 mm and a length L of 42 mm.

Depending on the diameter D and the length L of the element block part 112, as described later, the sound quality modification element 110 also changes the sound range to be modified and the degree of modification obtained by connection of the sound quality modification element 110 and others. In the system incorporating this sound quality modification element 110 including the element block part 12 having for example a round columnar shape with a diameter D of 10 mm and a length L of 42 mm, the sound SD to be emitted from the speaker system 40 can be modified to the sound that so that each tone of each instrument and voice sound in a relatively high range is clearly emphasized, as compared with sound SD0 obtainable by the system 2 in the basic configuration not using the sound quality modification element 110. More concretely, regarding the music (music pieces) and others to be reproduced from the speaker system, such as voice sound and piano sound, tones in the mid-range to the mid-high range are each distinctly emphasized. As the diameter D of the element block part 112 of the sound quality modification element 110 is set larger, the sound quality modification effect is obtained such that each tone not only in the mid-range and mid-high range but also in the mid-low range and further in the low range and deep low range is more clearly emphasized, and thus each tone even in the low range and deep low range is clearly emphasized, resulting in balanced sound. Furthermore, the longer the length L of the element block part 12, the greater the degree of the sound quality modification that clearly emphasizes each tone in sound ranges limited by the diameter D. In the systems 120 to 122 in the fourth to sixth embodiments incorporating the sound quality modification elements 110, the degree of the sound quality modification in the deep low range or in the low range is relatively low as compared with the systems 20 to 22 in the first to third embodiments incorporating the sound quality modification elements 10B and others. In contrast, the sound quality modification effect by the sound quality modification element in the mid-range to the mid-high range is relatively high.

The first connection cable 115 includes end parts 115S and 115T formed of U-shaped crimping terminals joined to both ends of a cable (a bundle of strands). The element-side end part 115S is pressed against and conductively connected to the first end face 112T1 of the element block part 112 with a retaining nut 18 screwed onto the first element terminal part 113. The length of the first connection cable 115 only has to be long enough to conductively connect the first element terminal part 113 of the sound quality modification element 110 to the amplifier output terminal 31P, 31N through the first connection cable 115 as described later. Concretely, the length of the first connection cable 115 is preferably 50 cm or less, more preferably, 30 cm or less. In the fourth to sixth embodiments, for example, it is 30 cm.

In the element body 111, the male screw-shaped, first element terminal part 13 is provided at one end of the element block part 112 in the length direction to protrude from the first end face 112T1. However, the first element terminal part may be formed as a female screw hole perforated in the first end face 112T1. In this case, a bolt may be threadedly inserted in the female screw-shaped hole to connect the element-side end part 115S of the first connection cable 115 to the element block part 112. Alternatively, the element block part 112 also may be provided with a cylindrical annular protrusion having a smaller diameter than the element block part 112 and protruding from the first end face 112T1. The element-side end part (a bundle of strands) 115S of the first connection cable 15 is inserted in an inner recess of the annular protrusion and then this annular protrusion is squashed so that the bundle of strands is crimped in conduction to the squashed annular protrusion.

In the element body 111 (see FIG. 6A), the entire surface 111S of the element body 111 including the entire surface 112S of the element block part 112 may be coated with a metal plating layer (e.g., a nickel plating layer) 111M. Depending on the materials of the metal plating layer 111M, as mentioned later, the sound quality of sound SD is variously modified by the sound quality modification element 110. To protect the element block part 112 or prevent unnecessary conductive connection, an insulating protective layer 111C made of an insulating coating may be provided on the element block part 112 or on all of the element block part 112, the element-side end part 115S of the first connection cable 115, and the retaining nut 18. Each of the sound quality modification elements 110 may be housed in a casing or a protective cover for protection. FIG. 6B shows the sound quality modification element 110 in which one end of the element body 111 is connected to the first connection cable 115. Alternatively, a sound quality modification element may be provided with two first connection cables 115 connected to one end of the element body 111.

Furthermore, as indicated by a chain line in FIGS. 6A and 6B, a vibration-proof layer SL may be provided on the surface 112S of the element block part 112 or on the metal plating layer 111M to suppress the influence of external vibration on the sound quality modification elements 111, as with the sound quality modification element 10A and other in the first embodiment. This configuration enables the sound SD to be more clearly reproduced by the speaker system 40. The vibration-proof layer SL may be further provided on the elemental-side end part 115S of the connection cable 115 and the retaining nut 18.

### Fourth Embodiment

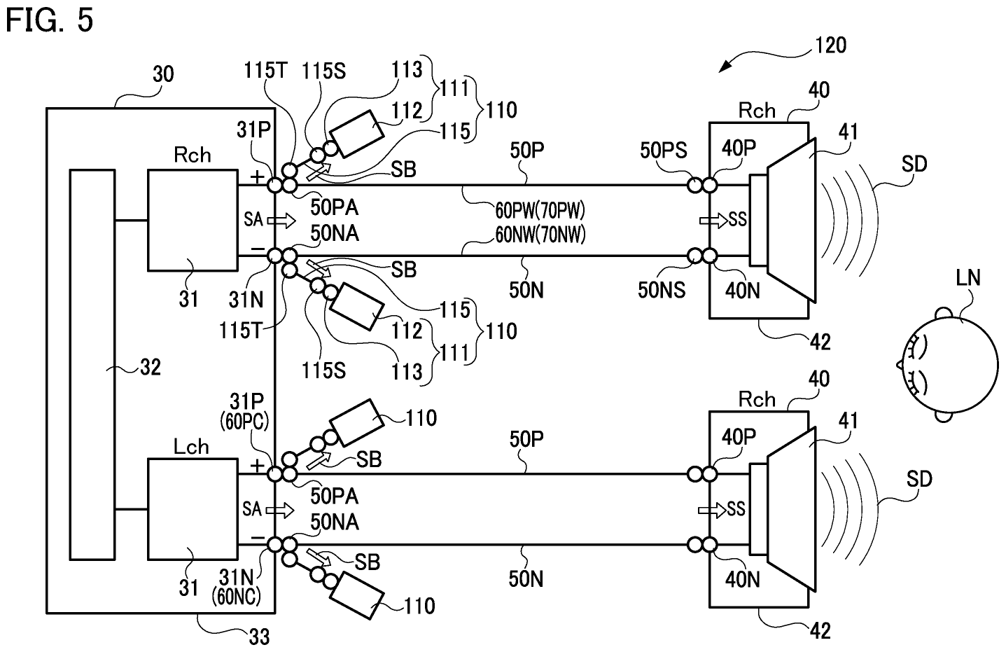

Next, a fourth embodiment will be described referring to FIGS. 5 and 6B. In a system 120 in the fourth embodiment incorporating the sound quality modification elements 110 shown in FIG. 6B, the other end parts 115T of the first connection cables 115 of the sound quality modification elements 110 are connected one to each of connection sites 60PC, 60NC in the transmission paths 60PW, 60NW of the connection paths 70PW, 70NW in the system 2 (see FIG. 21) in the foregoing basic configuration, concretely, externally connected one to each of the amplifier output terminals 31P, 31N of the amplifier 30 (the amplifier circuits 31). Thus, the first element terminal parts 113 of the sound quality modification elements 110 (the element bodies 111) are connected to the amplifier output terminals 31P, 31N. To the amplifier output terminals 31P, 31N, there are also connected the amp-side end parts 50PA, 50NA of the speaker cables 50P, 50N.

The system 120 in the fourth embodiment using the sound quality modification elements 110 as above can modify the sound quality of the sound SD to be emitted from the speaker systems 40, as compared with the system 2 not using sound quality modification element (that is, in the basic configuration). The detailed mechanism that the sound quality can be modified by the sound quality modification elements 110 connected as above is yet-to-be defined. However, a branching sound signal SB which is a part of the sound signal SA output from the amplifier output terminal 31P, 31N of the amplifier circuit 31 travels by diverging into the sound quality modification element 110. It is accordingly conceived that the sound signals SS to be input to the speaker systems 40 are changed, thereby modifying the sound quality of the sound reproduced by the speaker systems 40, as compared with a system not using the sound quality modification elements 110 (the system 2 in the basic configuration).

### Fifth Embodiment

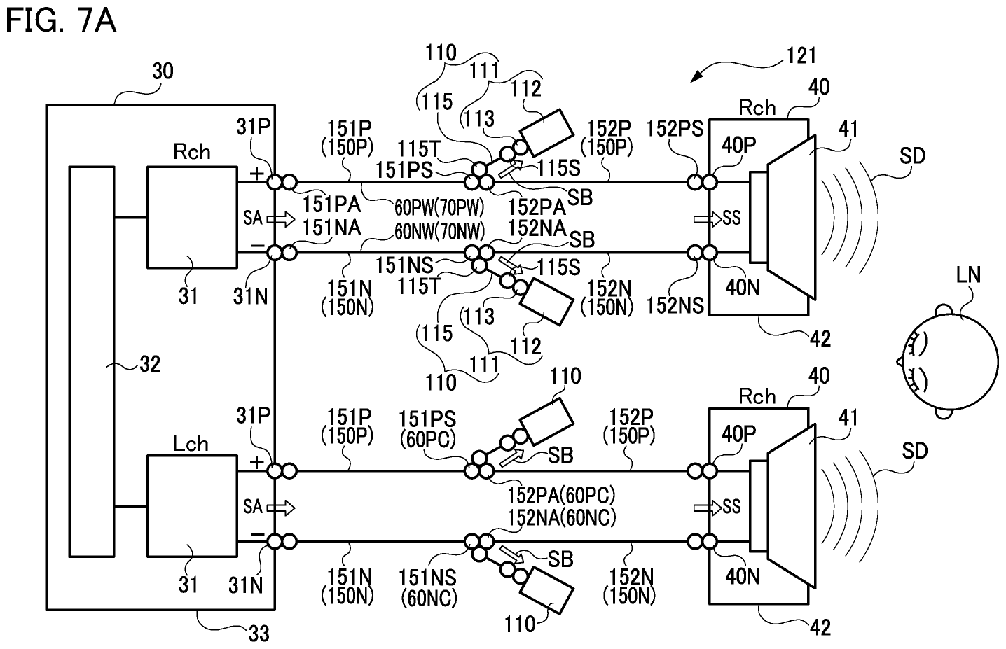

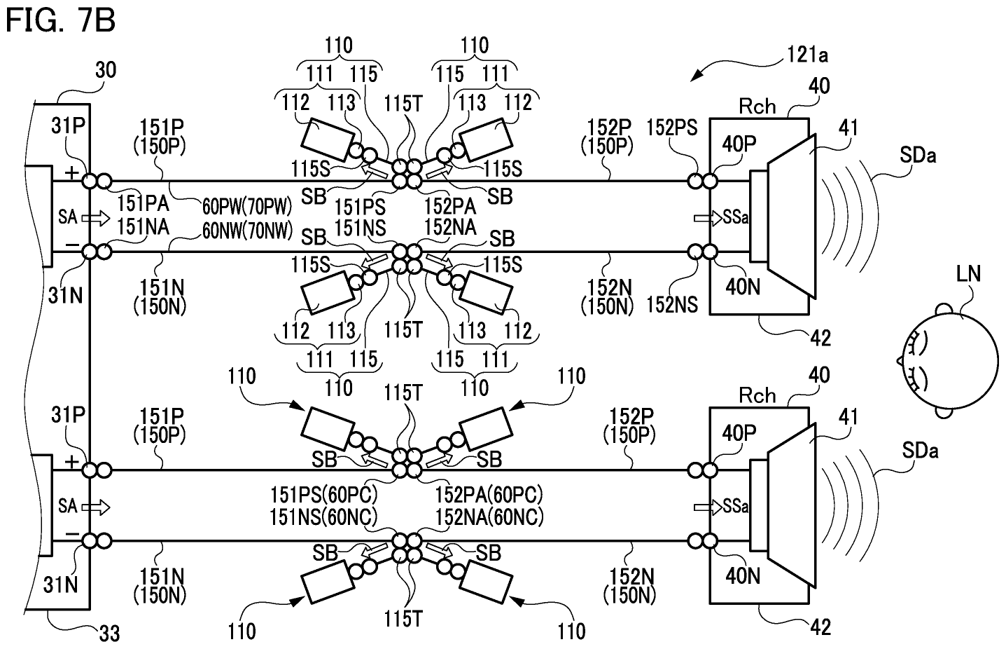

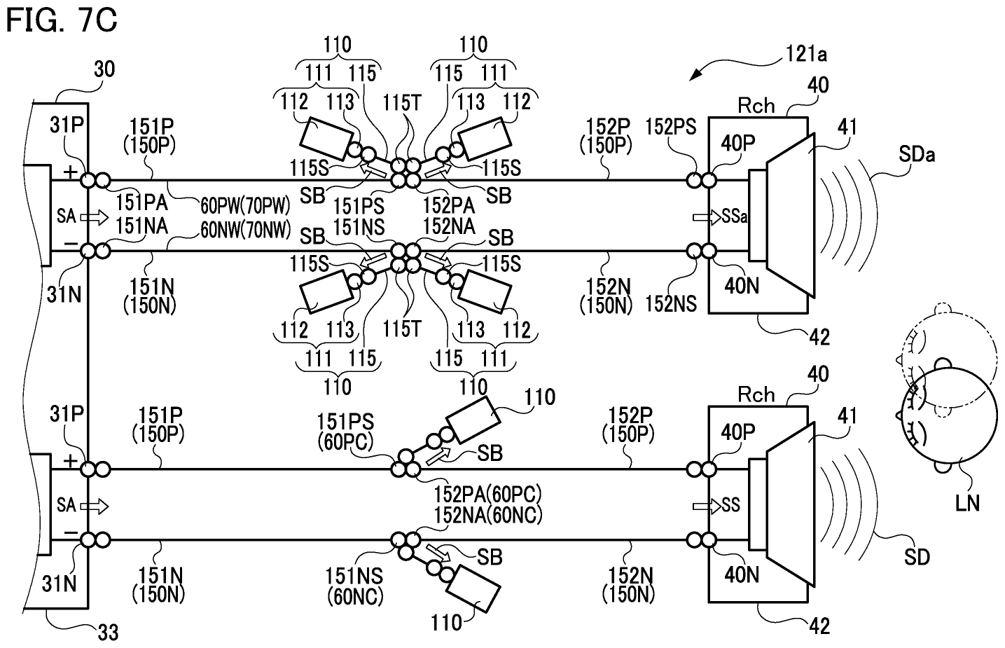

Next, a fifth embodiment will be described referring to FIGS. 7A and 6B. In a system 121 in the fifth embodiment incorporating the sound quality modification elements 110 shown in FIG. 6B, each sound quality modification element 110 is connected to each of the connection sites 60PC, 60NC in the transmission paths 60PW, 60NW in the system 2 (see FIG. 21) in the foregoing basic configuration, concretely, to a midpoint in each of the speaker cables 150P, 150N. More concretely, instead of the speaker cables 50P, 50N, the speaker cable 150P including the first speaker cable 151P and the second speaker cable 152P and the speaker cable 150N including the first speaker cable 151N and the second speaker cable 152N are used. Further, the other end part 115T of the first connection cable 115 of each of the sound quality modification elements 110 is connected to the speaker-side end part 151PS, 151NS of the first speaker cable 151P, 151N and the amp-side end part 152PA, 152NA of the second speaker cable 152P, 152N. Concretely, three parts, i.e., the other end part 115T of the first connection cable 115, the speaker-side end part 151PS of the first speaker cable 151P, and the amp-side end part 152PA of the second speaker cable 152P are joined together and conductively connected to one another by use of a bolt and a retaining nut which are not shown. Further, three parts, i.e., the other end part 115T of the first connection cable 115, the speaker-side end part 151 NS of the first speaker cable 151N, and the amp-side end part 152NA of the second speaker cable 152N are joined together and conductively connected to one another by use of a bolt and a retaining nut which are not shown. Thus, the first element terminal parts 113 of the sound quality modification elements 110 (the element bodies 111) are connected to the speaker-side end parts 151PS, 151NS and the amp-side end parts 152PA, 152NA, which correspond to the connection sites 60PC, 60NC respectively located at midpoints in the speaker cables 150P, 150N. The amp-side end parts 151PA, 151NA of the first speaker cables 151P, 151N are respectively connected to the amplifier output terminals 31P, 31N of the amplifier 30 (the amplifier circuits 31). The speaker-side end parts 152 PS, 152NS of the second speaker cables 152P, 152N are respectively connected to the speaker input terminals 40P, 40N of the speaker system 40.

The system 121 in the fifth embodiment using the sound quality modification elements 110, as with the system 120 in the fourth embodiment, can also change the sound signal SS to modify the sound quality of the sound SD to be emitted from the speaker systems 40, as compared with the system 2 not using the sound quality modification element (that is, in the basic configuration).

### Eighth Modified Embodiment

A system 121a in the eighth modified embodiment which is a variation of the fifth embodiment will be described referring to FIGS. 7B and 6B. In the system 121 in the fifth embodiment, the sound quality modification elements 110 are connected one to a midpoint of each of the speaker cables 150P, 150N. Differently from this, the system 121a in the eighth modified embodiment is configured such that a plurality of (two in this modified embodiment) sound quality modification elements 110 is connected to the same connection site 60PC, 60NC located at a midpoint of each speaker cable 150P, 150N. Specifically, four parts, i.e., the other end parts 115T of the first connection cables 115 of two sound quality modification elements 110, the speaker-side end part 151PS of the first speaker cable 151P, and the amp-side end part 152PA of the second speaker cable 152P are joined together and conductively connected by use of a bolt and a nut not shown. Further, four parts, i.e., the other end parts 115T of the first connection cables 115 of other two sound quality modification elements 110, the speaker-side end part 151NS of the first speaker cable 151N, and the amp-side end part 152NA of the second speaker cable 152N are joined together and conductively connected by use of a bolt and a nut not shown.

The sound SDa reproduced by the system 121a in the eighth modified embodiment also differs from the sound SD reproduced by the system 121 in the fifth embodiment. Since the plurality of sound quality modification elements 110 are connected to the same site at a midpoint of each speaker cable 150P, 150N, the sound quality modification effect obtained by each sound quality modification element is superimposed on the sound signal SSa to be input to the speaker system 40. Thus, the sound quality of the sound SDa to be reproduced by the speaker 41 is greatly modified, as compared with the sound SD in the fifth embodiment. The plurality of sound quality modification elements 110 connected as above may be designed such that the element block parts 112 have either the same or different dimension. When a plurality of sound quality modification elements including the element block parts 112 equal in dimension to each other is used, the sound quality modification effect is deeply generated. Further, when a plurality of sound quality modification elements including the element block parts 112 different in dimension is used, for example, when the sound quality modification elements 110 in which e.g. the diameters of the element block parts 112 are set to three different dimensions, large/middle/small, are used, the sound quality modification effect by each sound quality modification elements is superimposed, resulting in the sound quality modification effect exerted over a wide range. Even when the quality modification elements 110 are used in the foregoing fourth embodiment and the sixth embodiment described later, and others, the same effect as above can be obtained similarly.

### Ninth Modified Embodiment

Next, a system 121b in the ninth modified embodiment which is a variation of the fifth embodiment will be described referring to FIGS. 7C and 6B. In the systems 121, 121a in the foregoing fifth embodiment and the eighth modified embodiment, the sound quality modification elements are connected in the same pattern between both channels. Specifically, the one sound quality modification element 110 or the plurality of (two in the eighth modified embodiment) sound quality modification elements 110 are connected to a midpoint of each of the paired (two) speaker cables 150P, 150N in a similar manner for each channel (the R channel and the L channel). In the system 121b in the ninth embodiment, in contrast, two sound quality modification elements 110 are connected to a midpoint of each of the paired (two) speaker cables 150P, 150N for the R channel (an upper channel in FIG. 7C) as in the eighth modified embodiment. On the other hand, a single sound quality modification element 110 is connected to a midpoint of each of the paired (two) speaker cables 150P, 150N for the L channel (a lower channel in FIG. 7C) as in the fifth embodiment. In other words, the connected sound quality modification elements in this system 121b are arranged unevenly for the R channel and the L channel. Accordingly, the speaker system 40 for the R channel (the upper channel in FIG. 7C) receives the sound signal SSa and reproduces the sound SDa as in the eighth modified embodiment, while the speaker system 40 for the L channel (the lower channel in FIG. 7C) receives the sound signal SS and reproduces the sound SD as in the fifth embodiment. This configuration can influence the position of sound images perceptible to a listener LN and displace the position of sound images to be localized by the listener LN. The degree of the effect varies depending on the dimension of the element block parts 112 of the sound quality modification elements 110 to be used. Concretely, for example, when the listener LN is located in a position at the same distance from the two speaker systems 40 laterally arranged when seen from the listener LN, as shown in FIGS. 21, 7A, and 7B, the sound reproduced by the system 2 in the basic configuration, the system 121 in the fifth embodiment, and the system 121a in the eighth modified embodiment can be perceived by the listener LN as if a singer or an orchestra is located in just front of the listener. In contrast, when the listener LN is positioned somewhat close to the left speaker system 40 (a lower side in FIG. 7C) as shown in FIG. 7C, the sound reproduced by the system 121b in the ninth modified embodiment can be perceived by the listener LN as if a singer or an orchestra (sound images) is located in front of the listener.

### Sixth Embodiment

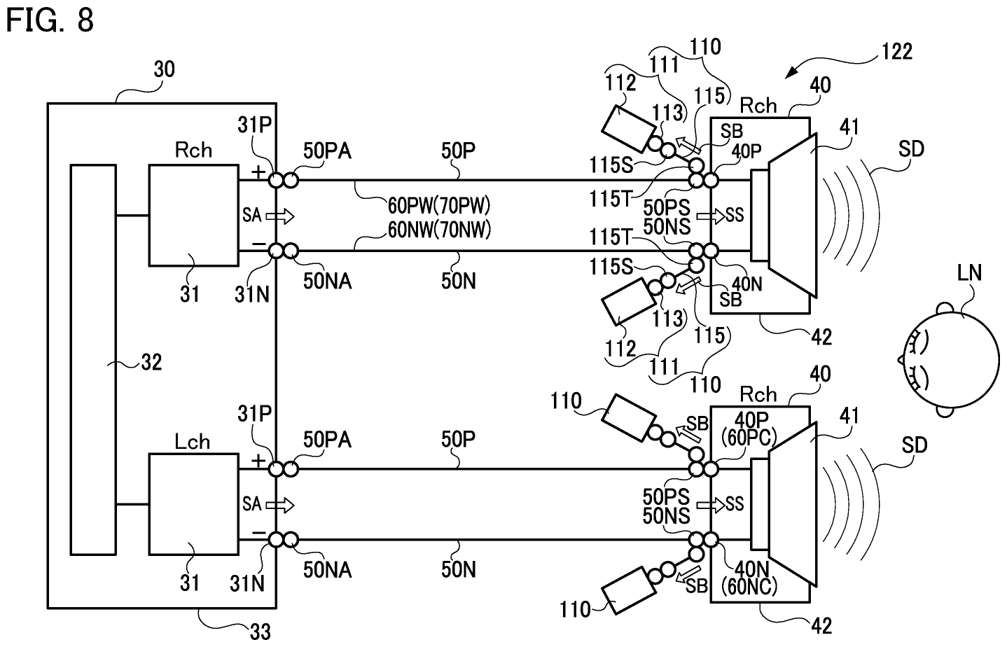

Next, a sixth embodiment will be described referring to FIGS. 8 and 6B. In a system 122 in the sixth embodiment incorporating the sound quality modification elements 110 shown in FIG. 6B, the other end parts 115T of the first connection cables 115 of the sound quality modification elements 110 are connected one to each of the connection sites 60PC, 60NC in the transmission paths 60PW, 60NW in the system 2 (see FIG. 21) in the foregoing basic configuration, concretely, externally connected one to each of the speaker input terminals 40P, 40N of the speaker systems 40. Thus, the first element terminal parts 113 of the sound quality modification elements 110 (the element bodies 111) are connected to the speaker input terminals 40P, 40N. To the speaker input terminals 40P, 40N, the speaker-side end parts 50PS, 50NS of the speaker cables 50P, 50N are also connected. As with the system 120 in the fourth embodiment and the system 121 in the fifth embodiment, the system 122 in the sixth embodiment using the sound quality modification elements 110 can also change the sound signal SS to modify the sound quality of the sound SD to be emitted from the speaker systems 40, as compared with the system 2 not using the sound quality modification element (that is, in the basic configuration).

(Loop Connection Type Sound Quality Modification Element)

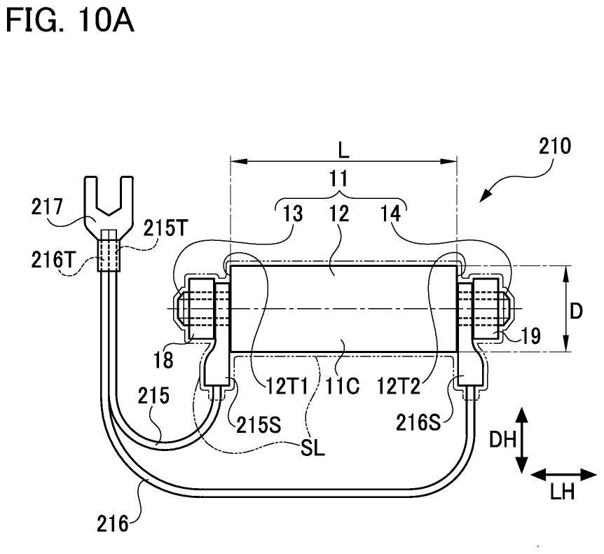

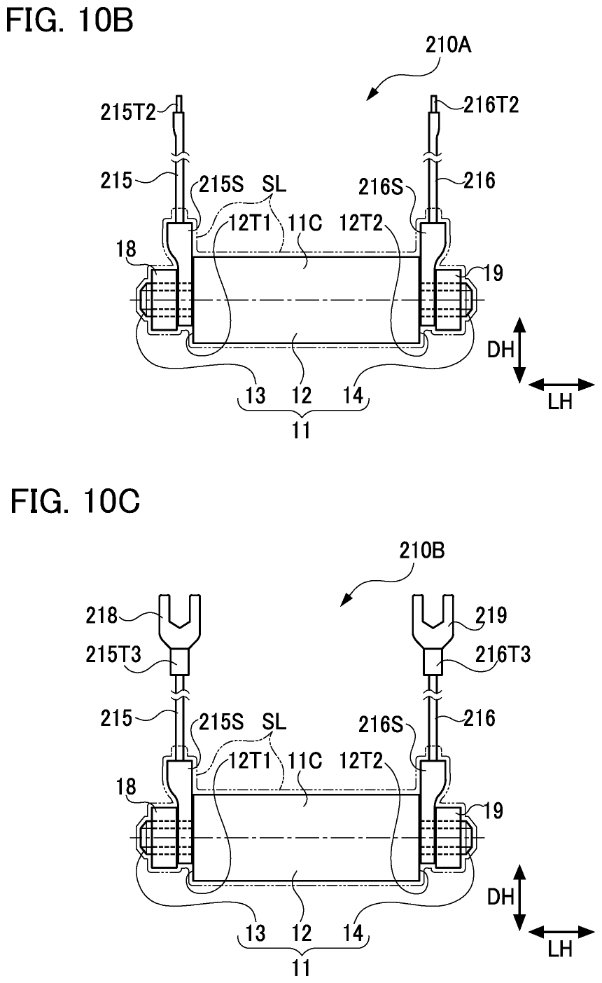

Next, loop connection type sound quality modification elements 210, 210A, and 210B used in the seventh to ninth embodiments, first and fourth modified embodiments, and others, will be described referring to FIGS. 10A, 10B, and 10C. The sound quality modification elements 210, 210A, and 210B (see FIGS. 10A to 10C) each include the foregoing element body 11 (see FIG. 2A), a first connection cable 215, and a second connection cable 216. The sound quality modification elements 210, 210A, and 210B are also used in the tenth and eleventh embodiments and the first and fourth modified embodiment, which will be described later. Each element body 11 (see FIG. 2A) is formed of a single metal block and includes the element block part 12 having a round-columnar shape, the first element terminal part 13 having a male screw shape protruding from the first end face 12T1, and the second element terminal part 14 having a male screw shape protruding from the first end face 12T2. The element block part 12 may have e.g. a round-columnar shape with a diameter D of 10 mm and a length L of 42 mm. Depending on the diameter D and the length L of the element block part 12, as described later, the sound range to be modified and the degree of modification obtained by connection of the sound quality modification element 210 are changed. In the system incorporating such a sound quality modification element 210 including the element block part 12 having for example a round columnar shape with a diameter D of 10 mm and a length L of 42 mm, the music (music pieces) and others to be reproduced from the speaker system, such as voice sound and piano sound, is modified such that each tone in the mid-range to the mid-high range is distinctly emphasized, as compared with the system 2 in the basic configuration not using the sound quality modification element and also as compared with the systems 20 to 22 and 120 to 122 in the first to sixth embodiment. Furthermore, differently from the systems 20 to 22 and 120 to 122 in the first to sixth embodiment, the sound quality modification effect is strongly exerted so that each tone not only in the mid-range and mid-high range but also in the mid-low range and further in the low range and the deep low range is clearly emphasized, resulting in balanced sound among those ranges. In addition, as the diameter D of the element block part 12 of the sound quality modification element 210 is set larger, the sound quality modification is exerted more strongly so that each tone is clearly emphasized in the deep low range to the mid-high range. Further, as the length L of the element block part 12 of the sound quality modification element 210 is set longer, the degree of the sound quality modification effect that clearly emphasizes each tone is greater. In the systems 220 to 222 in the seventh to ninth embodiment incorporating the sound quality modification elements 210, the degree of the sound quality modification in the deep low range or the low range and also the degree of the sound quality modification in the mid-range to the mid-high range are relatively high, as compared with the systems 20 to 22 in the first to third embodiments using the sound quality modification element 10B and others and the systems 120 to 122 in the fourth to sixth embodiments using the sound quality modification element 110.

The first connection cable 215 includes an element-side end part 215S formed of a U-shaped crimping terminal jointed to one end of a cable (a bundle of strands). This element-side end part 215S is pressed against and conductively connected to the first end face 12T1 of the element block part 12 with a retaining nut 18 screwed onto the first element terminal part 13. The second connection cable 216 similarly includes an element-side end part 216S formed of a U-shaped crimping terminal jointed to one end of a cable (a bundle of strands). This element-side end part 216S is also pressed against and conductively connected to the second end face 12T2 of the element block part 12 with a retaining nut 19 screwed onto the second element terminal part 14. In contrast, the other end part 21ST (a bundle of strands) of the first connection cable 215 and the other end part 216T (a bundle of strands) of the second connection cable 216 are tied together in a bundle with a terminal member 217 which is a U-shaped crimping terminal and are conductively connected to each other. The length of each of the first connection cable 215 and the second connection cable 216 only has to be long enough to conductively connect the first element terminal part 13 and the second element terminal part 14 of the sound quality modification element 210 to the amplifier output terminals 31P, 31N and others through the first connection cable 215 and the second connection cable 216, as mentioned later. Concretely, the length of each connection cable is preferably 50 cm or less, more preferably, 30 cm or less. In the seventh to eleventh embodiments, for example, the first connection cable 215 is 25 cm long and and the second connection cable 216 is 30 cm long.

In the seventh and other embodiments described below, the sound quality modification element 210A (see FIG. 10B) not including the terminal member 217 may be used, instead of the sound quality modification element 210 (see FIG. 10A). This sound quality modification element 210A may be arranged such that the other end part 215T2 (a bundle of strands) of the first connection cable 215 and the other end part 216T2 (a bundle of strands) of the second connection cable 216 are respectively directly connected to the same amplifier output terminal 31P, 31N, and others, instead of the terminal member 217 of the sound quality modification element 210.

Alternatively, in the seventh and other embodiments described below, instead of the sound quality modification element 210 (see FIG. 10A), the sound quality modification element 210B (see FIG. 10C) not including the terminal member 217 may be used, in which the strand bundle at the other end of the first connection cable 215 is joined to a U-shaped crimping terminal 217A to form the other end part 215T3, while the strand bundle at the other end of the second connection cable 216 is joined to a U-shaped crimping terminal 217B to form the other end part 216T2. This sound quality modification element 210B may be arranged such that the other end part 215T3 (the U-shaped crimping terminal 217A) of the first connection cable 215 and the other end part 216T3 (the U-shaped crimping terminal 217B) of the second connection cable 216 are directly conductively connected to the same amplifier output terminal 31P, 31N, etc., instead of the single terminal member 217 of the sound quality modification element 210. Furthermore, the sound quality modification elements 210, 210A, and 210B may be designed such that the first connection cable 215 and the second connection cable 216 are different in length to each other. However, the first connection cable 215 and the second connection cable 216 are preferably designed with the same length because the sound quality modification effect is greatly obtained by those same length cables.

As described above, the element body 11 (see FIG. 2A) may be entirely coated with the metal plating layer (e.g., a nickel plating layer).

To protect the element block part 12 and others or prevent unnecessary conductive connection, an insulating protective layer 11C made of an insulating coating, such as an enamel coating, may be provided on the element block part 12 and the element-side end parts 215S and 16S, and the retaining nuts 18, 19. Each of the sound quality modification elements 210, 210A, 210B may be housed in a protective casing or a protective cover.

Furthermore, as indicated by a chain line in FIGS. 10A to 10C, a vibration-proof layer SL may be provided on the surface 12S of the element block part 12 or on the metal plating layer 11M to suppress the influence of external vibration on the sound quality modification element 11. This configuration enables the sound SD to be more clearly reproduced by the speaker systems 40. The vibration-proof layer SL may be further provided on the elemental-side end parts 215S, 216S of the connection cables 215, 216 and the retaining nut 18.

### Seventh Embodiment

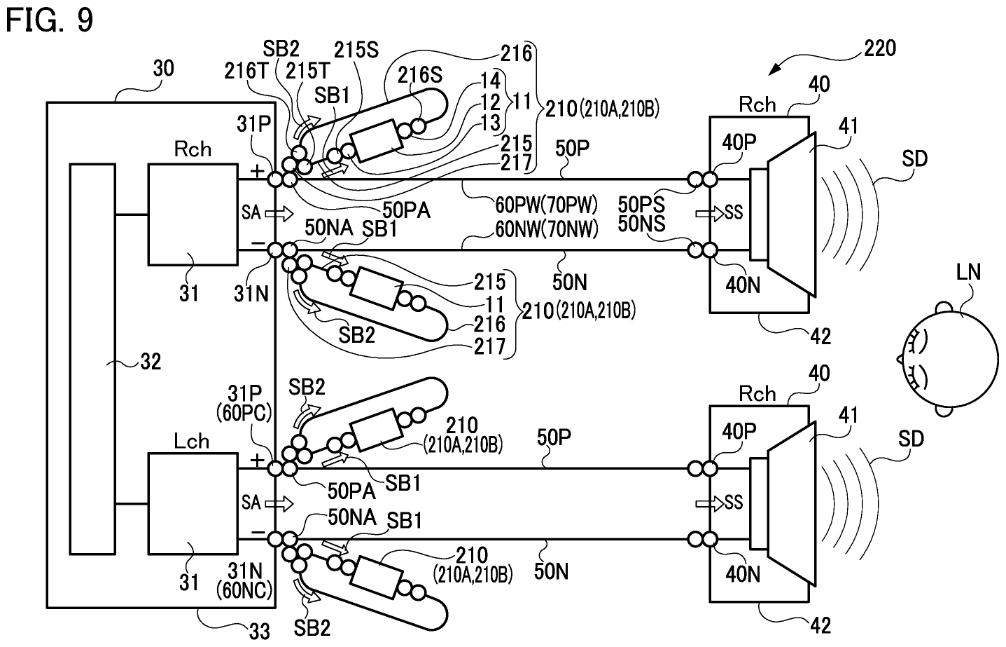

Next, a seventh embodiment will be described referring to FIGS. 9 and 10A. In a system 220 in the seventh embodiment incorporating the sound quality modification elements 210 shown in FIG. 10A, the terminal members 217 of the sound quality modification elements 210 are externally connected one to each of the connection sites 60PC, 60NC in the transmission paths 60PW, 60NW of the connection paths 70PW, 70NW in the system 2 (see FIG. 21) in the foregoing basic configuration, concretely, externally connected one to each of the amplifier output terminals 31P, 31N of amplifier 30 (the amplifier circuits 31). Thus, the first element terminal part 13 and the second element terminal part 14 of each sound quality modification element 210 (each element body 11) are connected to the same amplifier output terminal 31P, 31N. To each amplifier output terminal 31P, 31N, there is also connected the amp-side end part 50PA, 50NA of the speaker cable 50P, 50N.

The system 220 in the seventh embodiment using the sound quality modification elements 210 as above can modify the sound quality of sound SD to be emitted from the speaker systems 40, as compared with the system 2 not using the sound quality modification element (that is, in the basic configuration). The detailed mechanism that the sound quality can be modified by the sound quality modification elements 210 connected as above is yet-to-be defined. However, each sound quality modification element 210 (concretely, the terminal member 217) is connected to each connection site (the amplifier output terminals 31P, 31N in the seventh embodiment). Thus, branching sound signals SB1, SB2 which are parts of the sound signal SA output from the amplifier output terminal 31P, 31N of the amplifier circuit 31 travel by diverging into the sound quality modification element 210 and further travel in a loop flow through a path via the first element terminal part 13, the element block part 12, and the second element terminal part 14 in this order (and a reversed order) and then return to the connection site. It is accordingly conceived that the sound signals (electrical signals) SS to be input to the speaker systems 40 are changed, causing differences in sound quality of the sounds SD to be reproduced by the speaker systems 40. In addition, in the sound quality modification element 210, the branching sound signals SB1, SB2 travel in a loop flow in the element body 11 through the two connection cables 215 and 216, so that the influence on the sound quality of the sound SD to be reproduced also differs from that in the configuration using the sound quality modification elements 110 in the fourth to sixth embodiments.

### Eighth Embodiment

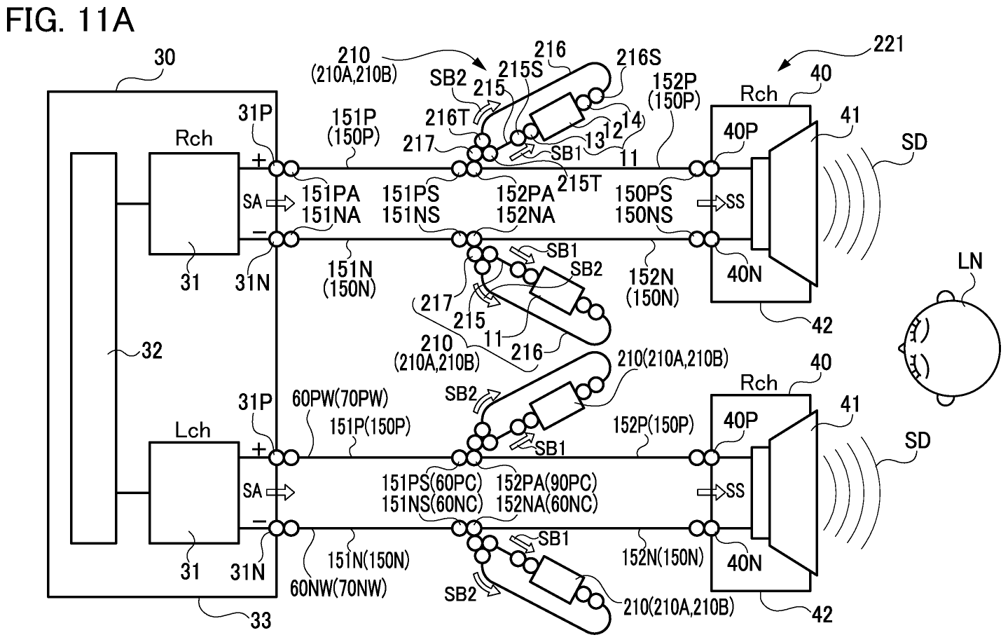

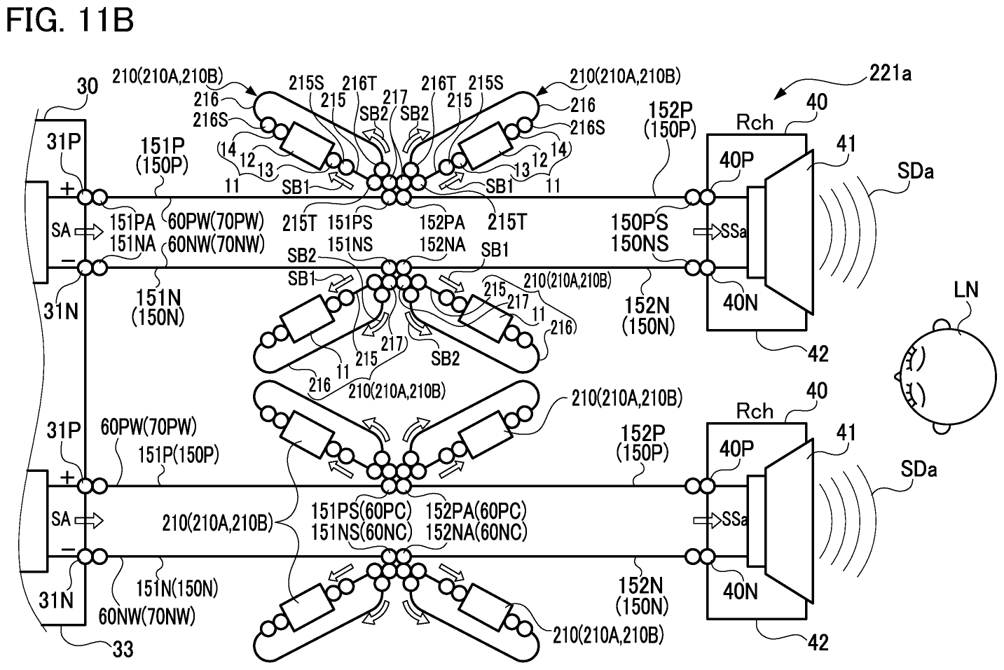

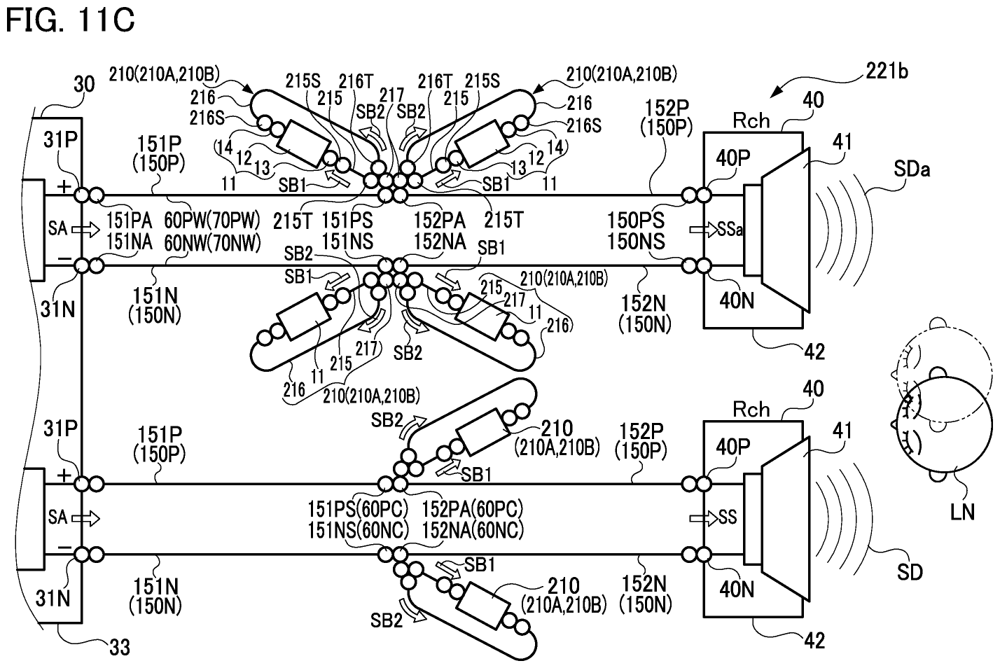

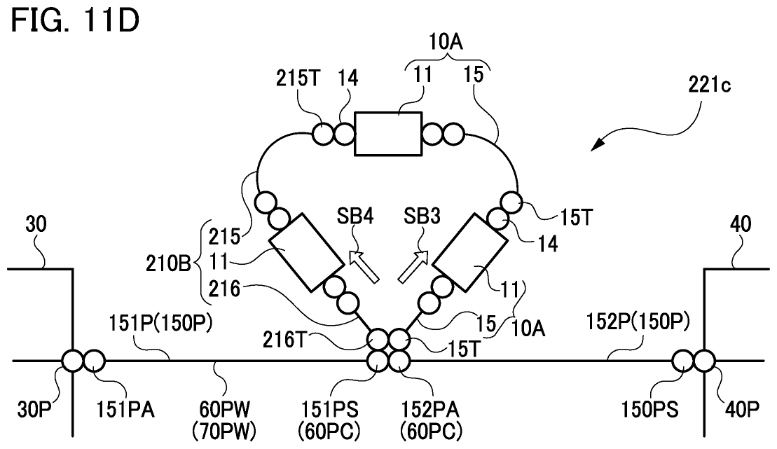

Next, an eighth embodiment will be described referring to FIGS. 11A and 10A.

In a system 221 in the eighth embodiment incorporating the sound quality modification elements 210 shown in FIG. 10A, each sound quality modification element 210 is connected to each of the connection sites 60PC, 60NC in the transmission paths 60PW, 60NW in the system 2 (see FIG. 21) in the basic configuration, concretely, to a midpoint of each speaker cable 50P, 50N. Concretely, as in the fifth embodiment, the speaker cables 150P, 150N each including the first speaker cable 151P, 151N and the second speaker cable 152P, 152N are used instead of the speaker cables 50P, 50N. Each of the terminal members 217 of the sound quality modification elements 210 is connected to the speaker-side end part 151PS, 151NS of the first speaker cable 151P, 151N and the amp-side end part 152PA, 152NA of the second speaker cable 152P, 152N. To be concrete, three parts, i.e., the terminal member 217 of the sound quality modification element 210, the speaker-side end part 151PS of the first speaker cable 151P, and the amp-side end part 152PA of the second speaker cable 152P are joined together and conductively connected to one another by use of a bolt and a retaining nut which are not shown. Further, three parts, i.e., the terminal member 217 of the sound quality modification element 210, the speaker-side end part 151NS of the first speaker cable 151N, and the amp-side end part 152NA of the second speaker cable 152 are joined together and conductively connected to one another by use of a bolt and a retaining nut which are not shown. Thus, the first element terminal parts 13 and the second element terminal parts 14 of the sound quality modification elements 210 (the element bodies 211) are connected to the speaker-side end parts 151PS, 151NS and the amp-side end parts 152PA, 152NA, which correspond to the connection sites 60PC, 60NC respectively located at midpoints in the speaker cables 150P, 150N. The amp-side end parts 151PA, 151NA of the first speaker cables 151P, 151N are respectively connected to the amplifier output terminals 31P, 31N of the amplifier 30. Further, the speaker-side end parts 152PS, 152NS of the second speaker cables 152P, 152N are respectively connected to the speaker input terminals 40P, 40N of each speaker system 40. The system 221 in the eighth embodiment using the sound quality modification elements 210, as with the system 220 in the seventh embodiment, can also change the sound signal SS to modify the sound quality of sound SD to be emitted from the speaker systems 40, as compared with the system 2 not using the sound quality modification element (that is, in the basic configuration).

### Tenth Modified Embodiment

A system 221a in the tenth modified embodiment which is a variation of the eighth embodiment will be described referring to FIGS. 11B and 10A. In the system 221 in the eighth embodiment described above, the sound quality modification elements 210 are connected one to a midpoint of each of the speaker cables 150P, 150N. Differently from this, the system 221a in the tenth embodiment is configured such that a plurality of (two in the tenth modified embodiment) sound quality modification elements 210 is connected to the same connection site 60PC, 60NC located at a midpoint of each speaker cable 150P, 150N. Specifically, four parts, i.e., the terminal members 217 of two sound quality modification elements 210, the speaker-side end part 151PS of the first speaker cable 151P, and the amp-side end part 152PA of the second speaker cable 152P are jointed together with a bolt and a nut not shown and conductively connected to each other. Similarly, the terminal members 217 of other two sound quality modification elements 210, the speaker-side end part 151NS of the first speaker cable 151N, and the amp-side end part 152NA of the second speaker cable 152N are jointed together with a bolt and a nut not shown and conductively connected to each other. Thus, the first element terminal parts 13 and the second element terminal parts 14 of each paired sound quality modification elements 210 (the element bodies 211) are connected to each speaker cable 150P, 150N.

The sound SDa reproduced by the system 221a in the tenth embodiment also differs from the sound SD reproduced by the system 221 in the eighth embodiment using one sound quality modification element 210 for each speaker cable 150P, 150N. The sound quality modification effect by each sound quality modification element 210 is superimposed on the sound signals SSa to be input to the speaker system 40. Thus, the sound quality of the sound to be reproduced by the speaker system 40 can be greatly modified, as compared with the sound SD in the eighth embodiment. The sound quality modification elements 210 to be connected may be designed such that the element block parts 12 have either the same or different dimension. When a plurality of sound quality modification elements including element block parts 12 equal in dimension is used, the sound quality modification effect is deeply generated. Further, when a plurality of sound quality modification elements including element block parts 12 different in dimension is used, for example, when sound quality modification elements 210 in which e.g. the diameters of the element block parts 12 are set to three different dimensions, large/middle/small, are used, the sound quality modification effect by respective sound quality modification elements is superimposed, resulting in the sound quality modification effect exerted over a wide range. Even when the sound quality modification elements 210 are used in the foregoing seventh embodiment and a ninth embodiment described later, and others, the same effect as above can be obtained similarly.

### Eleventh Modified Embodiment

Next, a system 221b in the eleventh embodiment which is a variation of the eighth embodiment will be described referring to FIGS. 11C and 10A. In the systems 221 and 221a in the eighth embodiment and tenth modified embodiment described above, the sound quality modification elements connected in the same pattern between both channels. Specifically, the one sound quality modification element 110 or the plurality of (two in the tenth modified embodiment) sound quality modification elements 210 are connected to a midpoint of each of the paired (two) speaker cables 150P, 150N in a similar manner for each channel (the R channel and the L channel). In the system 221b in the eleventh modified embodiment, in contrast, two sound quality modification elements 210 are connected to a midpoint of each of the paired (two) speaker cables 150P, 150N for the R channel (an upper channel in FIG. 11C) as in the tenth modified embodiment. On the other hand, a single sound quality modification element 210 is connected to a midpoint of each of the paired (two) speaker cables 150P, 150N for the L channel (a lower channel in FIG. 11C) as in the eighth embodiment. In other words, the connected sound quality modification elements in this system 221b are arranged unevenly for the R channel and the L channel.

Accordingly, the speaker system 40 for the R channel (the upper channel in FIG. 11C) receives the sound signal SSa and reproduces the sound SDa as in the tenth modified embodiment, while the speaker system 40 for the L channel receives the sound signal SS and reproduces the sound SD as in the eighth embodiment. This configuration can influence the position of sound images perceptible to a listener LN and displace the position of sound images to be localized by the listener LN. The degree of the effect varies depending on the dimension of the element block part 112 of the sound quality modification element 110 to be used. Concretely, for example, when the listener LN is positioned somewhat close to the left speaker system 40 (a lower side in FIG. 11C) as shown in FIG. 11C, the sound reproduced by the system 121b in the eleventh modified embodiment can be perceived by the listener LN as if a singer or an orchestra is located in front of the listener.

### Twelfth Modified Embodiment

A system 221c in the twelfth modified embodiment which is a variation of the eighth embodiment will be described referring to FIGS. 11D, 2B, and 10C. In the system 221a in the foregoing tenth modified embodiment, the plural (two in the tenth modified embodiment) sound quality modification elements 210 are independently connected to the same position at a midpoint of each of the speaker cables 150P, 150N. In the system 221c in the twelfth modified embodiment, in contrast, a plurality of (three in the twelfth modified embodiment) sound quality modification elements 10A and 210 are first connected in series to each other and further unconnected ones of the element terminal parts 13 and 14 are connected to the same connection sites 60PC, 60NC at a midpoint of each of the speaker cables 150P, 150N, so that the three series-connected sound quality modification elements 10A and 210 are connected in a loop form. Concretely, the second element terminal part 14 of one of the two sound quality modification elements 10A shown in FIG. 2B is connected to the other end part 15T of the first connection cable 15 of the other sound quality modification element 10A with a retaining nut not shown, while the second element terminal part 14 of this other sound quality modification element 10A is connected to the other end part 21ST of the first connection cable 215 of the sound quality modification element 210B shown in FIG. 10C with a retaining nut not shown.

Accordingly, two sound quality modification elements 10A and one sound quality modification element 210B are connected in series to each other. Further, four parts, i.e., the unconnected other end part 15T of the first connection cable 15 of the one sound quality modification element 10A, the unconnected other end part 216T of the second connection cable 216 of the sound quality modification element 210B, the speaker-side end part 151NS of the first speaker cable 151N, and the amp-side end part 152NA of the second speaker cable 152N are jointed together with a bolt and a retaining nut not shown and conductively connected to one another. The same configuration applies to the speaker cable 150N.

The SDa reproduced by the system 221c in the twelfth modified embodiment is different from the sound SD reproduced by the system 221 in the eighth embodiment using one sound quality modification element 210 for each connection cable. The sound quality modification effect by each sound quality modification element is superimposed on the sound signal SSa to be input to the speaker system 40. Thus, the sound quality of the sound SDa to be reproduced by the speaker system 40 is greatly modified as compared with the sound SD in the eighth embodiment. The sound quality modification elements 10A and 210B connected in series to each other may be designed such that their element block parts 12 are either the same or different in dimension. When a plurality of sound quality modification elements including the element block parts 12 equal in dimension is used, the sound quality modification effect is deeply generated. Further, when a plurality of sound quality modification elements including the element block parts 12 different in dimension is used, for example, when the sound quality modification elements in which e.g. the diameters of the element block parts 12 are set to three different dimensions, large/middle/small, are used, the sound quality modification effect by respective sound quality modification elements is superimposed, resulting in the sound quality modification effect exerted over a wide range.

### Ninth Embodiment

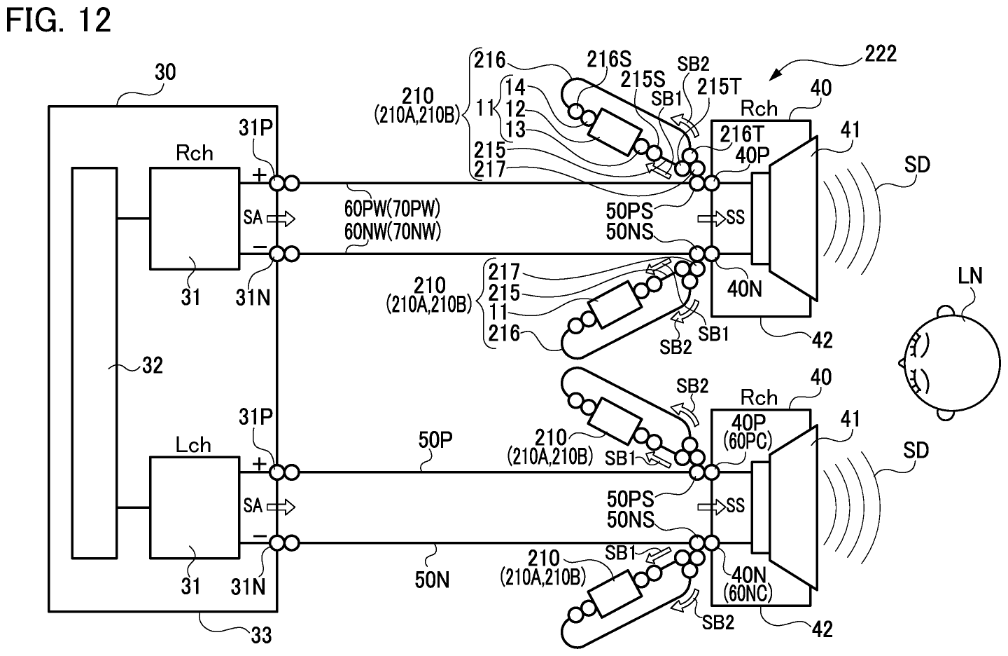

A ninth embodiment will be described below referring to FIGS. 12 and 10A. In a system 222 in the ninth embodiment incorporating the sound quality modification elements 210 shown in FIG. 10A, the terminal members 217 of the sound quality modification elements 210 are connected one to each of the connection sites 60PC, 60NC in the transmission paths 60PW, 60NW in the system 2 (see FIG. 21) in the foregoing basic configuration, concretely, to the speaker input terminals 40P, 40N of each speaker system 40. Thus, the first element terminal part 113 and the second element terminal part 114 of each sound quality modification element 210 (the element body 11) are connected to the same speaker input terminal 40P, 40N. To the speaker input terminals 40P, 40N of each speaker system 40, the speaker-side end parts 50PS, 50NS of the speaker cables 50P, 50N are also connected.

As with the systems 220, 221 in the seventh and eight embodiments, the system 222 in the ninth embodiment using the sound quality modification elements 210 can also change the sound signal SS to modify the sound quality of sound SD to be emitted from the speaker systems 40, as compared with the system 2 not using the sound quality modification element (that is, in the basic configuration).

(Audio Amplifier Apparatus Equipped With a Sound Quality Modification Element)

In the system 220 in the foregoing seventh embodiment (see FIG. 9), the sound quality modification elements 210 (the terminal members 217 thereof) are externally connected to the amplifier output terminals 31P, 31N of the amplifier 30 (the amplifier circuits 31) in the system 2 (see FIG. 21) in the foregoing basic configuration.

### First Modified Embodiment

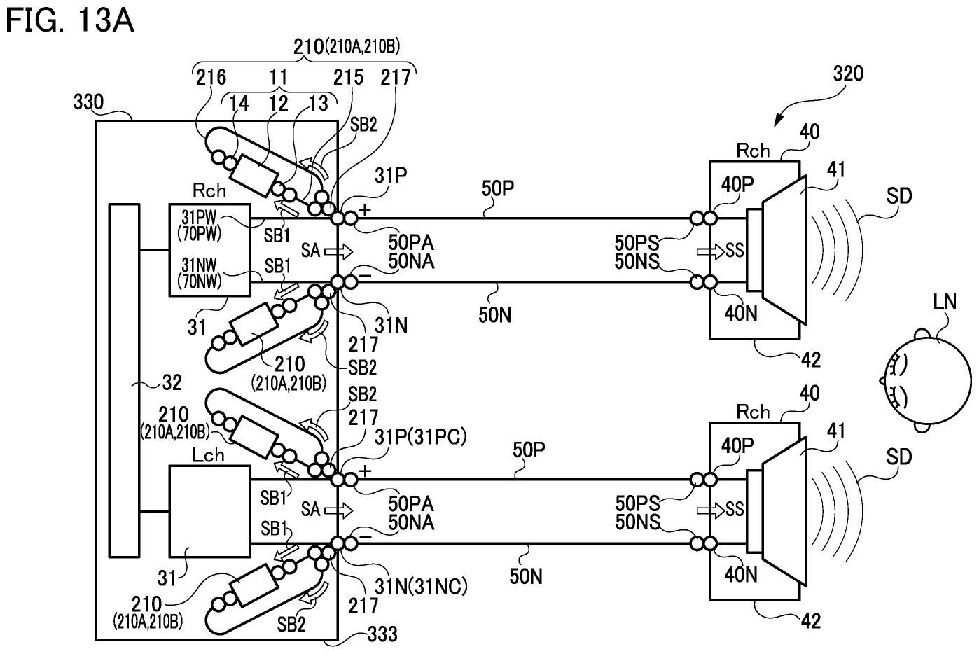

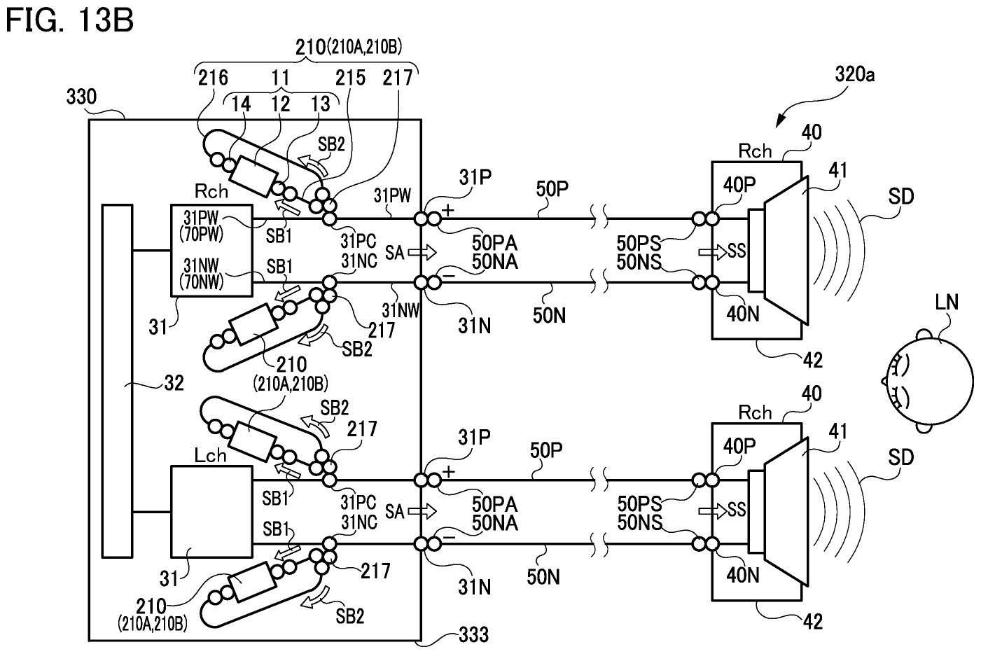

As alternatives, not limited to the above configuration of the seventh embodiment, an amplifier 330 itself may be configured such that the sound quality modification elements 210 are housed in an amplifier casing 333 and therein the sound quality modification elements 210 are connected to one to each of connection sites 31PC, 31NC in the output paths 31PW, 31NW extending from each amplifier circuit 31 to the amplifier output terminals 31P, 31N, for example, connected to the amplifier output terminals 31P, 31N of the output paths 31PW, 31NW. Specifically, as shown in a system 320 in the first modified embodiment (see FIG. 13A) which is a variation of the seventh embodiment, the amplifier 330 may be configured as an audio amplifier apparatus equipped with a sound quality modification element, in which the terminal members 217 of the sound quality modification elements 210 housed in the amplifier casing 333 are connected one to each of the amplifier output terminals 31P, 31N of each amplifier circuit 31 housed in the same amplifier casing 333. Thus, the first element terminal part 13 and the second element terminal part 14 of each sound quality modification element 210 (each element body 11) are connected to the same amplifier output terminal 31P, 31N. In this case, as with the system 2 in the basic configuration, the amplifier output terminals 31P, 31N of the amplifier 330 are respectively connected to the speaker input terminals 40P, 40N of the speaker systems 40 through the corresponding speaker cables 50P, 50N, so that the sound quality modification effect can be produced by the sound quality modification elements 210.

### Thirteenth Modified Embodiment

In the system 320 in the foregoing first modified embodiment, the sound quality modification elements 210 are connected to the amplifier output terminals 31P, 31N of the output paths 31PW, 31NW. Alternatively, as shown in a system 320a in the thirteenth modified embodiment shown in FIG. 13B, the sound quality modification elements 210 may be connected to the connection sites 31PC, 31NC located at midpoints of the output paths 31PW, 31NW extending from the amplifier circuits 31 to the amplifier output terminals 31P, 31N.

### Second Modified Embodiment

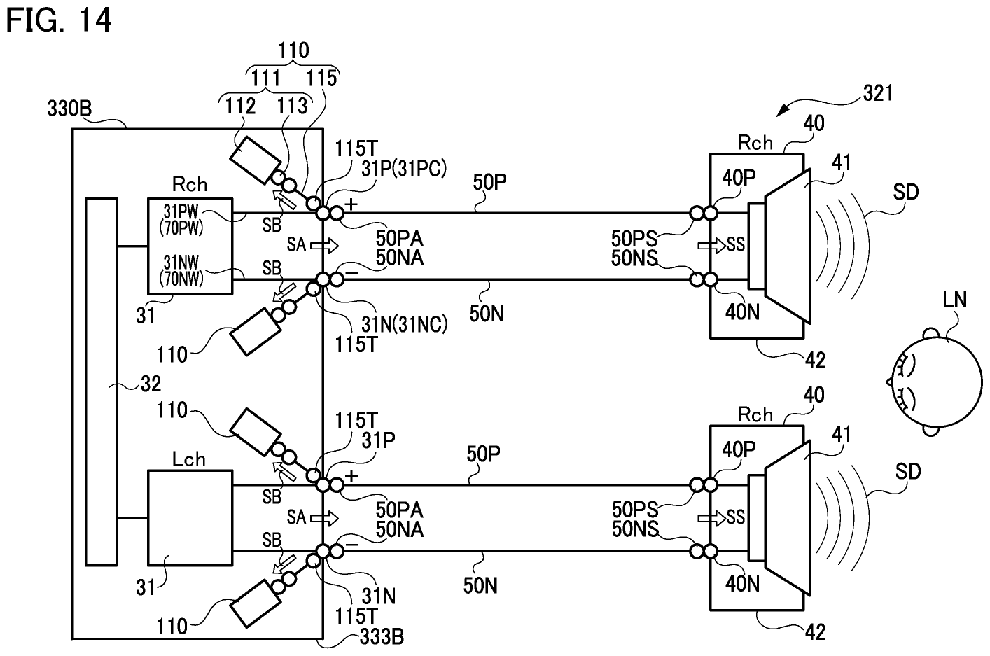

As in the foregoing first modified embodiment, an amplifier 330B itself may be configured such that the sound quality modification elements 110 shown in FIG. 6B are housed in an amplifier casing 333B and therein the sound quality modification elements 110 are connected to one to each of the connection sites 31PC, 31NC in the output paths 31PW, 31NW, for example, to the amplifier output terminals 31P, 31N of the output paths 31PW, 31NW. Specifically, as shown in a system 321 in the second modified embodiment (see FIG. 14) which is a variation of the fourth embodiment, using the sound quality modification elements 110 instead of the sound quality modification elements 210, the amplifier 330B may be configured as an audio amplifier apparatus equipped with a sound quality modification element, in which the other end part 15T of the first connection cable 15 of each sound quality modification element 110 housed in the amplifier casing 333B is connected to each of the amplifier output terminals 31P, 31N of the amplifier circuits 31 housed in the same amplifier casing 333B. Thus, the first element terminal parts 113 of the sound quality modification elements 110 (the element bodies 111) are connected one to each of the amplifier output terminals 31P, 31N. In this case, the amplifier output terminals 31P, 31N of the amplifier 330B are respectively connected to the speaker input terminals 40P, 40N of each speaker system 40 through the corresponding speaker cables 50P, 50N, so that the sound quality modification effect can be produced by the sound quality modification elements 110.

### Third Modified Embodiment

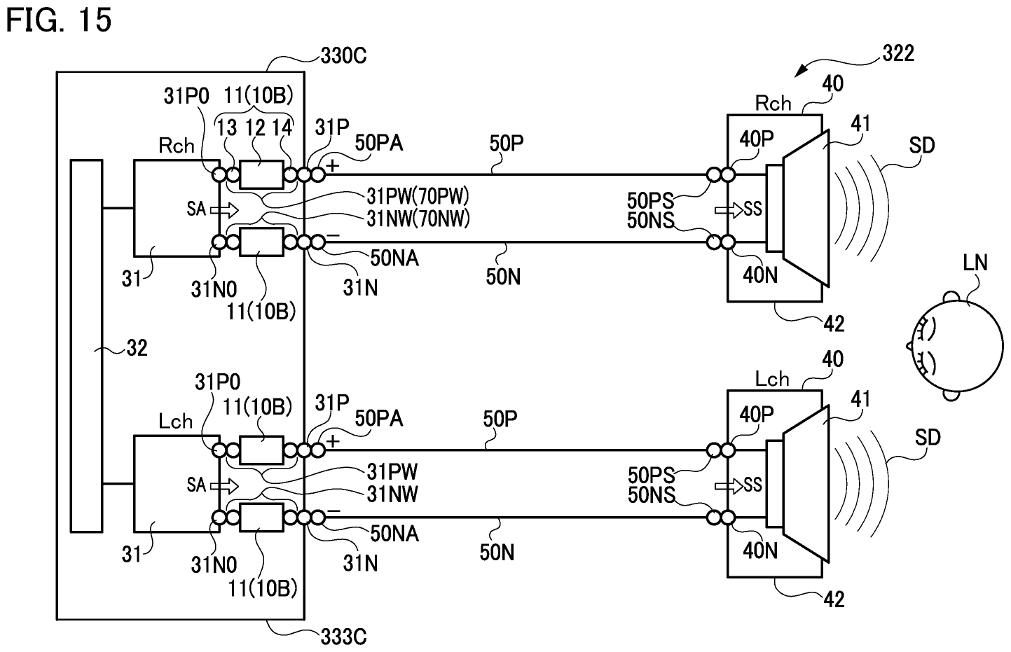

Alternatively, an amplifier 330C itself may be configured such that the sound quality modification elements 10B shown in FIG. 2A are housed in an amplifier casing 333C and therein each of the sound quality modification elements 10B is connected in series to each of the output paths 31PW, 31NW extending from each amplifier circuit 31 to the amplifier output terminals 31P, 31N. Specifically, as shown in a system 322 in the third modified embodiment (see FIG. 15) which is a variation of the second embodiment, each sound quality modification element 10B housed in an amplifier casing 333B of an amplifier 330C is connected in series to each of the output paths 31PW, 31NW each extending between an amplifier output inner terminal 31P0, 31N0 of each amplifier circuit 31 housed in the same amplifier casing 333C and the output terminal 31P, 31N. More concretely, the first element terminal parts 13 of the sound quality modification elements 10B are connected one to each of the amplifier output inner terminals 31P0, 31N0 and the second element terminal parts 14 of the sound quality modification elements 10B are connected one to each of the amplifier output terminals 31P, 31N so that each sound quality modification element 10 is placed in series between the amplifier output internal terminal 31P0 and the amplifier output terminal 31P and between the amplifier output internal terminal 31N0 and the amplifier output terminal 31N. In this case, the amplifier output terminals 31P, 31N of the amplifier 330C are respectively connected to the speaker input terminals 40P, 40N of the speaker systems 40 through the corresponding speaker cables 50P, 50N, so that the sound quality modification effect can be produced by the sound quality modification elements 10B.

(speaker System Equipped with a Sound Quality Modification Element)

In the system 222 in the foregoing ninth embodiment (see FIG. 12), the sound quality modification elements 210 (the terminal members 217 thereof) are externally connected to the speaker input terminals 40P, 40N of each speaker system 40 in the system 2 (see FIG. 21) in the foregoing basic configuration.

### Fourth Modified Embodiment

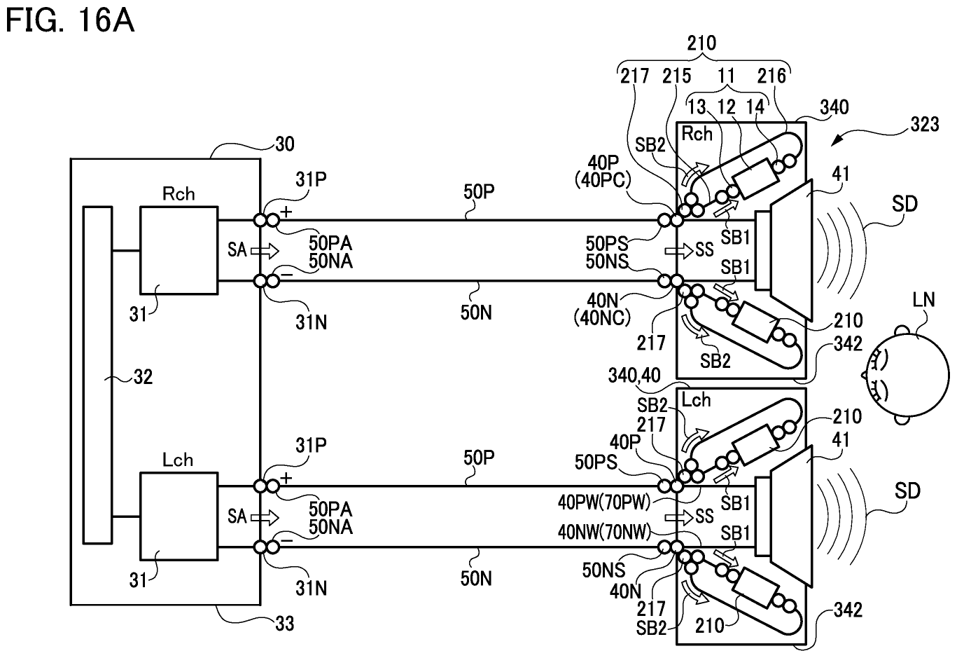

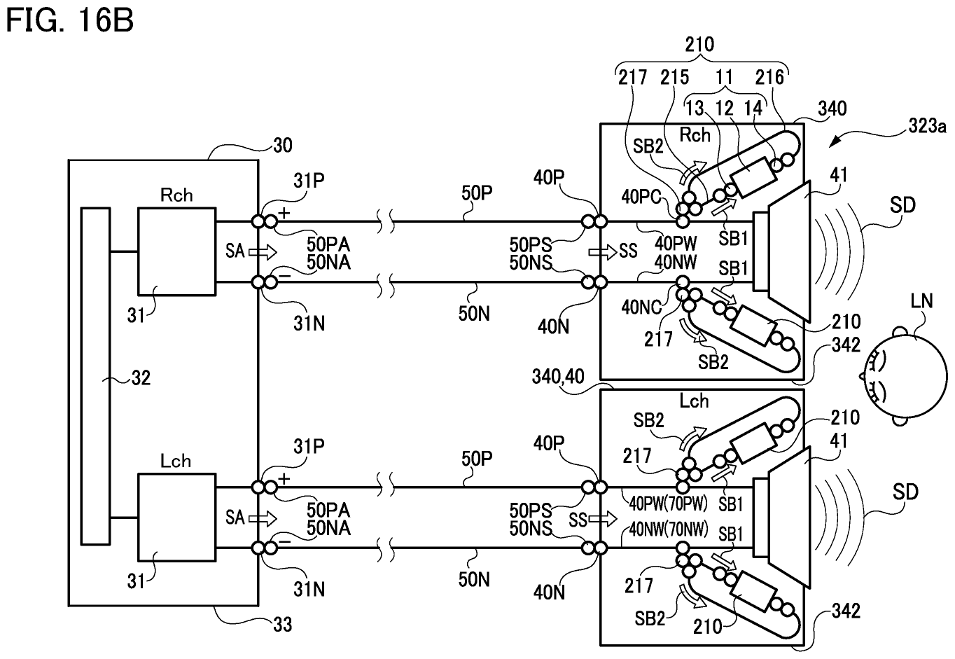

As alternatives, not limited to the foregoing configuration of the ninth embodiment, a speaker system 340 itself may be configured such that the sound quality modification elements 210 are housed in a speaker box 342 and therein the sound quality modification elements 210 are connected one to each of connection sites 40PC, 40NC in input paths 40PW, 40NW extending from the speaker 41 to the speaker input terminals 40P, 40N, for example, connected to the speaker input terminals 40P, 40N of the input paths 40PW, 40NW. Specifically, as shown in a system 323 in the fourth modified embodiment (see FIG. 16A) which is a variation of the ninth embodiment, a speaker system equipped with a sound quality modification element may be configured such that the terminal members 217 of the sound quality modification elements 210 housed in the speaker box 342 are connected one to each of the speaker input terminals 40P, 40N of the speaker system 340. Thus, the first element terminal part 13 and the second element terminal part 14 of each sound quality modification element 210 (each element body 11) are connected to the same one of the speaker input terminals 40P, 40N. In this case, as with the system 2 in the basic configuration, the amplifier output terminals 31P, 31N of the amplifier 30 are connected to the speaker input terminals 40P, 40N of the speaker system 340 through the speaker cables 50P, 50N, so that the sound quality modification can be produced by the sound quality modification elements 210.

### Fourteenth Modified Embodiment

In the system 323 in the foregoing fourth modified embodiment, the sound quality modification elements 210 are connected to the speaker input terminals 40P, 40N of the input paths 40PW, 40NW. Alternatively, as in a system 323a in the fourteenth modified embodiment shown in FIG. 16B, the sound quality modification elements 210 may be connected to the connection sites 40PC, 40NC located at midpoints of the input paths 40PW, 40NW respectively extending from the speaker input terminals 40P, 40N to the speaker 41.

### Fifth Modified Embodiment

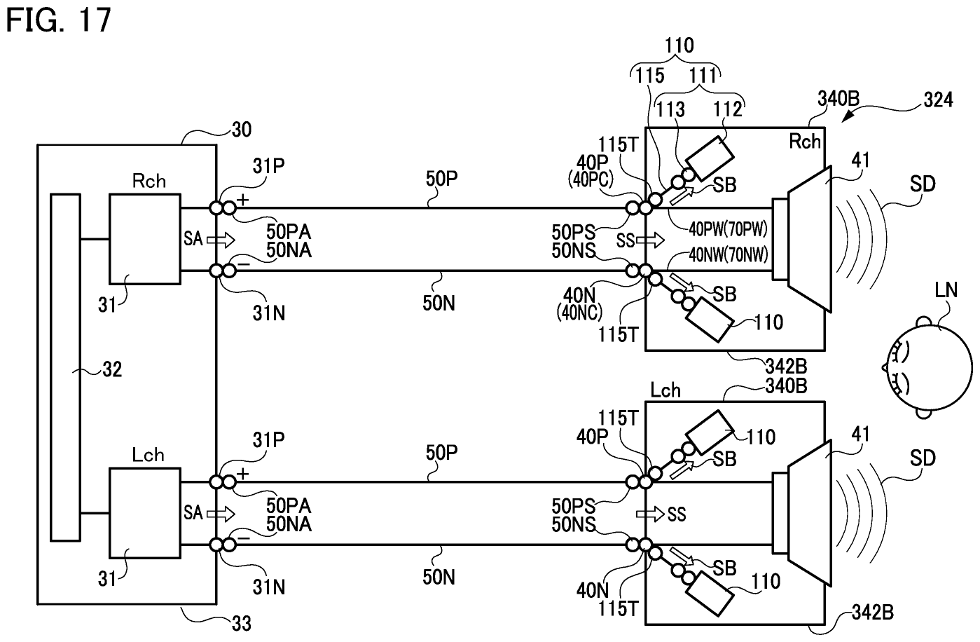

As in the foregoing fourth modified embodiment, a speaker system 340B itself may be configured such that the sound quality modification elements 110 shown in FIG. 6B are housed in a speaker box 324B and therein the sound quality modification elements 110 are connected one to each of the connection sites 40PC, 40NC in the input paths 40PW, 40NW, for example to the speaker input terminals 40P, 40N of the input paths 40PW, 40NW. Specifically, as shown in a system 324 in a fifth modified embodiment (see FIG. 17) which is a variation of the sixth embodiment, using the sound quality modification elements 110 instead of the sound quality modification elements 210, a speaker system equipped with sound quality modification element may be configured such that the other end part 15T of the first connection cable 15 of each sound quality modification element 110 housed in the speaker box 342B is connected to the speaker input terminal 40P, 40N of the speaker system 340B. Thus, the the first element terminal parts 113 of the sound quality modification elements 110 (the element bodies 111) are connected one to each of the speaker input terminals 40P, 40N. In this case, the amplifier output terminals 31P, 31N of the amplifier 30 are respectively connected to the speaker input terminals 40P, 40N of the speaker system 340B through the corresponding speaker cables 50P, 50N, so that the sound quality modification effect can be produced by the sound quality modification elements 110.

### Sixth Modified Embodiment

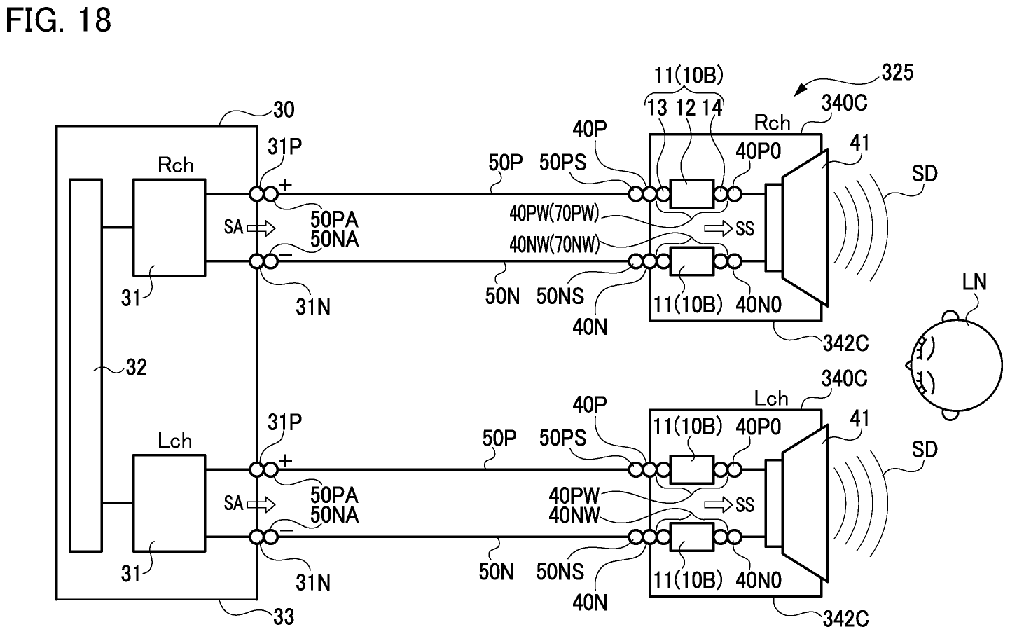

Alternatively, a speaker system 340C itself may be configured such that the sound quality modification elements 10B shown in FIG. 2A are housed in a speaker box 342C and therein each of the sound quality modification elements 10B is connected in series to each of the input paths 40PW, 40NW respectively extending from the speaker input terminals 40P, 40N to each speaker 41. Specifically, as shown in a system 325 in the sixth modified embodiment (see FIG. 18) which is a variation of the third embodiment, each sound quality modification elements 10B housed in a speaker box 342C may be connected in series to each of the input paths 40PW, 40NW respectively extending between the speaker input terminals 40P, 40N provided in the same speaker box 342C of the speaker system 340C and speaker input inner terminals 40P0, 40N0. More concretely, the first element terminal parts 13 of the sound quality modification elements 10B are connected one to each of the speaker input terminals 40P, 40N and the second element terminal parts 14 of the sound quality modification elements 10B are connected one to each of the speaker input inner terminals 40P0, 40N0 so that each sound quality modification element 10 is placed in series between the speaker input terminal 40P, 40N and the speaker input inner terminal 40P0, 40N0. In this case, the amplifier output terminals 31P, 31N of the amplifier 30 are respectively connected to the speaker input terminals 40P, 40N of the speaker systems 40 through the corresponding speaker cables 50P, 50N, so that the sound quality modification effect can be produced by the sound quality modification elements 10B.

### Tenth and Eleventh Embodiments

Next, the tenth and eleventh embodiments will be described referring to FIGS. 19, 20, and 10A. In the foregoing seventh embodiment (see FIG. 9), the terminal members 217 of the sound quality modification elements 210 shown in FIG. 10A are connected one to each of the amplifier output terminals 31P, 31N of the amplifier 30 (each amplifier circuit 31). That is, a pair of (two) sound quality modification elements 210 is provided for each channel.

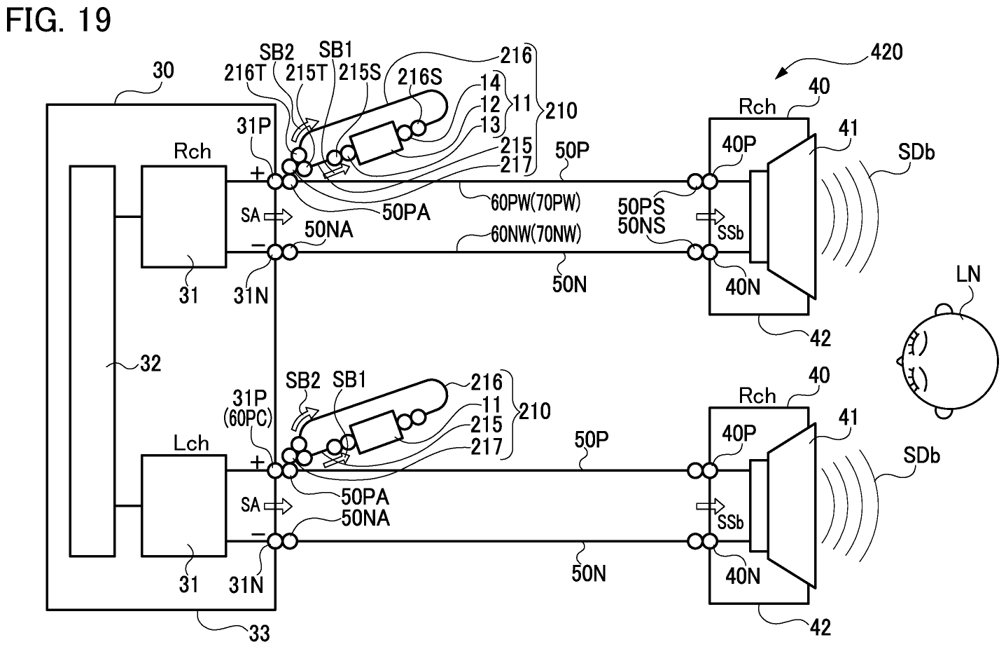

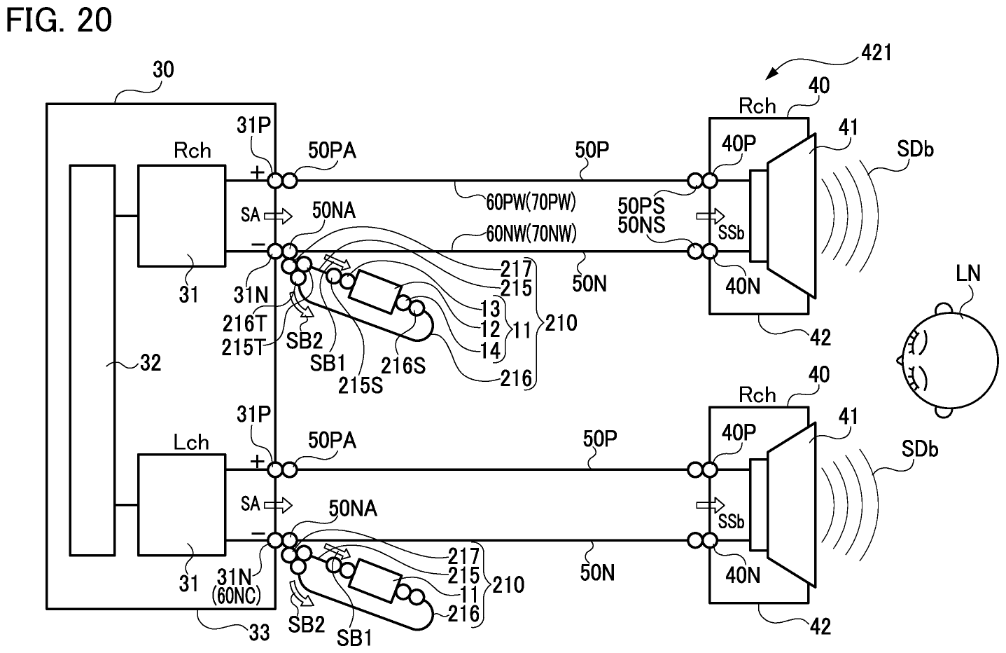

In a system 420 in the tenth embodiment (see FIG. 19), in contrast, the terminal member 217 of the sound quality modification element 210 is connected to only the amplifier output terminal 31P on one side in the amplifier 30 (each amplifier circuit 31) in the system 2 in the foregoing basic configuration (see FIG. 21). Accordingly, the first element terminal part 13 and the second element terminal part 14 of each sound quality modification element 210 (each element body 11) are connected to the same amplifier output terminal 31P. In a system 421 in the eleventh embodiment (see FIG. 20), the terminal member 217 of the sound quality modification element 210 is connected to only the amplifier output terminal 31N on one side in the amplifier 30 (each amplifier circuit 31) in the system 2 in the foregoing basic configuration (see FIG. 21). Accordingly, the first element terminal part 13 and the second element terminal part 14 of each sound quality modification element 210 (each element body 11) are connected to the same amplifier output terminal 31N. The amplifier output terminals 31P, 31N of the amplifier 30 (the amplifier circuits 31) are also connected to the amp-side end parts 50PA, 50NA of the speaker cables 50P, 50N respectively. Thus, each speaker 41 receives a sound signal SSb.

Even the systems 420, 421 in the tenth and eleventh embodiments using the sound quality modification elements 210, one for each channel, can also modify the sound quality of the sound SDb to be emitted from the speaker systems 40 as with the system 220 in the seventh embodiment, as compared with the sound SD0 produced by the system 2 not using the sound quality modification element (that is, in the basic configuration). However, those systems are inferior in sound quality modification that clearly modifies each tone, as compared with the system 220 in the seventh embodiment using the paired sound quality modification elements 210 (two sound quality modification elements 210) for each channel. As an alternative, instead of the sound quality modification elements 210, the sound quality modification elements 10B or the sound quality modification elements 110 may be provided one for each channel.

<Consideration of Dimensions of the Sound Quality Modification Elements (the Element Block Parts)>

### Examples 1-1 to 1-4, 2 to 15

A relationship between the shape (dimension) of the element block parts 12 and 112 of the sound quality modification elements 10B, 110, and 210 and the resultant effects of sound quality modification were investigated. In the following investigations, as shown in the system 21 in the second embodiment (see FIG. 3A), each sound quality modification element 10B is connected in series between the speaker-side end part 151PS, 151NS of the first speaker cable 151P, 151N and the amp-side end part 152PA, 152NA of the second speaker cable. In the following description, this connection pattern of the sound quality modification element 10B (10A, 10C) is referred to as a “series connection”. As shown in the systems 121, 221 in the fifth and eighth embodiments (see FIGS. 7A and 11A), furthermore, each sound quality modification element 110, 210 is connected to the speaker-side end part 151PS, 151NS of the first speaker cable 151P, 151N and the amp-side end part 152PA, 152NA of the second speaker cable. In the following description, the connection pattern of the sound quality modification element 110 is referred to as a “one-end connection” and the connection pattern of the sound quality modification element 210 is referred to as a “loop connection”.

Several samples of the sound quality modification elements 10B, 110, 210 in which the element block parts 12, 112 are different in shape (dimension) were produced. In each of the systems 21, 121, 221 in the second, fifth, and eighth embodiments, the same music CD was played by the CD drive part 32 and three evaluators A, B, and C listened to the music reproduced from the speakers 41 and evaluated the sound quality, such as extension of the sound SD and clearness of the sound SD, and others, about “high tones (treble)” and “low tones (bass)” separately.

The sound range of “high tones” in this evaluation generally refers to the mid-range (320 to 2600 Hz) and the mid-high range (2600 to 5000 Hz), and include many sounds, such as sounds of soprano voice, flute, piccolo, and violin treble strings. The sound range of “low tones” generally refers to the deep low range (16 to 40 Hz) and the low range (40 to 160 Hz), and include many sounds, such as sounds of bass voice, bass tubas, contrabass, and others. The range of an 88-key piano is A0 to C8 (27.5 to 4186Hz). Further, the music CD was similarly played by the system 2 in the reference configuration (see FIG. 21) not using the sound quality modification elements 10B, 110, 210. The reproduced sounds are evaluated in ten steps in which the evaluation of the sound SD0 is assumed as a reference (=1) and the best sounds reproduced in Examples 14 and 15 (eighth embodiment) are evaluated as 10.

In the audio system 2 in the basic configuration, a stereo amplifier, The-t.amp S-100 mk2 manufactured by Thomann UK, was used as the amplifier 30. Further, as the speaker system 40, a speaker box (an enclosure) MM-161 manufactured by Hasehiro Audio attached with a full-range speaker Alpair6 manufactured by Mark Audio was used. Further, for each of the first and second speaker cables 151P, 151N, 152P, 152N, an N-SKILL, heat-resistant, H-VFF, OFC speaker cord of 2 m, manufactured by Furukawa Electric Co., Ltd., was used. The speaker cables 50P and 50N were respectively prepared by connecting the first speaker cable 151P and the first speaker cable 151N and by connecting the second speaker cable 152P and the second speaker cable 152N.

As the music pieces in the music CDs used in the evaluation, the following three pieces were listened: 1. Air on the G String, SADO Yutaka, Hyogo Performing Arts Center Orchestra, from SADO Yutaka BEST x BEST ballade & passion (AVCL-25728/9, Avex Classics International Inc.); 2. First movement, Allegro, from concerto No. 1 in E major RV 269 “Spring”, Vivaldi: I Musici (I Musici, Ayo, Polygram Co., Ltd.); and 3. Christmas Song from KENNY G miracles (BMG Victor Co., Ltd.). Of those music pieces, particularly, the music piece 1 (Air on the G String) was evaluated with attention to the timbre of the contrabass. The music piece 2 (Spring) was evaluated with attention to the timbre of the treble part of violin. The music piece 3 (Christmas Song) was evaluated with attention to the timbre of the soprano sax, particularly, the timbre of its vibrato part.

In Examples 1-1 to 1-4, the diameters D of the element block parts 12 of the sound quality modification elements 10B are set to constant 10 mmφ, and the lengths L of the element block parts 12 are set to different 10, 20, 30, and 42 mm.

In Examples 1-4 and 2 to 15, the diameters D and the lengths L are variously set: concretely, D×L=10 mmφ×42 mm (Examples 1-4, 6, 11), 50 mmφ×20 mm (Examples 2, 7, 12), 100 mmφ×16 mm (Examples 3, 8, 13), 200 mmφ×18 mm (Examples 4, 9, 14), and 300 mmφ×19 mm (Examples 5, 10, 15). The materials of both the element bodies 11, 111 are oxygen-free copper (JIS: C1020, no plating, no coating layer, no vibration-proof layer). The results of each example are shown in Tables 1, 2, and 3.

TABLE 1

| | | MATERIAL OF | | | CONNECTING | | |
|---|---|---|---|---|---|---|---|
| | | ELEMENT | ELEMENT_D | ELEMENT_L | DESTINATION OF | CONNECTION | |
| | | BODY | (mm) | (mm) | ELEMENT | PATTERN | FIG |
| BASIC CONFIGURATION | | NONE | NONE | NONE | NONE | NONE | FIG. 21 |
| 2ND | EXAMPLE 1-1 | OXYGEN-FREE | 10 | 10 | SPEAKER | SERIES | FIG. 3 |
| EMBODIMENT | | COPPER (C1020) | | | CABLE | CONNECTION | |
| | EXAMPLE 1-2 | OXYGEN-FREE | 10 | 20 | SPEAKER | SERIES | FIG. 3 |
| | | COPPER (C1020) | | | CABLE | CONNECTION | |
| | EXAMPLE 1-3 | OXYGEN-FREE | 10 | 30 | SPEAKER | SERIES | FIG. 3 |
| | | COPPER (C1020) | | | CABLE | CONNECTION | |
| | EXAMPLE 1-4 | OXYGEN-FREE | 10 | 42 | SPEAKER | SERIES | FIG. 3 |
| | | COPPER (C1020) | | | CABLE | CONNECTION | |
| | EXAMPLE 2 | OXYGEN-FREE | 50 | 20 | SPEAKER | SERIES | FIG. 3 |
| | | COPPER (C1020) | | | CABLE | CONNECTION | |
| | EXAMPLE 3 | OXYGEN-FREE | 100 | 16 | SPEAKER | SERIES | FIG. 3 |
| | | COPPER (C1020) | | | CABLE | CONNECTION | |
| | EXAMPLE 4 | OXYGEN-FREE | 200 | 18 | SPEAKER | SERIES | FIG. 3 |
| | | COPPER (C1020) | | | CABLE | CONNECTION | |
| | EXAMPLE 5 | OXYGEN-FREE | 300 | 19 | SPEAKER | SERIES | FIG. 3 |
| | | COPPER (C1020) | | | CABLE | CONNECTION | |

| | | EVALUATOR | | EVALUATOR | | EVALUATOR | | AVERAGE | |
|---|---|---|---|---|---|---|---|---|---|
| | | A | | B | | C | | EVALUATION | |
| | | HIGH | LOW | HIGH | LOW | HIGH | LOW | HIGH | LOW |
| | | TONE | TONE | TONE | TONE | TONE | TONE | TONE | TONE |
| BASIC CONFIGURATION | | 1 | 1 | 1 | 1 | 1 | 1 | 1.0 | 1.0 |
| 2ND | EXAMPLE 1-1 | 1.5 | 1 | 2 | 2 | 1 | 2 | 1.5 | 1.7 |
| EMBODIMENT | EXAMPLE 1-2 | 2 | 1.5 | 2 | 2 | 2 | 2 | 2.0 | 1.8 |
| | EXAMPLE 1-3 | 2.5 | 2 | 3 | 2 | 3 | 2 | 2.8 | 2.0 |
| | EXAMPLE 1-4 | 3 | 3 | 3 | 3 | 3 | 3 | 3.0 | 3.0 |
| | EXAMPLE 2 | 5 | 5 | 5 | 6 | 5 | 6 | 5.0 | 5.7 |
| | EXAMPLE 3 | 7 | 8 | 7 | 8 | 6 | 8 | 6.7 | 8.0 |
| | EXAMPLE 4 | 7 | 8 | 8 | 8 | 7 | 8 | 7.3 | 8.0 |
| | EXAMPLE 5 | 7 | 8 | 8 | 8 | 7 | 8 | 7.3 | 8.0 |

| | | | | EVALUATION IN |
|---|---|---|---|---|
| | | | | EMBODIMENTS AND |
| | | | EVALUATION | BETWEEN |
| | | | PER EXAMPLE | EMBODIMENTS |
| BASIC CONFIGURATION | | | Assumed as reference | |
| | | | (=1) | |
| | 2ND | EXAMPLE 1-1 | Each high tone is | Results in Examples 1-1 to |
| | EMBODIMENT | | slightly clearer | 1-4 show that the longer |
| | | | than Reference | the element body, the |
| | | | configuration. | larger the effect of sound |
| | | EXAMPLE 1-2 | Each high tone is | quality modification. |
| | | | clearer than | The larger the diameter |
| | | | Reference | D of the element body, |
| | | | configuration. | the grater the effect of |
| | | | Better than | sound quality modification |
| | | | Example 1-1. | in both high tones and |
| | | EXAMPLE 1-3 | Each low tone and | low tones. |
| | | | each high tone are | For D of 200φ or more, |
| | | | both clear. Better | the effect reaches the |
| | | | than Example 1-2. | limit. |
| | | EXAMPLE 1-4 | Each low tone and | |
| | | | each high tone are | |
| | | | both clear. Better | |
| | | | than Example 1-3. | |
| | | EXAMPLE 2 | Each low tone and | |
| | | | each high tone are | |
| | | | both further clear. | |
| | | | Better than Example | |
| | | | 1-4. | |
| | | EXAMPLE 3 | Each low tone and | |
| | | | each high tone are | |
| | | | both further clear. | |
| | | | Better than | |
| | | | Example 2. | |
| | | EXAMPLE 4 | Each low tone and | |
| | | | each high tone are | |
| | | | both further clear. | |
| | | | There is not such a | |
| | | | large difference in | |
| | | | change as a | |
| | | | difference in change | |
| | | | from Example 2 | |
| | | | (φ50) to Example 3 | |
| | | | (φ100). But better | |
| | | | than Example 3 | |
| | | | (φ100). | |
| | | EXAMPLE 5 | Both each low | |
| | | | tone and each high | |
| | | | tone are further | |
| | | | clear. The same level | |
| | | | as Example 4 (φ200). | |

TABLE 2

| | | MATERIAL OF | | | CONNECTING | | |
|---|---|---|---|---|---|---|---|
| | | ELEMENT | ELEMENT_D | ELEMENT_L | DESTINATION OF | CONNECTION | |
| | | BODY | (mm) | (mm) | ELEMENT | PATTERN | FIG |
| BASIC CONFIGURATION | | NONE | NONE | NONE | NONE | NONE | FIG. |
| | | | | | | | 21 |
| 5TH | EXAMPLE 6 | OXYGEN-FREE | 10 | 42 | SPEAKER | ONE-END | FIG. |
| EMBODIMENT | | COPPER (C1020) | | | CABLE | CONNECTION | 7 |
| | EXAMPLE 7 | OXYGEN-FREE | 50 | 20 | SPEAKER | ONE-END | FIG. |
| | | COPPER (C1020) | | | CABLE | CONNECTION | 7 |
| | EXAMPLE 8 | OXYGEN-FREE | 100 | 16 | SPEAKER | ONE-END | FIG. |
| | | COPPER (C1020) | | | CABLE | CONNECTION | 7 |
| | EXAMPLE 9 | OXYGEN-FREE | 200 | 18 | SPEAKER | ONE-END | FIG. |
| | | COPPER (C1020) | | | CABLE | CONNECTION | 7 |
| | EXAMPLE 10 | OXYGEN-FREE | 300 | 19 | SPEAKER | ONE-END | FIG. |
| | | COPPER (C1020) | | | CABLE | CONNECTION | 7 |

| | | EVALUATOR | | EVALUATOR | | EVALUATOR | | AVERAGE | |
|---|---|---|---|---|---|---|---|---|---|
| | | A | | B | | C | | EVALUATION | |
| | | HIGH | LOW | HIGH | LOW | HIGH | LOW | HIGH | LOW |
| | | TONE | TONE | TONE | TONE | TONE | TONE | TONE | TONE |
| BASIC CONFIGURATION | | 1 | 1 | 1 | 1 | 1 | 1 | 1.0 | 1.0 |
| 5TH | EXAMPLE 6 | 4.3 | 2.3 | 4 | 2 | 5 | 2 | 4 | 3 |
| EMBODIMENT | EXAMPLE 7 | 6.2 | 4.0 | 6 | 4 | 6.5 | 4 | 6 | 4 |
| | EXAMPLE 8 | 8.0 | 6.3 | 8 | 7 | 8 | 6 | 8 | 6 |
| | EXAMPLE 9 | 9.0 | 7.0 | 9 | 7 | 9 | 7 | 9 | 7 |
| | EXAMPLE 10 | 9.0 | 7.0 | 9 | 7 | 9 | 7 | 9 | 7 |

| | | | | EVALUATION IN |
|---|---|---|---|---|
| | | | | EMBODIMENTS AND |
| | | | EVALUATION | BETWEEN |
| | | | PER EXAMPLE | EMBODIMENTS |
| BASIC CONFIGURATION | | | Assumed as reference | |
| | | | (=1) | |
| | 5TH | EXAMPLE 6 | Each low tone and | In one-end connection, |
| | EMBODIMENT | | high tone are | high tones are more |
| | | | clearer than | extended and low tones |
| | | | Reference | are less extended than |
| | | | configuration. | in series connection. |
| | | EXAMPLE 7 | Balanced sound in | |
| | | | low and high tones | |
| | | | than Example 6. | |
| | | EXAMPLE 8 | Balanced sound in | The larger the |
| | | | low and high tones. | diameter D of the |
| | | | Increased realism | element body, the |
| | | | more than Example 7. | greater the effect of |
| | | EXAMPLE 9 | Balanced sound in | sound quality |
| | | | low and high tones. | modification in both |
| | | | Further increased | high tones and low |
| | | | realism more than | tones. |
| | | | Example 8. | |
| | | EXAMPLE 10 | Balanced sound in | For D of 200φ or |
| | | | low and high tones. | more, the effect |
| | | | Further increased | reaches the limit. |
| | | | realism. The same | |
| | | | level as Example 9. | |

TABLE 3

| | | MATERIAL OF | | | CONNECTING | | |
|---|---|---|---|---|---|---|---|
| | | ELEMENT | ELEMENT_D | ELEMENT_L | DESTINATION OF | CONNECTION | |
| | | BODY | (mm) | (mm) | ELEMENT | PATTERN | FIG |
| BASIC CONFIGURATION | | NONE | NONE | NONE | NONE | NONE | FIG. 21 |
| 8TH | EXAMPLE 11 | OXYGEN-FREE | 10 | 42 | SPEAKER | LOOP | FIG. 11 |
| EMBODIMENT | | COPPER (C1020) | | | CABLE | CONNECTION | |
| | EXAMPLE 12 | OXYGEN-FREE | 50 | 20 | SPEAKER | LOOP | FIG. 11 |
| | | COPPER (C1020) | | | CABLE | CONNECTION | |
| | EXAMPLE 13 | OXYGEN-FREE | 100 | 16 | SPEAKER | LOOP | FIG. 11 |
| | | COPPER (C1020) | | | CABLE | CONNECTION | |
| | EXAMPLE 14 | OXYGEN-FREE | 200 | 18 | SPEAKER | LOOP | FIG. 11 |
| | | COPPER (C1020) | | | CABLE | CONNECTION | |
| | EXAMPLE 15 | OXYGEN-FREE | 300 | 19 | SPEAKER | LOOP | FIG. 11 |
| | | COPPER (C1020) | | | CABLE | CONNECTION | |

| | | EVALUATOR | | EVALUATOR | | EVALUATOR | | AVERAGE | |
|---|---|---|---|---|---|---|---|---|---|
| | | A | | B | | C | | EVALUATION | |
| | | HIGH | LOW | HIGH | LOW | HIGH | LOW | HIGH | LOW |
| | | TONE | TONE | TONE | TONE | TONE | TONE | TONE | TONE |
| BASIC CONFIGURATION | | 1 | 1 | 1 | 1 | 1 | 1 | 1.0 | 1.0 |
| 8TH | EXAMPLE 11 | 5.5 | 5 | 6 | 5 | 5 | 6 | 5.5 | 5.3 |
| EMBODIMENT | EXAMPLE 12 | 7 | 6 | 7 | 6 | 6 | 7 | 6.7 | 6.3 |
| | EXAMPLE 13 | 9 | 9 | 10 | 10 | 9 | 10 | 9.3 | 9.7 |
| | EXAMPLE 14 | 10 | 10 | 10 | 10 | 10 | 10 | 10.0 | 10.0 |
| | EXAMPLE 15 | 10 | 10 | 10 | 10 | 10 | 10 | 10.0 | 10.0 |

| | | | | EVALUATION IN |
|---|---|---|---|---|
| | | | | EMBODIMENTS AND |
| | | | EVALUATION | BETWEEN |
| | | | PER EXAMPLE | EMBODIMENTS |
| BASIC CONFIGURATION | | | Assumed as reference | |
| | | | (=1) | |
| | 8TH | EXAMPLE 11 | Each low tone and | In loop connection, |
| | EMBODIMENT | | high tone are | high tones are more |
| | | | clearer than | extended than in |
| | | | Reference | series and one-end |
| | | | configuration. | connections. |
| | | | Balanced sound. | |
| | | EXAMPLE 12 | Balanced sound in | |
| | | | low and high tones. | |
| | | | Increased realism | |
| | | | more than Example | |
| | | | 11. | |
| | | EXAMPLE 13 | Balanced sound in | Extended low tones |
| | | | low and high tones. | are also reproduced. |
| | | | Increased realism | The significant |
| | | | more than Example | effect of sound |
| | | | 12. Somewhat inferior | quality modification |
| | | | to pure aluminum | is obtained. |
| | | | (Example 35), while | |
| | | | it is influenced by | |
| | | | the length L. | |
| | | EXAMPLE 14 | Balanced sound in | For D of 200φ or |
| | | | low and high tones. | more, the effect |
| | | | Sufficient realism. | reaches the limit. |
| | | | Better than Example | |
| | | | 13. | |
| | | EXAMPLE 15 | Balanced sound in | |
| | | | low and high tones. | |
| | | | Sufficient realism. | |
| | | | The same level as | |
| | | | Example 14. | |

### Examples 1-1 to 1-4

According to Table 1, the evaluation results of Examples 1-1 to 1-4 (D=constant 10 mmφ, L=10 to 42 mm) reveal that the longer the length L of the element block part 12 of the sound quality modification element 10B, the greater the effect that modifies the sound quality of the sound SD reproduced from the speaker system 40. Concretely, as the length L of the element block part 12 is longer, each tone in the “high tones” (the mid-range and mid-high range) is more clearly emphasized, as compared with the sound SD0 reproduced by the reference configuration (no element). In the “low tones” (the deep low range and low range), similarly, each tone is more clearly emphasized as the length L of the element block part 12 is longer, even though it is evaluated lower than the “high tones”.

As understood from the above results, the length of the element block part 12 influences the degree of the sound quality modification that clearly emphasizes each tone, and the greater sound quality modification effect is obtained as the length L is longer.

In Examples 1-1 to 1-4, the sound quality modification element 10B is connected in the “series connection” pattern in the system 21 shown in FIG. 3A. However, even when the sound quality modification elements 110, 210 in the systems 121, 221 shown in FIGS. 7A, 11A are connected in the “one-end connection” or “loop connection” pattern, in which the diameter D of each of the element block parts 112, 12 of the sound quality modification elements 110, 210 is set to a fixed dimension, 10 mmφ, and the length L is set to different dimensions, 10, 20, 30, and 42 mm, even though it is not shown in Tables 2 and 3, it is also confirmed that the longer the length L of the element block parts 112, 12, the greater the degree of the sound quality modification that each tone is clearly emphasized.

If the length L of the element block part 12 is below 5 mm, the sound quality modification effect is slight. Thus, there is less advantage in intentionally using the sound quality modification element 10B and others. The length L is therefore preferably set to equal to or more than 5 mm.

### Examples 1-4 and 2 to 5

Next, in Examples 1-4 and 2 to 15, in the system 21 in the second embodiment (see FIG. 3A) in which the sound quality modification element 10B is connected in the “series connection” pattern, the diameter D and the length L of the element block part 12 are set different between these examples. The results thereof reveal the following facts (see Table 1). When the sound quality modification element 10B is used, the diameter D of the element block part 12 generally influences the range of a tone pitch (a sound range) of tones individually clearly emphasized and the degree of the effect. That is, the larger the diameter D of the element block part 12, the greater the degree of the sound quality modification that clearly emphasizes each tone in the “high tones” (the mid-range, the mid-high range). Regarding the “low tones” (the deep low range, the low range), similarly, the larger the diameter D of the element block part 12, the greater the degree of the sound quality modification that clearly emphasizes each tone. In addition, this greater effect tends to be perceived more greatly as the diameter D is larger as compared with the “high tones”.

It is however revealed that, for the diameter D of exceeding 200 mmφ, the degree of modifying the sound quality in the “high tones” and the “low tones” is almost equal between the examples and the increase in the effect reaches the limit (the effect is saturated). In contrast, when the diameter D is set larger, the body size of the sound quality modification element 10B is also increased, resulting in an increased weight. Therefore, the diameter D only has to be set to equal to or less 300 mmφ. It is found from those results that, for the “series connection” (Examples 1-4 and 2 to 5), the best sound quality modification is obtained by the configuration that the diameter D is 200 mmφ (Example 4).

On the other hand, when the diameter D of the element block part 12 is below 5 mm, the sound quality modification effect that clearly emphasizes each tone is obtained more in the “high tones” than in other ranges and the reproduced sound is apt to lose balance. To avoid such a defect, therefore, the diameter D is preferably set to equal to or more than 5 mmφ.

### Examples 6 to 10

Next, in Examples 6 to 10 using the system 121 in the fifth embodiment (see FIG. 7A) in which the sound quality modification element 110 is connected in the “one-end connection” pattern, the diameter D and the length L of the element block part 112 are set different between these examples. The results thereof reveal the following facts (see Table 2). That is, the larger the diameter D of the element block part 112, the greater the degree of the sound quality modification that clearly emphasizes each tone in the “high tones” (the mid-range, the mid-high range). In addition, the sound quality modification in the high tones is excellent as compared with the configuration in the “series connection” pattern (Examples 1-4 and 2 to 5). In the “low tones” (the deep low range, the low range), similarly, the larger the diameter D of the element block part 12, the greater the degree of the sound quality modification that clearly emphasizes each tone. However, the larger diameter D could not result in the greater effect as compared with the “high tones”. The degree of the sound quality modification is also relatively low as compared with the configuration in the “series connection” pattern (Examples 1-4 and 2 to 5). However, the sound balanced between high tones and low tones can be reproduced, resulting in increased realism.

It is also revealed that, for the diameter D of exceeding 200 mmφ, the degree of modifying the sound quality in the “high tones” and the “low tones” is almost equal between the examples and the increase in the effect reaches the limit (the effect is saturated). In contrast, when the diameter D is set larger, the body size of the sound quality modification element 110 is also increased, resulting in an increased weight. Therefore, the diameter D only has to be set to equal to or less 300 mmφ. It is found from those results that, for the “one-end connection” (Examples 6 to 10), the best sound quality modification is obtained by the configuration that the diameter D is 200 mmφ (Example 9).

On the other hand, when the diameter D of the element block part 112 is below 5 mm, the sound quality modification effect that clearly emphasizes each tone is obtained more in the “high tones” than in other ranges and the reproduced sound is apt to lose balance. To avoid such a defect, therefore, the diameter D is preferably set to equal to or more than 5 mmφ.

### Examples 11 to 15

Next, in Examples 11 to 15, in the system 221 in the eighth embodiment (see FIG. 11A) in which the sound quality modification element 210 is connected in the “loop connection” pattern, the diameter D and the length L of the element block part 12 are set different between these examples. The results thereof reveal the following facts (see Table 3). That is, the larger the diameter D of the element block part 12, the greater the degree of the sound quality modification that clearly emphasizes each tone in the “high tones” (the mid-range, the mid-high range). In addition, the sound quality modification in the high tones is excellent as compared with the “series connection” pattern (Examples 1-4 and 2 to 5) and the configuration in the “one-end connection” pattern (Examples 6 to 10). Regarding the “low tones” (the deep low range, the low range), similarly, the larger the diameter D of the element block part 12, the greater the degree of the sound quality modification effect that clearly emphasizes each tone. In addition, the degree of the sound quality modification in the “low tones” is excellent as compared with the “series connection” pattern (Examples 1-4 and 2 to 5) and the “one-end connection” pattern (Examples 6 to 10). In other words, both the “high tones” and the “low tones” reproduced in the “loop connection” pattern (Examples 11 to 15) are most excellent as compared with the “series connection” and the “one-end connection” patterns. Furthermore, the sound balanced between “high tones” and “low tones” can be reproduced, resulting in increased realism.

It is also revealed that, for the diameter D of exceeding 200 mmφ, the degree of modifying the sound quality in the “high tones” and the “low tones” is almost equal between the examples and the increase in the effect reaches the limit (the effect is saturated). In contrast, when the diameter D is set larger, the body size of the sound quality modification element 110 is also increased, resulting in an increased weight. Therefore, the diameter D only has to be set to equal to or less 300 mmφ. It is found from those results that, for the loop connection” (Examples 11 to 15), the best sound quality modification is obtained by the configuration that the diameter D is 200 mmφ (Example 14).

On the other hand, when the diameter D of the element block part 12 is below 5 mm, the sound quality modification effect that clearly emphasizes each tone is obtained more in the “high tones” than in other ranges and the reproduced sound is apt to lose balance. To avoid such a defect, therefore, the diameter D is preferably set to equal to or more than 5 mmφ.

Regarding the sound quality modification elements 10B, 110, 210 in Examples 1-4 and 2 to 15, the above results, as already explained, reveal that the diameter D of the element block parts 12 generally influences the range of a tone pitch (a sound range) of tones individually clearly emphasized and the degree of this effect. In the sound quality modification elements 10B, 110, 210 in which the diameter D of each of the element block parts 12, 112 is as relatively small as 10 mmφ (Examples 1-4, 6, and 11), each tone in the “high tones” (mid-range, mid-high range) of music pieces reproduced from the speaker system 40 is clearly emphasized. However, the sound quality modification degree is relatively low in the “low tones” (deep low range, low range) as compared with the “high tones”.

However, in the sound quality modification elements 10B, 110, 210 in which the diameter D of each of the element block parts 12, 112 is relatively large; 50 mmφ(Examples 2, 7, and 12), the sound range in which the sound quality modification effect is produced extends over low tones, so that each tone is clearly emphasized not only in the “high tones” (mid-range, mid-high range) but also in the mid-low (160 to 320 Hz) and further in the “low tones” (low range, deep low range), and the degree of the sound quality modification effect further increases. Moreover, regarding the sound quality modification elements 10B, 110, 210 (Examples 3 to 5, 8 to 10, and 13 to 15) in which the diameter D of each element block part 12, 112 is larger; 100, 200, or 300 mmφ (80 mmφ or more), the sound range where the sound quality modification is obtained extends over low tones, so that each tone is clearly emphasized not only in the “high tones” (mid-range, mid-high range) but also in the “low tones” (low range, deep low range) and the degree of the sound quality modification effect further increases. However, even when the diameter of each element block part 12, 112 is set to 300 mmφ (Examples 5, 10, and 15) larger than 200 mmφ or to more than 300 mmφ, the body size of each of the sound quality modification elements 10B, 110, 210 increases in weight, but the sound quality modification is apt to be saturated (i.e., to reach the limit). It is therefore found that the diameter D of each element block part 12, 112 is preferably set to 300 mmφ or less, more preferably the order of 200 mmφ (Examples 4, 9, and 14).

On the other hand, it is revealed that the length L of each element block part 12, 112 influences the degree of the sound quality modification that clearly emphasizes each tone, and the greater sound quality modification effect is obtained as the length L is longer (Examples 1-1 to 1-4). The detailed reasons why the differences in diameter D and length L between the element block parts 12, 112 result in different degrees of the sound quality modification effect and different widths of the sound range that generates the effect are yet-to-be defined. However, since the sound signal SA and the branching sound signals SB, SB1, SB2 traveling through the corresponding element block parts 12, 112 for example resonate and reflect in the element block parts 12, 112, the differences in diameter D and length L of the element block parts 12, 112 may influence the degree of the sound quality modification effect and the widths of the sound range that generates the effect.

<Consideration of Materials of the Sound Quality Modification Elements (the Element Bodies)>

### Examples 1-4, 16, 17, and 32 to 36

Next, a relationship between the materials of the sound quality modification element 10B (the element body 11) and the resultant sound quality modification effect was investigated. Concretely, the sound quality modification elements 10B (the element bodies 11) were produced from any material selected from among oxygen-free copper (JIS: C1020), pure aluminum (JIS: A1070), aluminum alloy (JIS: A5052), and stainless steel (JIS: SUS304). With those sound quality modification elements, the systems 21 shown in FIG. 3A were constituted as Examples 1-4, 32, 16, and 17 and evaluated in the same manner as above. In each sound quality modification element, the element block part 112 has a diameter D of 10 mmφ and a length L of 42 mm.

Results of each Example are shown in Tables 4 and 5.

TABLE 4

| | | MATERIAL OF | | | CONNECTING | | |
|---|---|---|---|---|---|---|---|
| | | ELEMENT | ELEMENT_D | ELEMENT_L | DESTINATION OF | CONNECTION | |
| | | BODY | (mm) | (mm) | ELEMENT | PATTERN | FIG |
| BASIC CONFIGURATION | | NONE | NONE | NONE | NONE | NONE | FIG. 21 |
| 2ND | EXAMPLE | OXYGEN-FREE | 10 | 42 | SPEAKER | SERIES | FIG. 3 |
| EMBODIMENT | 1-4 | COPPER | | | CABLE | CONNECTION | |
| | | (C1020) | | | | | |
| | EXAMPLE | PURE | 10 | 42 | SPEAKER | SERIES | FIG. 3 |
| | 32 | ALUMINUM | | | CABLE | CONNECTION | |
| | | (A1070) | | | | | |
| | EXAMPLE | ALUMINUM | 10 | 42 | SPEAKER | SERIES | FIG. 3 |
| | 16 | ALLOY | | | CABLE | CONNECTION | |
| | | (A5052) | | | | | |
| | EXAMPLE | STAINLESS | 10 | 42 | SPEAKER | SERIES | FIG. 3 |
| | 17 | STEEL | | | CABLE | CONNECTION | |
| | | (SUS304) | | | | | |
| 5TH | EXAMPLE | OXYGEN-FREE | 10 | 42 | SPEAKER | ONE-END | FIG. 7 |
| EMBODIMENT | 6 | COPPER | | | CABLE | CONNECTION | |
| | | (C1020) | | | | | |
| | EXAMPLE | PURE | 10 | 42 | SPEAKER | ONE-END | FIG. 7 |
| | 33 | ALUMINUM | | | CABLE | CONNECTION | |
| | | (A1070) | | | | | |

| | | EVALUATOR | | EVALUATOR | | EVALUATOR | |
|---|---|---|---|---|---|---|---|
| | | A | | B | | C | |
| | | HIGH | LOW | HIGH | LOW | HIGH | LOW |
| | | TONE | TONE | TONE | TONE | TONE | TONE |
| BASIC CONFIGURATION | | 1 | 1 | 1 | 1 | 1 | 1 |
| 2ND | EXAMPLE 1-4 | 3 | 3 | 3 | 3 | 3 | 3 |
| EMBODIMENT | EXAMPLE 32 | 4 | 3 | 3 | 3 | 3 | 3 |
| | EXAMPLE 16 | 2.5 | 3 | 2 | 3 | 2 | 3 |
| | EXAMPLE 17 | 2 | 3 | 2 | 3 | 1.5 | 3 |
| 5TH | EXAMPLE 6 | 4 | 2 | 5 | 2 | 4 | 3 |
| EMBODIMENT | EXAMPLE 33 | 5 | 2 | 5 | 3 | 4 | 3 |

AVERAGE
EVALUATION

| | | | HIGH | LOW | EVALUATION |
|---|---|---|---|---|---|
| | | | TONE | TONE | PER EXAMPLE |
| BASIC CONFIGURATION | | | 1.0 | 1.0 | Assumed as reference |
| | | | | | (=1) |
| | 2ND | EXAMPLE 1-4 | 3.0 | 3.0 | Each low tone and high |
| | EMBODIMENT | | | | tone are clearer than |
| | | | | | Reference configuration. |
| | | | | | Well-extended sound in |
| | | | | | mid-high range and soft |
| | | | | | sound quality more than |
| | | | | | Example 16 (aluminum |
| | | | | | alloy) and Example 17 |
| | | | | | (stainless steel). The |
| | | | | | same level as pure |
| | | | | | aluminum (Example 32). |
| | | EXAMPLE 32 | 3.3 | 3.0 | Each low tone and high |
| | | | | | tone are clearer than |
| | | | | | Reference configuration. |
| | | | | | Almost the same property |
| | | | | | as Example 1-4 |
| | | | | | (oxygen-free copper), |
| | | | | | but some listener |
| | | | | | feels that the sound |
| | | | | | is relatively soft and |
| | | | | | comfortable to listen. |
| | | EXAMPLE 16 | 2.2 | 3.0 | Similar to Example 1-4 |
| | | | | | (oxygen-free copper), |
| | | | | | but inferior in |
| | | | | | extension of high |
| | | | | | tones. |
| | | EXAMPLE 17 | 1.8 | 3.0 | Each tone is clearer than |
| | | | | | Reference configuration, |
| | | | | | but harder in high tones |
| | | | | | than Example 1-4 |
| | | | | | (oxygen-free copper). |
| | 5TH | EXAMPLE 6 | 4.3 | 2.3 | Each low tone and high |
| | EMBODIMENT | | | | tone are clearer than |
| | | | | | Reference configuration. |
| | | EXAMPLE 33 | 4.7 | 2.7 | Each low tone and high |
| | | | | | tone are clearer than |
| | | | | | Reference configuration. |
| | | | | | Almost the same property |
| | | | | | as, but slightly better |
| | | | | | than Example 6 |
| | | | | | (oxygen-free copper). |
| | | | | | Some listener feels |
| | | | | | that the sound is |
| | | | | | relatively soft and |
| | | | | | comfortable to |
| | | | | | listen. |

EVALUATION ON MATERIAL DIFFERENCES
Property difference appears due to differences in material (oxygen-free copper, pure aluminum, aluminum alloy, stainless steel), while it is influenced by the connection patterns.
The configurations using oxygen-free copper (Examples 1-4, 13) or pure aluminum (Examples 32, 35) are better than those using aluminum alloy or stainless steel (Examples 16, 17, 36).
Oxygen-free copper and pure aluminum are almost the same in property, but pure aluminum is sometimes evaluated as slightly better (Example 11 vs Example 34, Example 13 vs Example 35).
Aluminum alloy is inferior in property to oxygen-free copper and pure aluminum (Examples 13 and 35 vs Example 36).

TABLE 5

| | | MATERIAL OF | | | CONNECTING | | |
|---|---|---|---|---|---|---|---|
| | | ELEMENT | ELEMENT_D | ELEMENT_L | DESTINATION OF | CONNECTION | |
| | | BODY | (mm) | (mm) | ELEMENT | PATTERN | FIG |
| BASIC | | NONE | NONE | NONE | NONE | NONE | FIG. 21 |
| CONFIGURATION | | | | | | | |
| 8TH | EXAMPLE | OXYGEN-FREE | 10 | 42 | SPEAKER | LOOP | FIG. 11 |
| EMBODIMENT | 11 | COPPER | | | CABLE | CONNECTION | |
| | | (C1020) | | | | | |
| | EXAMPLE | PURE | 10 | 42 | SPEAKER | LOOP | FIG. 11 |
| | 34 | ALUMINUM | | | CABLE | CONNECTION | |
| | | (A1070) | | | | | |
| | EXAMPLE | OXYGEN-FREE | 100 | 16 | SPEAKER | LOOP | FIG. 11 |
| | 13 | COPPER | | | CABLE | CONNECTION | |
| | | (C1020) | | | | | |
| | EXAMPLE | PURE | 100 | 22 | SPEAKER | LOOP | FIG. 11 |
| | 35 | ALUMINUM | | | CABLE | CONNECTION | |
| | | (A1070) | | | | | |
| | EXAMPLE | ALUMINUM | 100 | 22 | SPEAKER | LOOP | FIG. 11 |
| | 36 | ALLOY | | | CABLE | CONNECTION | |
| | | (A5052) | | | | | |

| | | EVALUATOR | | EVALUATOR | | EVALUATOR | |
|---|---|---|---|---|---|---|---|
| | | A | | B | | C | |
| | | HIGH | LOW | HIGH | LOW | HIGH | LOW |
| | | TONE | TONE | TONE | TONE | TONE | TONE |
| BASIC CONFIGURATION | | 1 | 1 | 1 | 1 | 1 | 1 |
| 8TH | EXAMPLE 11 | 5.5 | 5 | 6 | 5 | 5 | 6 |
| EMBODIMENT | EXAMPLE 34 | 6 | 5 | 6 | 6 | 6 | 6 |
| | EXAMPLE 13 | 9 | 9 | 10 | 10 | 9 | 10 |
| | EXAMPLE 35 | 10 | 10 | 10 | 10 | 10 | 10 |
| | EXAMPLE 36 | 8 | 10 | 8 | 10 | 8 | 10 |

AVERAGE
EVALUATION

| | | | HIGH | LOW | EVALUATION |
|---|---|---|---|---|---|
| | | | TONE | TONE | PER EXAMPLE |
| BASIC CONFIGURATION | | | 1.0 | 1.0 | Assumed as reference |
| | | | | | (=1) |
| | 8TH | EXAMPLE 11 | 5.5 | 5.3 | Each low tone and high |
| | EMBODIMENT | | | | tone are clearer than |
| | | | | | Reference configuration. |
| | | | | | Balanced sound. |
| | | EXAMPLE 34 | 6.0 | 5.7 | Each low tone and high |
| | | | | | tone are clearer than |
| | | | | | Reference configuration. |
| | | | | | The same property as |
| | | | | | Example 11 (oxygen-free |
| | | | | | copper), but slightly |
| | | | | | better in both high |
| | | | | | tones and low tones. |
| | | | | | Soft and comfortable |
| | | | | | to listen. |
| | | EXAMPLE 13 | 9.3 | 9.7 | Each low tone and high |
| | | | | | tone are clearer than |
| | | | | | Reference configuration. |
| | | | | | Balanced sound in both |
| | | | | | high tones and low tones. |
| | | | | | Further increased realism |
| | | | | | more than Example 12 |
| | | | | | (oxygen-free copper, |
| | | | | | 50φ × 20). Somewhat |
| | | | | | inferior to pure aluminum |
| | | | | | (Example 35). |
| | | EXAMPLE 35 | 10.0 | 10.0 | Each low tone and high |
| | | | | | tone are clearer than |
| | | | | | Reference configuration. |
| | | | | | Balanced sound in both |
| | | | | | high tones and low |
| | | | | | tones. Extended clear |
| | | | | | high tones and similar |
| | | | | | low tones as compared |
| | | | | | with Example 13 |
| | | | | | (oxygen-free copper). |
| | | | | | Example 35 seems to be |
| | | | | | greatly influenced by |
| | | | | | the longer length. |
| | | EXAMPLE 36 | 8.0 | 10.0 | Clearer tones than |
| | | | | | Reference configuration, |
| | | | | | but inferior in high |
| | | | | | tones to oxygen-free |
| | | | | | copper (Example 13) and |
| | | | | | pure aluminum (Example |
| | | | | | 35). Some listener feels |
| | | | | | that high tones are |
| | | | | | somewhat dull than |
| | | | | | oxygen-free copper |
| | | | | | (Example 13) and |
| | | | | | pure aluminum |
| | | | | | (Example 35). |

EVALUATION ON MATERIAL DIFFERENCES
Property difference appears due to differences in material (oxygen-free copper, pure aluminum, aluminum alloy, stainless steel), while it is influenced by the connection patterns.
The configurations using oxygen-free copper (Examples 1-4, 13) or pure aluminum (Examples 32, 35) are better than those using aluminum alloy or stainless steel (Examples 16, 17, 36).
Oxygen-free copper and pure aluminum are almost the same in property, but pure aluminum is sometimes evaluated as slightly better (Example 11 vs Example 34, Example 13 vs Example 35).
Aluminum alloy is inferior in property to oxygen-free copper and pure aluminum (Examples 13 and 35 vs Example 36).

According to Examples 1-4, 32, 16, and 17 (see Table 4) using the sound quality modification element 10B having a diameter D of 10 mmφ and a length L of 42 mm, it is found that the sound quality modification elements 10B produced from any material can generate the sound quality modification effect that clearly emphasizes each tone, but the degree of the sound quality modification and the sound quality are different depending on the materials of the sound quality modification elements 10B (the element bodies 11), as compared with the system 2 in the reference configuration not using the sound quality modification elements. Specifically, in Example 16 using aluminum alloy, the “high tones” is inferior in extension to Examples 1-4 and 32 using oxygen-free copper or pure aluminum. Further, in Example 17 using stainless steel, clear tones are reproduced, but the “high tones” sound hard. Reversely, in Examples 1-4 and 32 using oxygen-free copper or pure aluminum, the tones in the mid-high range favorably extend and make soft the sound quality, which are particularly excellent as compared with Examples 16 and 17 (aluminum alloy, stainless steel).

In comparison of Examples 1-4 (oxygen-free copper) and Example 32 (pure aluminum), the property is almost the same, but some listener evaluated that the pure aluminum was relatively soft and comfortable to hear. Thus, the pure aluminum shows a somewhat good evaluation. Further, almost the same property are found even in comparison between Example 6 (oxygen-free copper) using the sound quality modification element 110 and Example 33 (pure aluminum), each having a diameter D of 10 mmφ and a length L of 42 mm, and also in comparison between Example 11 (oxygen-free copper) and Example 34 (pure aluminum), each having a diameter D of 10 mmφ and a length L of 42 mm. However, some listener evaluated that the pure aluminum was relatively soft and comfortable to hear. Thus, the pure aluminum is given a somewhat good evaluation (see Tables 4 and 5).

According to Examples 13, 35, and 36 (see Table 5) using the sound quality modification element 210 having a diameter D of 100 mmφ, the sound quality modification element made of aluminum alloy (Example 36) is evaluated as being inferior in the high tones as compared with oxygen-free copper (Example 13) and pure aluminum (Example 35). On the other hand, in comparison of Example 13 (oxygen-free copper) and Example 35 (pure aluminum), the high tones are evaluated as being clearer and more extended in Example 35 than Example 13. However, Example 13 (L=16 mm) and Example 35 (L=22 mm) are equal in diameter D (=100 mmφ) but different in length L. That is, since the length L is longer in Example 35 by as much as 38%, the differences in property between Example 13 and Example 35 greatly depend on the difference in length L rather than the difference in material. After subtracting this point, in the sound quality modification elements 210 each having a diameter D of 100 mmφ, a difference in material between oxygen-free copper (Example 13) and pure aluminum (Example 35) less influences the property and provides substantially the same property.

It is conceived from the above results that, a difference in material between oxygen-free copper and pure aluminum less influences the property and provides substantially the same property; however, the pure aluminum is slightly more often given a good evaluation. However, it is obvious that oxygen-free copper and pure aluminum are more preferable than aluminum alloy and stainless steel. The detailed reasons why the degree of the sound quality modification effect and the sound quality differ between the element block parts depending on differences in material as above are unclear. However, since oxygen-free copper and pure aluminum are high in electric conductivity, it is conceived that differences in electric conductivity resulting from different materials have an influence on the degree of the sound quality modification and the sound quality.

<Consideration of Connection Patterns of Sound Quality Modification Elements in a System>

### Examples 1-4, 6, 11, and 18 to 25

Furthermore, a relationship between the connection patterns of the sound quality modification elements 10A, 10B, 10C, 110, and 210 and the sound quality modification effect was investigated. Concretely, the systems 20 to 22, 120 to 122, 220 to 222, 420, and 421 in Examples 1 to 11 (see FIGS. 1, 3A, 4, 5, 7A, 8, 9, 11A, 12, 19, and 20) were produced and evaluated in the same manner as above. The material of each element body 11, 111 is oxygen-free copper (JIS: C1020, no plating, no coating layer) and each element block part 12, 112 has a diameter D or 10 mmφ and a length L of 42 mm. Results of those Examples are shown in Table 6.

TABLE 6

| | | MATERIAL OF | | | CONNECTING | | |
|---|---|---|---|---|---|---|---|
| | | ELEMENT | ELEMENT_D | ELEMENT_L | DESTINATION OF | CONNECTION | |
| | | BODY | (mm) | (mm) | ELEMENT | PATTERN | FIG |
| BASIC CONFIGURATION | | NONE | NONE | NONE | NONE | NONE | FIG. 21 |
| 2ND | EXAMPLE | OXYGEN-FREE | 10 | 42 | SPEAKER | SERIES | FIG. 3 |
| EMBODIMENT | 1-4 | COPPER | | | CABLE | CONNECTION | |
| | | (C1020) | | | | | |
| 1ST | EXAMPLE | OXYGEN-FREE | 10 | 42 | AMP OUTPUT | SERIES | FIG. 1 |
| EMBODIMENT | 18 | COPPER | | | TERMINAL, | CONNECTION | |
| | | (C1020) | | | SPEAKER CABLE | | |
| 3RD | EXAMPLE | OXYGEN-FREE | 10 | 42 | SPEAKER CABLE, | SERIES | FIG. 4 |
| EMBODIMENT | 19 | COPPER | | | SPEAKER INPUT | CONNECTION | |
| | | (C1020) | | | TERMINAL | | |
| 5TH | EXAMPLE | OXYGEN-FREE | 10 | 42 | SPEAKER | ONE-END | FIG. 7 |
| EMBODIMENT | 6 | COPPER | | | CABLE | CONNECTION | |
| | | (C1020) | | | | | |
| 4TH | EXAMPLE | OXYGEN-FREE | 10 | 42 | AMP OUTPUT | ONE-END | FIG. 5 |
| EMBODIMENT | 20 | COPPER | | | TERMINAL | CONNECTION | |
| | | (C1020) | | | | | |
| 6TH | EXAMPLE | OXYGEN-FREE | 10 | 42 | SPEAKER INPUT | ONE-END | FIG. 8 |
| EMBODIMENT | 21 | COPPER | | | TERMINAL | CONNECTION | |
| | | (C1020) | | | | | |
| 8TH | EXAMPLE | OXYGEN-FREE | 10 | 42 | SPEAKER | LOOP | FIG. 11 |
| EMBODIMENT | 11 | COPPER | | | CABLE | CONNECTION | |
| | | (C1020) | | | | | |
| 7TH | EXAMPLE | OXYGEN-FREE | 10 | 42 | AMP OUTPUT | LOOP | FIG. 9 |
| EMBODIMENT | 22 | COPPER | | | TERMINAL | CONNECTION | |
| | | (C1020) | | | | | |
| 9TH | EXAMPLE | OXYGEN-FREE | 10 | 42 | SPEAKER INPUT | LOOP | FIG. 12 |
| EMBODIMENT | 23 | COPPER | | | TERMINAL | CONNECTION | |
| | | (C1020) | | | | | |
| 10TH | EXAMPLE | OXYGEN-FREE | 10 | 42 | AMP OUTPUT | LOOP | FIG. 19 |
| EMBODIMENT | 24 | COPPER | | | TERMINAL | CONNECTION | |
| | | (C1020) | | | (ONLY +TERMINAL) | | |
| 11TH | EXAMPLE | OXYGEN-FREE | 10 | 42 | AMP OUTPUT | LOOP | FIG. 20 |
| EMBODIMENT | 25 | COPPER | | | TERMINAL | CONNECTION | |
| | | (C1020) | | | (ONLY −TERMINAL) | | |

| | | EVALUATOR | | EVALUATOR | | EVALUATOR | | AVERAGE | |
|---|---|---|---|---|---|---|---|---|---|
| | | A | | B | | C | | EVALUATION | |
| | | HIGH | LOW | HIGH | LOW | HIGH | LOW | HIGH | LOW |
| | | TONE | TONE | TONE | TONE | TONE | TONE | TONE | TONE |
| BASIC CONFIGURATION | | 1 | 1 | 1 | 1 | 1 | 1 | 1.0 | 1.0 |
| 2ND EMBODIMENT | EXAMPLE 1-4 | 3 | 3 | 3 | 3 | 3 | 3 | 3.0 | 3.0 |
| 1ST EMBODIMENT | EXAMPLE 18 | 3 | 3 | 3 | 3 | 3 | 3 | 3.0 | 3.0 |
| 3RD EMBODIMENT | EXAMPLE 19 | 3 | 3 | 3 | 3 | 3 | 3 | 3.0 | 3.0 |
| 5TH EMBODIMENT | EXAMPLE 6 | 4 | 2 | 5 | 2 | 4 | 3 | 4.3 | 2.3 |
| 4TH EMBODIMENT | EXAMPLE 20 | 4 | 2 | 5 | 2 | 4 | 3 | 4.3 | 2.3 |
| 6TH EMBODIMENT | EXAMPLE 21 | 4 | 2 | 5 | 2 | 4 | 3 | 4.3 | 2.3 |
| 8TH EMBODIMENT | EXAMPLE 11 | 5.5 | 5 | 6 | 5 | 5 | 6 | 5.5 | 5.3 |
| 7TH EMBODIMENT | EXAMPLE 22 | 5.5 | 5 | 6 | 5 | 5 | 6 | 5.5 | 5.3 |
| 9TH EMBODIMENT | EXAMPLE 23 | 5.5 | 5 | 6 | 5 | 5 | 6 | 5.5 | 5.3 |
| 10TH EMBODIMENT | EXAMPLE 24 | 2 | 3 | 2 | 2 | 2 | 3 | 2.0 | 2.7 |
| 11TH EMBODIMENT | EXAMPLE 25 | 2 | 3 | 2 | 2 | 2 | 3 | 2.0 | 2.7 |

| | | EVALUATION OF | EVALUATION OF |
|---|---|---|---|
| | | EXAMPLES | EXAMPLES |
| | | (DIFFERENCES | (DIFFERENCES IN |
| | | IN CONNECTION | CONNECTION |
| | | DESTINATION OF | PATTERN OF |
| | | ELEMENT) | ELEMENT) |
| BASIC CONFIGURATION | | Assumed as reference | |
| | | (=1) | |
| 2ND | EXAMPLE 1-4 | Each low tone and high | Connection of element |
| EMBODIMENT | | tone are clearer than | provides the effect of |
| | | Reference configuration. | sound quality |
| 1ST | EXAMPLE 18 | Almost no difference | modification (each low |
| EMBODIMENT | | between Examples 1-4, | tone and each high |
| | | 18, and 19. Almost the | tone are |
| 3RD | EXAMPLE 19 | same effect of sound | clearer than Reference |
| EMBODIMENT | | quality modification | configuration), but |
| | | even by different | different connection |
| | | connection | patterns (series |
| | | destinations of the | connection, one-end |
| | | sound quality | connection, and loop |
| | | modification element | connection) result in |
| | | 10A and others. | differences in property. |
| 5TH | EXAMPLE | Each low tone and high | In one-end connection, |
| EMBODIMENT | 6 | tone are clearer than | high tones are better |
| | | Reference configuration. | than but low tones are |
| 4TH | EXAMPLE | Almost no difference | inferior to those in |
| EMBODIMENT | 20 | between Examples 6, | series connection. |
| | | 20, and 21. Almost the | In loop connection, |
| 6TH | EXAMPLE | same effect of sound | high tones are more |
| EMBODIMENT | 21 | quality modification | extended than in |
| | | even by different | series connection and |
| | | connection | one-end connection.Low |
| | | destinations of the | tones are also |
| | | sound quality | extended. Significant |
| | | modification elements | effect of sound |
| | | 110. | quality modification |
| 8TH | EXAMPLE | Each low tone and high | is obtained. |
| EMBODIMENT | 11 | tone are clearer than | |
| 7TH | EXAMPLE | Reference configuration. | |
| EMBODIMENT | 22 | Balanced sound in low | |
| 9TH | EXAMPLE | tones and high tones. | |
| EMBODIMENT | 23 | Almost no difference | |
| | | between Examples 11, | |
| | | 22, and 23. Almost | |
| | | the same effect of | |
| | | sound quality | |
| | | modification even by | |
| | | different connection | |
| | | destinations of the | |
| | | sound quality | |
| | | modification elements | |
| | | 210. | |
| 10TH | EXAMPLE | Because of use of the | The same result irrespective of |
| EMBODIMENT | 24 | single sound quality | which the element is connected |
| | | modification element | to, +terminal or −terminal. |
| | | 210, the effect of | |
| | | sound quality | |
| | | modification is inferior | |
| | | to Example 11 using two | |
| | | sound quality | |
| | | modification elements. | |
| 11TH | EXAMPLE | Because of use of the | |
| EMBODIMENT | 25 | single sound quality | |
| | | modification element | |
| | | 210, the effect of | |
| | | sound quality | |
| | | modification is inferior | |
| | | to Example 11 using two | |
| | | sound quality | |
| | | modification elements. | |

### First to Ninth Embodiments

Referring to the evaluations of Examples 1-4, 18, and 19 corresponding to the first to third embodiments (see FIGS. 1, 3A, and 4), every example is given the same evaluation. This shows that the connection pattern of “series connection” using the sound quality modification elements 10A, 10B, 10C results in substantially the same degree of the sound quality modification effect even if the connecting destinations of the sound quality modification elements 10A, 10B, 10C are different between the examples. Further, referring to the evaluations of Examples 6, 20, and 21 corresponding to the fourth to sixth embodiments (see FIGS. 5, 7A, and 8), every example is given the same evaluation. This shows that the connection pattern of “one-end connection” using the sound quality modification elements 10B results in substantially the same degree of the sound quality modification effect even if the connecting destinations of the sound quality modification elements 10B are different between the examples. Still further, referring to the evaluations of Examples 11, 22, and 23 corresponding to the seventh to ninth embodiments (see FIGS. 9, 11A, and 12A), every example is given the same evaluation. This reveals that the connection pattern of “loop connection” using the sound quality modification elements 210 results in substantially the same degree of the sound quality modification effect even if the connecting destinations of the sound quality modification elements 210 are different between the examples.

In other words, the sound quality modification effect is not influenced by selection of the connecting destinations of the sound quality modification element 10A and others in the present disclosure, from among the amplifier output terminals 31P, 31N, the speaker input terminals 40P, 40N, and the midpoints (151PS, 151NS, 152PA, 152NA) of the speaker cables. In contrast, the sound quality modification effect is greatly influenced by selection of the connection patterns of the sound quality modification element 10A and others, from among the “series connection”, the “one-end connection”, and the “loop connection”, and selection of the dimension (diameter D and length L) of the element block parts 12, 112. In particular, when the element block parts 12, 112 having the same dimension (diameter D and length L) are used, the most preferable one of the connection patterns of the sound quality modification element 10A and others is the “loop connection” pattern (Examples 11, 22, and 23) as obviously from Table 6. A second preferable one is the “one-end connection” pattern (Examples 6, 20, and 21), but this is inferior in the “low tones” to the “series connection” pattern. Thus, the “series connection” pattern (Examples 1-4, 18, and 19) may be preferably selected depending on listener's preferences.

The reasons why such a difference in connection pattern results in different degrees of the sound quality modification effect and different sound qualities as mentioned above are yet-to-be defined. However, in the “loop connection”, the sound quality modification element 210 is connected to a connection site, such as the amplifier output terminals 41P, 31N, the speaker input terminals 40P, 40N, or the speaker cables 151P, 151N, 152P, 152N. Accordingly, part of the sound signal SA output from the amplifier output terminals 31P, 31N of the amplifier circuits 31 is divided into the branching sound signals SB1, SB2 for the sound quality modification element 210, and travels through a looped path via the first element terminal part 13, the element block part 12, and the second element terminal part 14 in this order (alternatively, a path via the second element terminal part 14, the element block part 12, and the first element terminal part 13 in the reversed order) to return to the connection site. It is conceived that the branching sound signals SB1, SB2 cause a large change in the sound signal SS to be input to the speaker system 40 (the speaker 41) through the speaker input terminals 40P, 40N, thereby changing the sound quality of the sound SD reproduced by the speaker system 40, as compared with the configuration not using the sound quality modification element 210. The reason why the “loop connection” pattern is more preferable than the “one-end connection” and “series-connection” patterns seems because a looped flow of the branching sound signals SB1, SB2 in the “loop connection” pattern could greatly change the sound signal SS to be input to the speaker system 40 more than the “one-end connection” and “series-connection” patterns.

### Examples 22, 24, and 25

Next, the evaluations of Examples 22, 24, and 25 corresponding to the seventh, tenth, and eleventh embodiments (see FIGS. 9, 19, and 20) are reviewed below. In the system 220 in the seventh embodiment (see FIG. 9: Example 22), the sound quality modification elements 210 (total four sound quality modification elements) are connected to the two pairs of amplifier output terminals 31P, 31N of the amplifier 30. In contrast, in the system 410 in the tenth embodiment (see FIG. 19: Example 24), the sound quality modification elements 210 (total two sound quality modification elements) are connected to only the plus-side amplifier output terminals 31P of the two pairs of amplifier output terminals 31P, 31N of the amplifier 30. On the contrary, in the system 421 in the eleventh embodiment (see FIG. 20: Example 25), the sound quality modification elements 210 (total two sound quality modification elements) are connected to only the minus-side amplifier output terminals 31N of the two pairs of amplifier output terminals 31P, 31N of the amplifier 30.

In Examples 24 and 25, therefore, the sound quality modification effect is obtained for both the “high tones” and “low tones” as compared with the basic configuration, but the degree of the sound quality modification is inferior to Example 22. This is because the number of sound quality modification elements 210 used therein is smaller than Example 22. On the other hand, the same property is obtained irrespective of which the sound quality modification element 210 is connected to, the plus-side amplifier output terminal 31P or the minus-side amplifier output terminal 31N.

<Consideration of Plating Materials of Sound Quality Modification Elements (Element Block Parts)>

### Examples 6, 26 to 31, 33, 37

Next, a relationship between the materials of the metal plating layer 111M coated on the entire surface of the element body 111 of the sound quality modification element 110 and the sound quality modification effect was investigated. Concretely, the sound quality modification elements 110 (the element bodies 111) were produced in such a way that each element 110 was coated with the metal plating layer 111M made of electrolytic nickel plating (thickness: 5 μm), electrolytic nickel-chrome plating (thickness: 5 μm/0.3 μm), electrolytic nickel-gold plating (thickness: 2 to 3 μm/0.2 μm), tin plating (thickness: 5 μm), silver plating (thickness: 5 μm), or unichrome plating (zinc plating bright chromate conversion coating: thickness 5 μm). With those sound quality modification elements 110 (the element bodies 111), the systems 121 of the “one-end connection” in the fifth embodiment (see FIG. 7A) were constituted as Examples 6, 26 to 31, 33, and 37 and evaluated in the same manner as above. Each element body 111 is made of oxygen-free copper (JIS: C1020) except in Examples 33 and 37, and pure aluminum (JIS: A1070) in Examples 33 and 37. Further, every element block part 112 has a diameter D of 10 mmφ and a length L of 42 mm. In Examples 6 and 33, each element body 111 is not provided with the metal plating layer 111M. Results of each Example are shown in Table 7.

TABLE 7

| | | | PLATING | | | | |
|---|---|---|---|---|---|---|---|
| | | MATERIAL OF | LAYER OF | | | CONNECTING | |
| | | ELEMENT | ELEMENT | ELEMENT_D | ELEMENT_L | DESTINATION OF | CONNECTION |
| | | BODY | BODY | (mm) | (mm) | ELEMENT | PATTERN |
| BASIC | | NONE | NONE | NONE | NONE | NONE | NONE |
| CONFIGURATION | | | | | | | |
| 5TH | EXAMPLE | OXYGEN-FREE | NONE | 10 | 42 | SPEAKER | ONE-END |
| EMBODIMENT | 6 | COPPER | | | | CABLE | CONNECTION |
| | | (C1020) | | | | | |
| | EXAMPLE | OXYGEN-FREE | ELECTROLYTIC | 10 | 42 | SPEAKER | ONE-END |
| | 26 | COPPER | NICKEL | | | CABLE | CONNECTION |
| | | (C1020) | | | | | |
| | EXAMPLE | OXYGEN-FREE | ELECTROLYTIC | 10 | 42 | SPEAKER | ONE-END |
| | 27 | COPPER | NICKEL-CHROME | | | CABLE | CONNECTION |
| | | (C1020) | | | | | |
| | EXAMPLE | OXYGEN-FREE | ELECTROLYTIC | 10 | 42 | SPEAKER | ONE-END |
| | 28 | COPPER | NICKEL-GOLD | | | CABLE | CONNECTION |
| | | (C1020) | | | | | |
| | EXAMPLE | OXYGEN-FREE | TIN | 10 | 42 | SPEAKER | ONE-END |
| | 29 | COPPER | | | | CABLE | CONNECTION |
| | | (C1020) | | | | | |
| | EXAMPLE | OXYGEN-FREE | SILVER | 10 | 42 | SPEAKER | ONE-END |
| | 30 | COPPER | | | | CABLE | CONNECTION |
| | | (C1020) | | | | | |
| | EXAMPLE | OXYGEN-FREE | UNICHROME | 10 | 42 | SPEAKER | ONE-END |
| | 31 | COPPER | | | | CABLE | CONNECTION |
| | | (C1020) | | | | | |
| | EXAMPLE | PURE | NONE | 10 | 42 | SPEAKER | ONE-END |
| | 33 | ALUMINUM | | | | CABLE | CONNECTION |
| | | (A1070) | | | | | |
| | EXAMPLE | PURE | ELECTROLYTIC | 10 | 42 | SPEAKER | ONE-END |
| | 37 | ALUMINUM | NICKEL | | | CABLE | CONNECTION |
| | | (A1070) | | | | | |

| | | | EVALUATOR | | EVALUATOR | | EVALUATOR | | AVERAGE | |
|---|---|---|---|---|---|---|---|---|---|---|
| | | | A | | B | | C | | EVALUATION | |
| | | | HIGH | LOW | HIGH | LOW | HIGH | LOW | HIGH | LOW |
| | | FIG | TONE | TONE | TONE | TONE | TONE | TONE | TONE | TONE |
| BASIC CONFIGURATION | | FIG. 21 | 1 | 1 | 1 | 1 | 1 | 1 | 1.0 | 1.0 |
| 5TH | EXAMPLE 6 | FIG. 7 | 4 | 2 | 5 | 2 | 4 | 3 | 4.3 | 2.3 |
| EMBODIMENT | EXAMPLE 26 | FIG. 7 | 5 | 3 | 5 | 2 | 4 | 3 | 4.7 | 2.7 |
| | EXAMPLE 27 | FIG. 7 | 5 | 3 | 5 | 3 | 3 | 3 | 4.3 | 3.0 |
| | EXAMPLE 28 | FIG. 7 | 5 | 3 | 5.5 | 3.5 | 5 | 4 | 5.2 | 3.5 |
| | EXAMPLE 29 | FIG. 7 | 4 | 2 | 3 | 2 | 4 | 2 | 3.7 | 2.0 |
| | EXAMPLE 30 | FIG. 7 | 4 | 3 | 3 | 3 | 4 | 3 | 3.7 | 3.0 |
| | EXAMPLE 31 | FIG. 7 | 2 | 2 | 2 | 2 | 2 | 2 | 2.0 | 2.0 |
| | EXAMPLE 33 | FIG. 7 | 5 | 2 | 5 | 3 | 4 | 3 | 4.7 | 2.7 |
| | EXAMPLE 37 | FIG. 7 | 5 | 3 | 5 | 2 | 4 | 3 | 4.7 | 2.7 |

| | | | EVALUATION ON |
|---|---|---|---|
| | | | DIFFERENCES |
| | | EVALUATION | IN PLATING |
| | | PER EXAMPLE | MATERIALS |
| BASIC CONFIGURATION | | Assumed as reference | |
| | | (=1) | |
| 5TH | EXAMPLE 6 | Each low tone and each | Preferably, a protective |
| EMBODIMENT | | high tone are clearer | layer such as enamel is |
| | | than Reference | additionally provided. |
| | | configuration. The | |
| | | surface is apt to | |
| | | oxidize. | |
| | EXAMPLE 26 | Each low tone and each | |
| | | high tone are clearer | |
| | | than Reference | |
| | | configuration. Similar | |
| | | to no plating (Example | |
| | | 6) but balanced in low | |
| | | tones and high tones | |
| | | than no plating. | |
| | EXAMPLE 27 | Each low tone and each | The most preferable one |
| | | high tone are clearer | is electrolytic |
| | | than Reference | nickel-gold plating. |
| | | configuration. Balanced | Second preferable one |
| | | in low tones and high | is electrolytic nickel |
| | | tones than no plating | plating. |
| | | (Example 6). Similar | |
| | | to Example 26 (nickel), | |
| | | low tones are more | |
| | | emphasized but high | |
| | | tones are inferior | |
| | | thereto. | |
| | EXAMPLE 28 | Each low tone and each | Third preferable one |
| | | high tone are clearer | is electrolytic |
| | | than Reference | nickel-chrome plating. |
| | | configuration. Balanced | |
| | | in low tones and high | |
| | | tones and further high | |
| | | tones sound going | |
| | | forward and sharpest | |
| | | as compared with no | |
| | | plating (Example 6). | |
| | | The sound quality is | |
| | | similar to Example 26 | |
| | | (nickel) but more | |
| | | preferable than | |
| | | Example 26 (nickel) and | |
| | | Example 27 (chrome) and | |
| | | best. | |
| | EXAMPLE 29 | Each low tone and | Silver plating and tin |
| | | each high tone are | plating are somewhat |
| | | clearer than | low in evaluation, but |
| | | Reference | reproduce soft sounds. |
| | | configuration. | |
| | | Balanced in low | |
| | | tones and high | |
| | | tones than no | |
| | | plating (Example | |
| | | 6). Sound softer | |
| | | than other Examples | |
| | | using different | |
| | | platings. | |
| | EXAMPLE 30 | Each low tone and | Unichrome plating provides |
| | | each high tone are | the effect of sound |
| | | clearer than | quality modification, but |
| | | Reference | reproduces rougher sound |
| | | configuration. | than other platings. |
| | | Balanced in low | Undesired. |
| | | tones and high | |
| | | tones than no | |
| | | plating (Example | |
| | | 6). Low tones | |
| | | sound soft. Silver | |
| | | plating is apt to | |
| | | oxidize. | |
| | EXAMPLE 31 | Each low tone and each | |
| | | high tone are clearer | |
| | | than Reference | |
| | | configuration. | |
| | | However, low evaluation | |
| | | is given because of | |
| | | the sound rougher than | |
| | | in no plating (Example | |
| | | 6) and nickel plating | |
| | | (Example 26). | |
| | EXAMPLE 33 | Each low tone and each | |
| | | high tone are clearer | |
| | | than Reference | |
| | | configuration. Almost | |
| | | the same property as | |
| | | Example 6 (oxygen-free | |
| | | copper), but slightly | |
| | | better. Some listener | |
| | | feels that the sound | |
| | | is relatively soft and | |
| | | comfortable to listen. | |
| | EXAMPLE 37 | Each low tone and each | |
| | | high tone are clearer | |
| | | than Reference | |
| | | configuration. Almost | |
| | | the same property as | |
| | | Example 33 (no | |
| | | plating) and Example | |
| | | 26 (oxygen-free copper). | |

In Examples 26 and 37 each using the sound quality modification element 110 including the metal plating layer 111M made of electrolytic nickel plating, both the “low tones” and “high tones” are individually clear as in Example 6 using the sound quality modification element 110 not including the metal plating layer 111M, as compared with the reference configuration not using the sound quality modification element 110. Furthermore, the reproduced sound SD is balanced between the “low tones” and the “high tones”, as compared with Example 6 using the sound quality modification element 110 not including the metal plating layer 111M.

Even if the element block parts 112 are made of different materials (oxygen-free copper, pure aluminum) which are base materials for the metal plating layer 111M, the sound quality is similarly influenced by the presence/absence of the metal plating layer 111M and the material of the metal plating layer.

In Example 27 using the sound quality modification element 110 including the metal plating layer 111M made of electrolytic nickel-chrome plating, similarly, both the “low tones” and “high tones” are individually clear, as compared with the reference configuration not using the sound quality modification element 110. Furthermore, the reproduced sound SD is balanced between the “low tones” and the “high tones”, as compared with Example 6 using the sound quality modification element 110 not including the metal plating layer 111M. The sound quality is similar to that in Example 26 (electrolytic nickel) and the “low tones” are more emphasized than Example 26, whereas the “high tones” are inferior to Example 26.

In Example 28 using the sound quality modification element 110 including the metal plating layer 111M made of electrolytic nickel-gold plating, similarly, both the “low tones” and “high tones” are individually clear, as compared with the reference configuration not using the sound quality modification element 110. Furthermore, the reproduced sound SD is balanced between the “low tones” and the “high tones”, as compared with Example 6 using the sound quality modification element 110 not including the metal plating layer 111M. The sound quality is similar to that in Example 26 (electrolytic nickel) and both the “low tones” and the “high tones” are more emphasized than in Example 26. This Example 28 is given a best evaluation as compared with other examples provided with the metal plating layers 111M.

In Example 29 using the sound quality modification element 110 including the metal plating layer 111M made of tin, similarly, both the “low tones” and “high tones” are individually clear, as compared with the reference configuration not using the sound quality modification element 110. Furthermore, the reproduced sound SD is balanced between the “low tones” and the “high tones”, as compared with Example 6 using the sound quality modification element 110 not including the metal plating layer 111M. However, this Example 29 is inferior in the degree of emphasis of the “low tones” and the “high tones” to Example 26 (electrolytic nickel). Regarding the sound quality, the reproduced sound SD in this example sounds softer in both the “low tones” and the “high tones” as compared with Example 6 (no metal plating layer) and Example 26 (electrolytic nickel).

In Example 30 using the sound quality modification element 110 including the metal plating layer 111M made of silver, similarly, both the “low tones” and “high tones” are individually clear, as compared with the reference configuration not using the sound quality modification element 110. Furthermore, the reproduced sound SD is balanced between the “low tones” and the “high tones”, as compared with Example 6 using the sound quality modification element 110 not including the metal plating layer 111M. On the other hand, this Example 30 is inferior in the degree of emphasis of the “high tones”, but the low tones sound more emphasized, as compared with Example 26 (electrolytic nickel). Regarding the sound quality, the reproduced sound SD in this example sounds softer in the “low tones” as compared with Example 6 (no metal plating layer) and Example 26 (electrolytic nickel).

In Example 31 using the sound quality modification element 110 including the metal plating layer 111M made of unichrome, similarly, both the “low tones” and “high tones” are individually clear, as compared with the reference configuration not using the sound quality modification element 110. Furthermore, the reproduced sound SD is balanced between the “low tones” and the “high tones”, as compared with Example 6 using the sound quality modification element 110 not including the metal plating layer 111M. However, this Example 31 is inferior in the degree of emphasis of the “low tones” and the “high tones”, as compared with Example 26 (electrolytic nickel). In addition, regarding the sound quality, the reproduced sound SD in this example sounds rougher as compared with Example 6 (no metal plating layer) and Example 26 (electrolytic nickel). This example is given a low evaluation.

The reasons why the differences in material of the metal plating layer 111M coated on the surface of the element body 111 result in different degrees of the sound quality modification and different sound qualities (soft sound, rough sound, etc.) are unclear. However, it is conceived that the degree of the sound quality modification and the sound quality are influenced by differences in conductivity on or around the surface of the element body 111 of the metal plating layer 111M due to different materials of the metal plating layer 111M and differences in size and interfacial state of metal particles constituting the metal plating layer 111M. In Examples 26 to 31 and 37 mentioned above, the system 121 in the fifth embodiment in which the sound quality modification element 110 is connected in the “one-end connection” pattern is evaluated. Similarly, the same differences as above are made due to the materials of the metal plating layers 111M, 11M even in the systems 120 and 122 in the fourth and sixth embodiments using the sound quality modification elements 110 each connected in the “one-end connection” pattern, the systems 20 to 22 in the first to third embodiments using the sound quality modification elements 10A to 10C each connected in the “series connection” pattern, and also the systems 220 to 222, 420, and 421 in the seventh to eleventh embodiments using the sound quality modification elements 210 each connected in the “loop connection” pattern. From the above-mentioned results, each of the systems using the corresponding sound quality modification elements 110, 10A to 10C, or 210 each including the element body 111, 11 formed, on its surface, with the metal plating layer 111M, 11M made of electrolytic nickel plating (Examples 26 37), electrolytic nickel-gold plating (Example 28), or electrolytic nickel-chrome plating (Example 27) can clearly emphasize each of “low tones” and “high tones” and reproduce the sound SD balanced between the “low tones” and the “high tones”, as compared with the configuration not using the sound quality modification element 110 and others.

Each of the systems using the corresponding sound quality modification elements 110, 10A to 10C, and 210 each including the element body 111, 11 formed, on its surface, with the metal plating layer 111M, 11M made of tin plating (Example 29), can clearly emphasize each of “low tones” and “high tones”, as compared with the configuration not using the sound quality modification element 110 and others, and reproduce the sound SD balanced between the “low tones” and the “high tones” and further the sound SD with softer sound quality, as compared with the configuration using the sound quality modification element 110 and others not including the metal plating layer. In each of the systems using the corresponding sound quality modification elements 110, 10A to 10C, and 210 each including the element body 111, 11 formed, on its surface, with the metal plating layer 111M, 11M made of silver plating (Example 30) can clearly emphasize each of “low tones” and “high tones” as compared with the configuration not using the sound quality modification element 110 and others, and also reproduce the sound SD balanced between the “low tones” and the “high tones” as compared with the configuration using the sound quality modification element 110 and others not including the metal plating layer, and further reproduce the sound SD with softer sound quality in the “low tones”.

The metal plating layer 111M, 11M is preferably an oxidation-resistant metal plating layer, for example, the electrolytic nickel plating layer (Examples 26, 37), electrolytic nickel-gold plating layer (Example 28), electrolytic nickel-chrome plating layer (Example 27), tin plating layer (Example 30), or unichrome plating (Example 31). This is because those materials can suppress property variations of the sound quality modification elements 110, 10A to 10C, 210 over time due to oxidation of the metal plating layers 111M, 11M and thus the sound quality modification elements 110, 10A to 10C, 210 can maintain the sound quality modification effect for long periods. On the other hand, for use of the sound quality modification element 10B, 110, etc. not including the metal plating layer and made of a material apt to oxidize (oxygen-free copper and others) or for use of the metal plating layer 111M, 11M low in oxidation resistance (apt to oxidize), such as a silver layer, an insulating protective layer made of resin, such as enamel, or glass may be applied to coat the surface of the sound quality modification element or the surface of the metal plating layer.

The present invention is described above in the first to eleventh embodiments, the first to fourteenth modified embodiments, and Examples 1 to 37, but the foregoing embodiments and others give no limitation to the present invention. The present invention may be embodied in other specific forms without departing from the essential characteristics thereof. The foregoing embodiments and others exemplify the stereo audio system 20 and others and stereo amplifier 30 and others. As alternatives, a monaural system and an audio system using three or more speaker systems such as a 5.1 ch surround system may be configured as an audio system using the aforementioned sound quality modification elements 10A and others. Further, the foregoing embodiments and others show the speaker system 40 and others configured such that the single speaker (a full range speaker) 41 is housed in the speaker box 42 and others. Alternatively, for example, it may be applied to a multi-way speaker system configured such that a plurality of speakers (speaker units) such as a woofer, a squawker, and a tweeter and a network circuit board (a circuit board constituting a network circuit, such as a low-pass filter and a high-pass filter, not shown) is housed in a single speaker box.

Each of the foregoing embodiments exemplifies the use of a U-shaped crimping terminal as each of the other end parts 15T and the terminal members 217 of the connection cables 15 and others of the sound quality modification elements 10A, 10C, 110, 210, 210A, and 210B. As an alternative, an O-shaped crimping terminal, a banana plug, or the like may be used according to the shapes of the amplifier output terminals 31P, 31N, the speaker input terminals 40P, 40N, the end parts 50PA of the speaker cables 50P, 50N, and others. In addition, an appropriate configuration or a connection method using soldering of cable strands (a bundle of strands) stripped off by removal of a cable coating may be adopted.

### REFERENCE SIGNS LIST

10A, 10B, 10C, 110, 210, 210A, 210B Sound quality modification element

SL Vibration-proof layer

11, 111 Element body

11S, 111S Surface (of element body)

12, 112 Element block part

12S, 112S Surface (of element block part)

13, 113 First element terminal part

14 Second element terminal part

15, 115, 215 First connection cable

15S, 115S, 215S Element-side end (One end) (of first connection cable)

15T, 115T, 215T, 215T2, 215T3 The other end (of first connection cable)

16, 216 Second connection cable

16S, 216S Element-side end (One end) (of second connection cable)

16T, 216T, 216T2, 216T3 The other end (of second connection cable)

217, 217A, 217B Terminal member

2, 20, 21, 21a, 22, 120, 121, 121a, 121b, 122, 220, 221, 221a, 221b, 221c, 222, 320, 320a,

321, 322, 323, 323a, 324, 325, 420, 421 Audio system

30 Audio amplifier

330, 330B, 330C Audio amplifier (Audio amplifier apparatus equipped with sound quality modification element)

Audio amplifier circuit

31P, 31N Amplifier output terminal

31PW, 31NW Output path

31PC, 31NC Connection site (in output path)

SA Sound signal (output from audio amplifier circuit)

SS, SSa, SSb Sound signal (output to speaker)

SB, SB1, SB2, SB3, SB4 Divided sound signal

40 Speaker system

340, 340B, 340C Speaker system (Speaker system equipped with sound quality modification element)

40P, 40N Speaker input terminal

40P0, 40N0 Speaker input inner terminal

40PW, 40NW Input path

40PC, 40NC Connection site (in input path)

41 Speaker

SD, SDa, SDb, SD0 Sound (emitted from speaker)

50P, 50N, 150P, 150N Speaker cable

50PA, 50NA Amp-side end (End of audio amplifier circuit side) (of speaker cable)

50PS, 50NS Speaker-side end (End of speaker system side) (of speaker cable)

151P, 151N First speaker cable (of audio amplifier circuit side)

152P, 152N Second speaker cable (of speaker system side)

151PA, 151NA Amp-side end (of first speaker cable)

152PA, 152NA Amp-side end (Midpoint) (of second speaker cable)

151PS, 151NS Speaker-side end (Midpoint) (of first speaker cable)

152PS, 152NS Speaker-side end (of second speaker cable)

60PW, 60NW Transmission path

60PC, 60NC Connection site (in transmission path)

70PW, 70NW Connection path

LN Listener

DH Diametrical direction

LH Length direction

D Diameter (Dimension in diametrical direction)

L Length (Dimension in length direction)

1. A sound quality modification element to be connected to a connection path extending from an audio amplifier circuit that outputs a sound signal to one or a plurality of speakers, the sound quality modification element being configured to modify sound quality of sound to be emitted from the one or the plurality of speakers, the sound quality modification element comprising an element body including:
an element block part formed of a single metal block having a dimension of 5 mm or more in a diametrical direction and a dimension of 5 mm in a length direction perpendicular to the diameter direction; and
one first element terminal part provided at one end of the element block part in the length direction, from among the first element terminal part and one second element terminal part provided at an other end of the element block part in the length direction.

2. The sound quality modification element according to claim 1, wherein the element block part is made of pure aluminum.

3. The sound quality modification element according to claim 1, wherein the element block part is made of oxygen-free copper.

4. The sound quality modification element according to claim 1, wherein
the element block part is made of pure aluminum or oxygen-free copper, and
the element block part includes a metal plating layer that covers over an entire surface of the element block part.

5. The sound quality modification element according to claim 4, wherein the metal plating layer is an oxidation-resistant metal plating layer.

6. The sound quality modification element according to claim 4, wherein the metal plating layer is a nickel plating layer.

7. The sound quality modification element according to claim 4, wherein the metal plating layer is a nickel plating layer and a gold plating layer covering the nickel plating layer.

8. The sound quality modification element according to claim 1, further including a vibration-proof layer on a surface of the element block part or on the metal plating layer.

9. The sound quality modification element according to claim 1, wherein the element body is configured such that the element block part includes the first element terminal part without including the second element terminal part.

10. The sound quality modification element according to claim 1, wherein the element body is configured such that the element block part includes the first element terminal part and the second element terminal part.

11. An audio system comprising:
the one or the plurality of sound quality modification elements according to claim 9;
the audio amplifier circuit; and
a speaker system including the one or the plurality of speakers,
wherein the first element terminal part of the one or the plurality of sound quality modification elements is connected to a connection site in a transmission path extending from an amplifier output terminal of the audio amplifier circuit to a speaker input terminal of the speaker system.

12. An audio system comprising:
the one or the plurality of sound quality modification elements according to claim 10;
the audio amplifier circuit; and
a speaker system including the one or the plurality of speakers,
wherein the first element terminal part and the second element terminal part of the one or the plurality of sound quality modification elements are connected to a same connection site in a transmission path extending from an amplifier output terminal of the audio amplifier circuit to a speaker input terminal of the speaker system.

13. An audio system comprising:
the plurality of sound quality modification elements according to claim 10, the plurality of sound quality modification elements being connected in series to each other;
the audio amplifier circuit; and
a speaker system including the one or the plurality of speakers,
wherein unconnected one of the first element terminal parts and unconnected one of the second element terminal parts of the plurality of sound quality modification elements connected in series to each other are connected to a same connection site in a transmission path extending from an amplifier output terminal of the audio amplifier circuit to a speaker input terminal of the speaker system.

14. An audio system comprising:
the one or the plurality of sound quality modification elements according to claim 10, the plurality of sound quality modification elements being connected in series to each other;
the audio amplifier circuit; and
a speaker system including the one or the plurality of speakers,
wherein the one or the plurality of sound quality modification elements connected in series to each other are connected in series in a transmission path extending from an amplifier output terminal of the audio amplifier circuit to a speaker input terminal of the speaker system by use of unconnected one of the first element terminal parts and unconnected one of the second element terminal parts.

15. An audio amplifier apparatus equipped with a sound quality modification element, the audio amplifier apparatus comprising:
the one or the plurality of sound quality modification elements according to claim 9; and
the audio amplifier circuit including an amplifier output terminal,
wherein
the first element terminal part of the one or the plurality of sound quality modification elements is connected to a connection site in an output path extending from the audio amplifier circuit to the amplifier output terminal.

16. A speaker system equipped with a sound quality modification element, the speaker system comprising:
the one or the plurality of sound quality modification elements according to claim 9; and
the speaker system including a speaker input terminal,
wherein
the first element terminal part of the one or the plurality of sound quality modification elements is connected to a connection site in an input path extending from the speaker input terminal of the speaker system to the one or the plurality of speakers.

17. The sound quality modification element according to claim 4, further including a vibration-proof layer on a surface of the element block part or on the metal plating layer.

18. An audio amplifier apparatus equipped with a sound quality modification element, the audio amplifier apparatus comprising:
the one or the plurality of sound quality modification elements according to claim 10; and
the audio amplifier circuit including an amplifier output terminal,
wherein
the first element terminal part and the second element terminal part of the one or the plurality of sound quality modification elements are connected to a same connection site in an output path extending from the audio amplifier circuit to the amplifier output terminal, or
the audio amplifier apparatus further includes an output path extending from the audio amplifier circuit to the amplifier output terminal, and the one or the plurality of sound quality modification elements connected in series to each other are connected in series within the output path by use of unconnected one of the first element terminal parts and unconnected one of the second element terminal parts.

19. A speaker system equipped with a sound quality modification element, the speaker system comprising:
the one or the plurality of sound quality modification elements according to claim 10; and
the speaker system including a speaker input terminal,
wherein
the first element terminal part and the second element terminal part of the one or the plurality of sound quality modification elements are connected to a same connection site in an input path extending from the speaker input terminal of the speaker system to the one or the plurality of speakers, or
the speaker system further includes an input path extending from the speaker input terminal to the one or the plurality of speakers, and the one or the plurality of sound quality modification elements connected in series to each other are connected in series in the input path by use of unconnected one of the first element terminal parts and unconnected one of the second element terminal parts.
